(19) United States
(12) Patent Application Publication
(10) Pub. No.: US 2024/0282846 A1
(43) Pub. Date: Aug. 22, 2024

(54) SEMICONDUCTOR DEVICE

(71) Applicant: ROHM CO., LTD., Kyoto-shi (JP)

(72) Inventor: Shinya UMEKI, Kyoto-shi (JP)

(73) Assignee: ROHM CO., LTD., Kyoto-shi (JP)

(21) Appl. No.: 18/653,339

(22) Filed: May 2, 2024

Related U.S. Application Data
(63) Continuation of application No. PCT/JP2022/043762, filed on Nov. 28, 2022.

(30) Foreign Application Priority Data
Dec. 8, 2021 (JP) 2021-199503
Dec. 8, 2021 (JP) 2021-199504

(51) Int. Cl. H01L 29/739; H01L 23/522; H01L 29/06; H01L 29/10; H01L 29/66

(52) U.S. Cl. CPC H01L 29/7397; H01L 29/0688; H01L 29/1095; H01L 29/66348; H01L 23/5228

(57) ABSTRACT

Provided is a semiconductor device including a semiconductor layer which has opposing first and second principal surfaces, an IGBT region which is formed in the semiconductor layer, a diode region which is formed in the semiconductor layer and adjacent to the IGBT region, a first impurity region of a first conductivity type which is formed inside the semiconductor layer.

### CROSS-REFERENCE TO RELATED APPLICATIONS

This application is a Continuation Application of PCT Application No. PCT/JP2022/043762 filed on Nov. 28, 2022, which claims the benefit of priorities to Japanese Patent Application No. 2021-199503 filed on Dec. 8, 2021 and Japanese Patent Application No. 2021-199504 filed on Dec. 8, 2021. The entire contents of each application are hereby incorporated herein by reference.

### TECHNICAL FIELD

The present disclosure relates to a semiconductor device which includes an IGBT region and a diode region.

### BACKGROUND ART

WO 2020/080476 has disclosed an RC-IGBT (reverse conducting-insulated gate bipolar transistor) which is an example of a semiconductor device. The RC-IGBT includes an IGBT region and a diode region which are fabricated into a common semiconductor layer. The IGBT region includes an IGBT. The diode region includes a diode.

### BRIEF DESCRIPTION OF DRAWINGS

FIG. 1 is a schematic plan view of a semiconductor device according to a preferred embodiment of the present disclosure.

FIG. 2 is a schematic plan view which shows a structure of a first principal surface of the semiconductor device.

FIG. 3 is an enlarged view of a portion which is surrounded by an alternate long and short dashed line III in FIG. 1.

FIG. 4 is an enlarged view of a portion which is surrounded by an alternate long and short dashed line IV in FIG. 3.

FIG. 5 is an enlarged view of a portion which is surrounded by an alternate long and short dashed line V in FIG. 4.

FIG. 6 is an enlarged view of a portion which is surrounded by an alternate long and short dashed line VI in FIG. 4.

FIG. 7 is a cross-sectional view taken along line VII-VII in FIG. 5.

FIG. 8 is a cross-sectional view taken along line VIII-VIII in FIG. 6.

FIG. 9 is a cross-sectional view taken along line IX-IX in FIG. 5.

FIG. 10A to FIG. 10R are each a cross-sectional view of a region corresponding to FIG. 8, and a cross-sectional view for describing one example of a method of manufacturing the semiconductor device shown in FIG. 1 (Basic Structure 1).

FIG. 11 is a schematic enlarged plan view which shows a part of Basic Structure 2 of the semiconductor device, and an enlarged view of a portion corresponding to FIG. 4.

FIG. 12 is an enlarged view of a portion which is surrounded by an alternate long and short dashed line XII in FIG. 11.

FIG. 13 is an enlarged view of a portion which is surrounded by an alternate long and short dashed line XIII in FIG. 11.

FIG. 14 is a cross-sectional view taken along line XIV-XIV in FIG. 12.

FIG. 15 is a cross-sectional view taken along line XV-XV in FIG. 13.

FIG. 16 is a cross-sectional view taken along line XVI-XVI in FIG. 12.

FIG. 17A to FIG. 17C are each a cross-sectional view of a region which corresponds to FIG. 15, and a cross-sectional view for describing one example of a method of manufacturing the semiconductor device of FIG. 1 (Basic Structure 2).

FIG. 18 is a drawing of results of examining reverse recovery characteristics of a pn junction diode of a semiconductor device according to Reference Example 1 by a simulation.

FIG. 19A to FIG. 19I are each a drawing of results of examining a hole current density of the semiconductor device according to Reference Example 1 by a simulation.

FIG. 20A to FIG. 20D are each a schematic view of a pn junction diode according to Reference Examples 2 to 5, respectively.

FIG. 21 is a drawing of results of examining forward characteristics of the pn junction diodes according to Reference Examples 2 to 5 by a simulation.

FIG. 22 is a drawing of results of examining a degree of forward hole density of each of the pn junction diodes according to Reference Examples 2 to 5 by a simulation.

FIG. 23 is a drawing of results of examining reverse recovery characteristics of reverse recovery characteristics of the pn junction diodes according to Reference Examples 2 to 5 by a simulation.

FIG. 24 is a schematic cross-sectional view which shows Improved Structure 1-1 of the semiconductor device.

FIG. 25 is a schematic cross-sectional view which shows Improved Structure 1-1 of the semiconductor device.

FIG. 26A to FIG. 26C are each a cross-sectional view which shows a step in relation to formation of the structures of FIG. 24 and FIG. 25.

FIG. 27A and FIG. 27B are each a cross-sectional view which shows a step in relation to formation of the structures of FIG. 24 and FIG. 25.

FIG. 28 is a schematic cross-sectional view which shows Improved Structure 1-2 of the semiconductor device.

FIG. 29 is a schematic cross-sectional view which shows Improved Structure 1-2 of the semiconductor device.

FIG. 30A to FIG. 30C are each a cross-sectional view which shows a step in relation to formation of the structures of FIG. 28 and FIG. 29.

FIG. 31 is a schematic cross-sectional view which shows Improved Structure 1-3 of the semiconductor device.

FIG. 32 is a schematic cross-sectional view which shows Improved Structure 1-3 of the semiconductor device.

FIG. 33 is a schematic cross-sectional view which shows Improved Structure 1-4 of the semiconductor device.

FIG. 34 is a schematic cross-sectional view which shows Improved Structure 1-4 of the semiconductor device.

FIG. 35 is a schematic cross-sectional view which shows Improved Structure 2-1 of the semiconductor device.

FIG. 36A to FIG. 36E are each a cross-sectional view which shows a step in relation to formation of the structure of FIG. 35.

FIG. 37 is a schematic cross-sectional view which shows Improved Structure 2-2 of the semiconductor device.

FIG. 38 is a schematic cross-sectional view which shows Improved Structure 2-3 of the semiconductor device.

FIG. 39 is a schematic cross-sectional view which shows Improved Structure 2-4 of the semiconductor device.

FIG. 40 is a schematic cross-sectional view which shows Improved Structure 3-1 of the semiconductor device.

FIG. 41A to FIG. 41C are each a cross-sectional view which shows a step in relation to formation of the structure of FIG. 40.

FIG. 42 is a schematic cross-sectional view which shows Improved Structure 3-2 of the semiconductor device.

FIG. 43 is a schematic cross-sectional view which shows Improved Structure 4-1 of the semiconductor device.

FIG. 44A to FIG. 44C are each a cross-sectional view which shows a step in relation to formation of the structure of FIG. 43.

FIG. 45 is a schematic cross-sectional view which shows Improved Structure 5-1 of the semiconductor device.

FIG. 46 is a schematic perspective view which shows Improved Structure 5-1 of the semiconductor device.

FIG. 47A to FIG. 47E are each a cross-sectional view which shows a step in relation to formation of the structure of FIG. 43.

FIG. 48 is a schematic cross-sectional view which shows Improved Structure 6-1 of the semiconductor device.

FIG. 49A to FIG. 49C are each a cross-sectional view which shows a step in relation to formation of the structure of FIG. 48.

FIG. 50 is a schematic cross-sectional view which shows Improved Structure 7-1 of the semiconductor device.

FIG. 51 is a cross-sectional view which shows a step in relation to formation of the structure of FIG. 50.

FIG. 52 is a schematic cross-sectional view which shows Improved Structure 8-1 of the semiconductor device.

FIG. 53 is a schematic cross-sectional view which shows Improved Structure 8-2 of the semiconductor device.

FIG. 54 is a schematic cross-sectional view which shows Improved Structure 8-3 of the semiconductor device.

FIG. 55 is a schematic cross-sectional view which shows Improved Structure 8-4 of the semiconductor device.

FIG. 56 is a schematic cross-sectional view which shows Improved Structure 9-1 of the semiconductor device.

FIG. 57 is a schematic cross-sectional view which shows Improved Structure 9-2 of the semiconductor device.

FIG. 58 is a schematic cross-sectional view which shows Improved Structure 9-3 of the semiconductor device.

FIG. 59 is a schematic cross-sectional view which shows Improved Structure 9-4 of the semiconductor device.

FIG. 60 is a schematic cross-sectional view which shows Improved Structure 10-1 of the semiconductor device.

FIG. 61 is a schematic cross-sectional view which shows Improved Structure 10-2 of the semiconductor device.

FIG. 62 is a schematic cross-sectional view which shows Improved Structure 10-3 of the semiconductor device.

FIG. 63 is a schematic cross-sectional view which shows Improved Structure 10-4 of the semiconductor device.

FIG. 64 is a schematic cross-sectional view which shows Improved Structure 11-1 of the semiconductor device.

FIG. 65 is a schematic cross-sectional view which shows Improved Structure 11-2 of the semiconductor device.

FIG. 66 is a schematic cross-sectional view which shows Improved Structure 11-3 of the semiconductor device.

FIG. 67 is a schematic cross-sectional view which shows Improved Structure 11-4 of the semiconductor device,

FIG. 68 is a perspective view which shows a configuration example of a semiconductor module.

FIG. 69 is a circuit diagram which shows an electrical configuration of the semiconductor module of FIG. 68.

### DESCRIPTION OF EMBODIMENTS

### [Basic Structure 1 of Semiconductor Device]

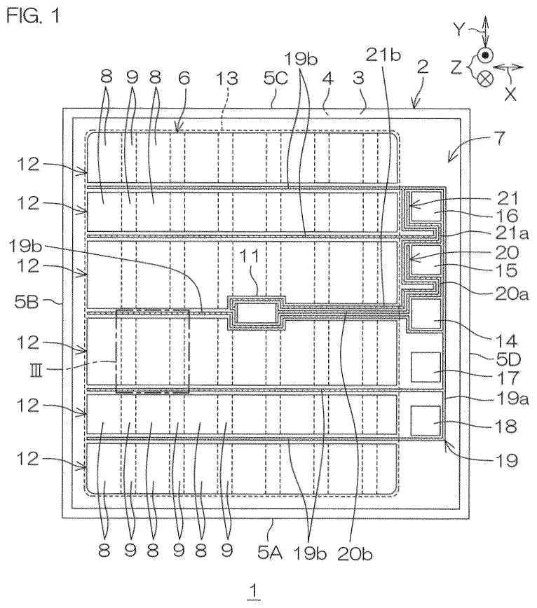

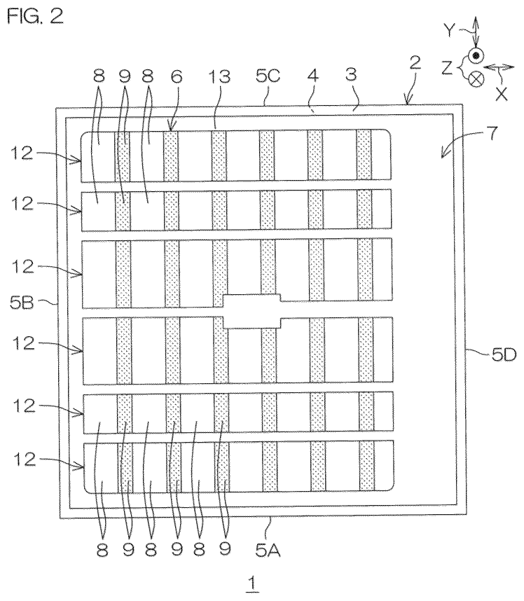

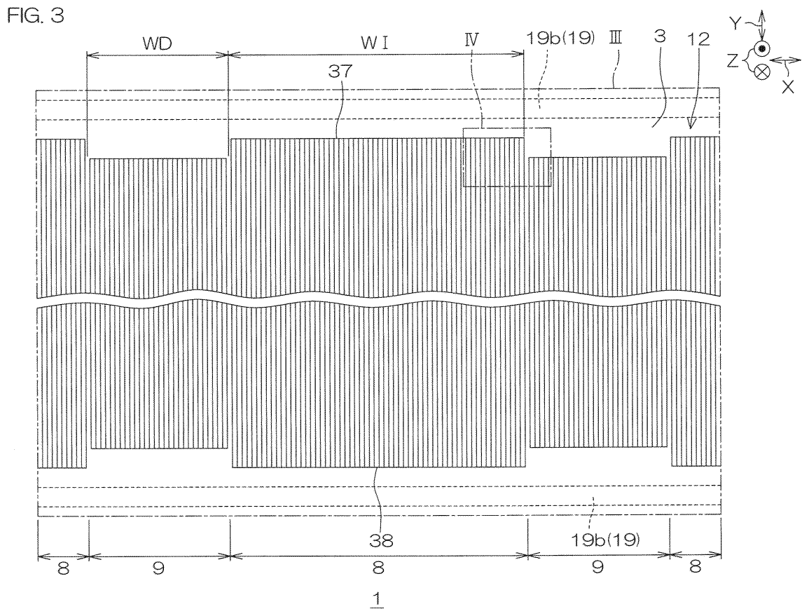

FIG. 1 is a schematic plan view of a semiconductor device 1 according to a preferred embodiment of the present disclosure. FIG. 2 is a schematic plan view which shows a structure of a first principal surface 3 of the semiconductor device 1. FIG. 3 is an enlarged view of a portion which is surrounded by an alternate long and short dashed line III in FIG. 1.

The semiconductor device 1 is an electronic component which has an RC-IGBT (reverse conducting-insulated gate bipolar transistor) which is integrally equipped with an IGBT and a diode.

With reference to FIG. 1 and FIG. 2, the semiconductor device 1 includes a semiconductor layer 2 which is formed in a rectangular parallelepiped shape. The semiconductor layer 2 has the first principal surface 3 at one side, a second principal surface 4 at the other side, and side surfaces 5A, 5B, 5C, 5D which connect the first principal surface 3 and the second principal surface 4.

The first principal surface 3 and the second principal surface 4 are formed in a quadrilateral shape in a plan view as viewed from a normal direction Z (hereinafter simply referred to as “plan view”). The side surface 5A and the side surface 5C extend along a first direction X and oppose each other in a second direction Y which intersects the first direction X. The side surface 5B and the side surface 5D extend along the second direction Y and oppose each other in the first direction X. Specifically, the second direction Y is orthogonal to the first direction X.

A thickness of the semiconductor layer 2 may be not less than 50 μm and not more than 200 μm. The thickness of the semiconductor layer 2 may be not less than 50 μm and not more than 100 μm, not less than 100 μm and not more than 150 μm, or not less than 150 μm and not more than 200 μm. By decreasing the thickness of the semiconductor layer 2, it is made possible to decrease a resistance value of the semiconductor layer 2.

The semiconductor layer 2 includes an active region 6 and an outer region 7. The active region 6 is a region in which the RC-IGBT is formed. The active region 6 is set at a central portion of the semiconductor layer 2 at an interval toward an inner region from the side surfaces 5A to 5D in a plan view. The active region 6 may be set in a quadrilateral shape having four sides parallel to the side surfaces 5A to 5D in a plan view.

The outer region 7 is a region outside the active region 6. The outer region 7 extends as a band along a peripheral edge of the active region 6 in a plan view. Specifically, the outer region 7 is set in an endless shape (quadrilateral annular shape) which surrounds the active region 6 in a plan view.

The active region 6 includes an IGBT region 8 and a diode region 9. In FIG. 2, the diode region 9 is shown with hatching for clarification. The IGBT region 8 is a region in which an IGBT is formed. The diode region 9 is a region in which a diode is formed. The diode region 9 is adjacent to the IGBT region 8.

Specifically, the active region 6 includes an RC-IGBT array 12. The plurality of (six in this preferred embodiment) of RC-IGBT arrays 12 are formed at an interval in the second direction Y. The RC-IGBT array 12 has a first end portion at one side (side surface 5B side) and a second end portion at the other side (side surface 5D side).

The RC-IGBT array 12 has a loop array which repeatedly includes the IGBT region 8, the diode region 9, the IGBT region 8, the diode region 9, . . . , which are arrayed in a single column along the first direction X from the first end portion to the second end portion. In this preferred embodiment, the first end portion of the RC-IGBT array 12 is formed of the IGBT region 8. In this preferred embodiment, the second end portion of the RC-IGBT array 12 is formed of the IGBT region 8. The first end portion of the RC-IGBT array 12 may be formed of the diode region 9. The second end portion of the RC-IGBT array 12 may be formed of the diode region 9.

Thus, the plurality of IGBT regions 8 are arrayed in a dispersed manner in the active region 6. The plurality of IGBT regions 8 are formed at an interval along the first direction X and the second direction Y. In this preferred embodiment, the plurality of IGBT regions 8 are arrayed in a matrix in a plan view. The plurality of IGBT regions 8 oppose each other along the first direction X and oppose each other along the second direction Y.

In this preferred embodiment, the plurality of IGBT regions 8 are each formed in a quadrilateral shape in a plan view. Specifically, the plurality of IGBT regions 8 are each formed in a rectangular shape along the second direction Y.

With reference to FIG. 3, a width WI of each IGBT region 8 may be not less than 10 μm and not more than 1000 μm. The width WI is a width of the IGBT region 8 in the first direction X. The width WI may be not less than 10 μm and not more than 100 μm, not less than 100 μm and not more than 200 μm, not less than 200 μm and not more than 300 μm, not less than 300 μm and not more than 400 μm, not less than 400 μm and not more than 500 μm, not less than 500 μm and not more than 600 μm, not less than 600 μm and not more than 700 μm, not less than 700 μm and not more than 800 μm, not less than 800 μm and not more than 900 μm, or not less than 900 μm and not more than 1000 μm. The width WI is preferably not less than 100 μm. The width WI is more preferably not less than 200 μm.

Also, the plurality of diode regions 9 are arrayed in a dispersed manner in the active region 6. The plurality of diode regions 9 are formed at an interval along the first direction X and the second direction Y. In this preferred embodiment, the plurality of diode regions 9 are arrayed in a matrix in a plan view. The plurality of diode regions 9 oppose each other along the first direction X and oppose each other along the second direction Y.

Specifically, the plurality of diode regions 9 are each formed so as to be adjacent to the IGBT region 8 in the first direction X. In this preferred embodiment, the plurality of diode regions 9 are each formed in a quadrilateral shape in a plan view. Specifically, the plurality of diode regions 9 are each formed in a rectangular shape extending along the second direction Y.

A planar area of each diode region 9 is preferably not more than a planar area of each IGBT region 8. The planar area of each diode region 9 is more preferably less than the planar area of each IGBT regions 8. With reference to FIG. 3, a width WD of each diode region 9 is preferably not more than the width WI of each IGBT region 8. The width WD is a width of the diode region 9 in the first direction X. The width WD of each diode region 9 is more preferably less than the width WI of each IGBT region 8.

The width WD may be not less than 5 μm and not more than 1000 μm. The width WD may be not less than 5 μm and not more than 100 μm, not less than 100 μm and not more than 200 μm, not less than 200 μm and not more than 300 μm, not less than 300 μm and not more than 400 μm, not less than 400 μm and not more than 500 μm, not less than 500 μm and not more than 600 μm, not less than 600 μm and not more than 700 μm, not less than 700 μm and not more than 800 μm, not less than 800 μm and not more than 900 μm, or not less than 900 μm and not more than 1000 μm. The width WD is preferably not less than 100 μm. The width WD is more preferably not less than 200 μm.

With reference to FIG. 1 and FIG. 2, the active region 6 further includes a sensor region 11. The sensor region 11 is a region in which a temperature sensor is formed. The sensor region 11 is formed in a region between two RC-IGBT arrays 12 that are adjacent to each other in the second direction Y. In this preferred embodiment, the sensor region 11 is formed at a central portion of the active region 6. At the central portion of the active region 6, heat tends to increase. Therefore, by disposing the temperature sensor at the central portion of the active region 6, it is made possible to appropriately detect a temperature of the semiconductor layer 2.

The semiconductor device 1 includes an emitter terminal electrode 13 (see broken line portion in FIG. 1) as an example of the second electrode that is formed on the first principal surface 3 of the semiconductor layer 2 in the active region 6. The emitter terminal electrode 13 transmits an emitter signal to the active region 6 (IGBT region 8). The emitter signal may be a reference potential or a ground potential.

The semiconductor device 1 includes a plurality of (five in this preferred embodiment) of terminal electrodes 14, 15, 16, 17 and 18 which are formed on the first principal surface 3 of the semiconductor layer 2 in the outer region 7. The plurality of terminal electrodes 14 to 18 are disposed at an interval from each other along the side surface 5D. The plurality of terminal electrodes 14 to 18 are formed in a quadrilateral shape in a plan view.

In this preferred embodiment, the plurality of terminal electrodes 14 to 18 include the gate terminal electrode 14, a first sense terminal electrode 15, a second sense terminal electrode 16, a current detection terminal electrode 17 and an open terminal electrode 18. The gate terminal electrode 14 transmits a gate signal to the active region 6 (IGBT region 8). The first sense terminal electrode 15 and the second sense terminal electrode 16 transmit a control signal that controls the sensor region 11 (temperature sensor). Although a specific description shall be omitted, the current detection terminal electrode 17 is an electrode for detecting and taking out a current flowing through the active region 6 to the exterior. The open terminal electrode 18 is put in an electrically floating state.

A layout of the gate terminal electrode 14, the first sense terminal electrode 15, the second sense terminal electrode 16, the current detection terminal electrode 17 and the open terminal electrode 18 is arbitrary. In this preferred embodiment, the open terminal electrode 18, the current detection terminal electrode 17, the gate terminal electrode 14, the first sense terminal electrode 15 and the second sense terminal electrode 16 are disposed in that order from the side surface 5A to the side surface 5C.

The semiconductor device 1 includes a gate wiring 19 which is electrically connected to the gate terminal electrode 14. The gate wiring 19 is also called a gate finger. The gate wiring 19 extends from the outer region 7 to the active region 6. The gate wiring 19 transmits a gate signal which is applied to the gate terminal electrode 14 to the active region 6 (IGBT region 8).

Specifically, the gate wiring 19 includes a first region 19a which is positioned in the outer region 7 and a second region 19b which is positioned in the active region 6. The first region 19a is electrically connected to the gate terminal electrode 14. In this preferred embodiment, the first region 19a is selectively routed in a region of the outer region 7 at the side surface 5D side.

The plurality (five in this preferred embodiment) of second regions 19b are formed in the active region 6. The plurality of second regions 19b are formed at an interval along the second direction Y. The plurality of second regions 19b are each formed in a region between two RC-IGBT arrays 12 that are adjacent to each other. The plurality of second regions 19b extend as a band along the first direction X.

The plurality of second regions 19b each extend from a region of the outer region 7 at the side surface 5D side to a region at the side surface 5B side. The plurality of second regions 19b may cross the active region 6. The plurality of second regions 19b are continuous to the first region 19a in the outer region 7. The plurality of second regions 19b transmits a gate signal to one of or both of the two RC-IGBT arrays 12 that are adjacent to each other.

The gate signal applied to the gate terminal electrode 14 is transmitted via the first region 19a to the second region 19b. The gate signal is thereby transmitted via the second region 19b to the active region 6 (IGBT region 8).

The semiconductor device 1 includes a first sense wiring 20 which is electrically connected to the first sense terminal electrode 15. The first sense wiring 20 extends from the outer region 7 to the sensor region 11. The first sense wiring 20 transmits a control signal for the temperature sensor.

Specifically, the first sense wiring 20 includes a first region 20a which is positioned in the outer region 7 and a second region 20b which is positioned in the active region 6. The first region 20a is electrically connected to the first sense terminal electrode 15. In this preferred embodiment, the first region 20a is selectively routed in a region of the outer region 7 at the side surface 5D side.

The second region 20b is formed in a region in which the sensor region 11 is formed in a region between the plurality of RC-IGBT arrays 12 that are adjacent to each other. The second region 20b extends as a band from the outer region 7 to the sensor region 11 along the first direction X.

The second region 20b is electrically connected to the temperature sensor in the sensor region 11. The second region 20b is continuous to the first region 20a in the outer region 7. An electrical signal applied to the first sense terminal electrode 15 is transmitted to the second region 20b via the first region 20a. The electrical signal is thereby transmitted to the temperature sensor via the second region 20b.

A second sense wiring 21 is electrically connected to the second sense terminal electrode 16. The second sense wiring 21 extends from the outer region 7 to the sensor region 11. The second sense wiring 21 transmits a control signal for the temperature sensor.

Specifically, the second sense wiring 21 includes a first region 21a which is positioned in the outer region 7 and a second region 21b which is positioned in the active region 6. The first region 21a is electrically connected to the second sense terminal electrode 16. In this preferred embodiment, the first region 21a is selectively routed in a region of the outer region 7 at the side surface 5D side.

The second region 21b is formed in a region in which the sensor region 11 is formed in a region between the plurality of RC-IGBT arrays 12 that are adjacent to each other. The second region 21b extends as a band from the outer region 7 toward the sensor region 11 along the first direction X. The second region 21b is electrically connected to the temperature sensor in the sensor region 11.

The second region 21b is continuous to the first region 21a in the outer region 7. An electrical signal applied to the second sense terminal electrode 16 is transmitted to the second region 21b via the first region 21a. The electrical signal is thereby transmitted to the temperature sensor via the second region 21b.

The gate wiring 19, the first sense wiring 20 and the second sense wiring 21 are formed in a region in which the sensor region 11 is formed in a region between the plurality of RC-IGBT arrays 12 that are adjacent to each other. The gate wiring 19, the first sense wiring 20 and the second sense wiring 21 run parallel in a region between two RC-IGBT arrays 12 that are adjacent to each other.

With such a structure, while increasing temperature detection precision by the temperature sensor, a decrease in wiring forming area can be achieved. That is, it is possible to suppress a decrease in size of the active region 6 due to formation of the temperature sensor inside the active region 6. While the temperature sensor is improved in temperature detection precision, it is thereby possible to suppress a decrease in area in which the RC-IGBT array 12 can be formed.

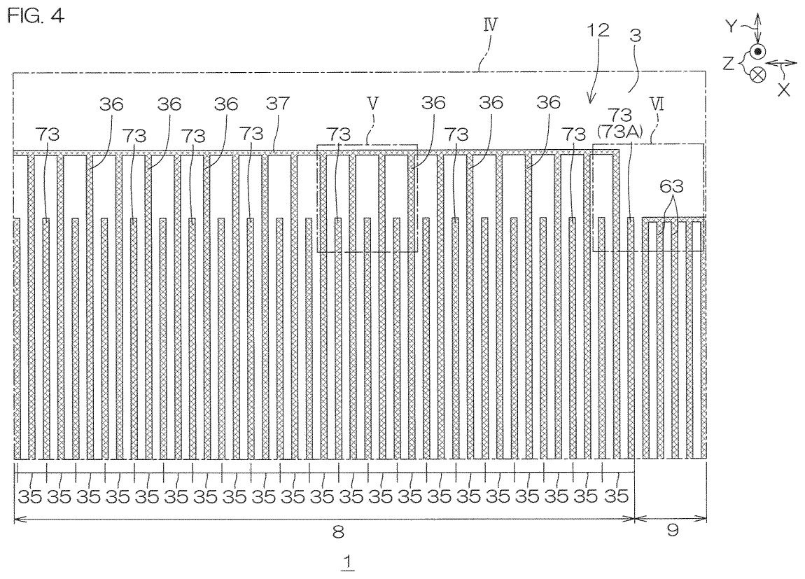

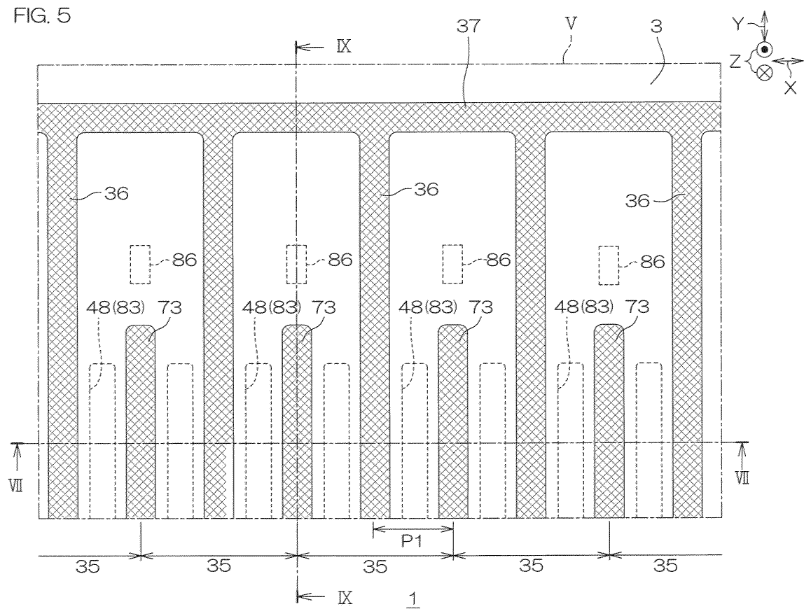

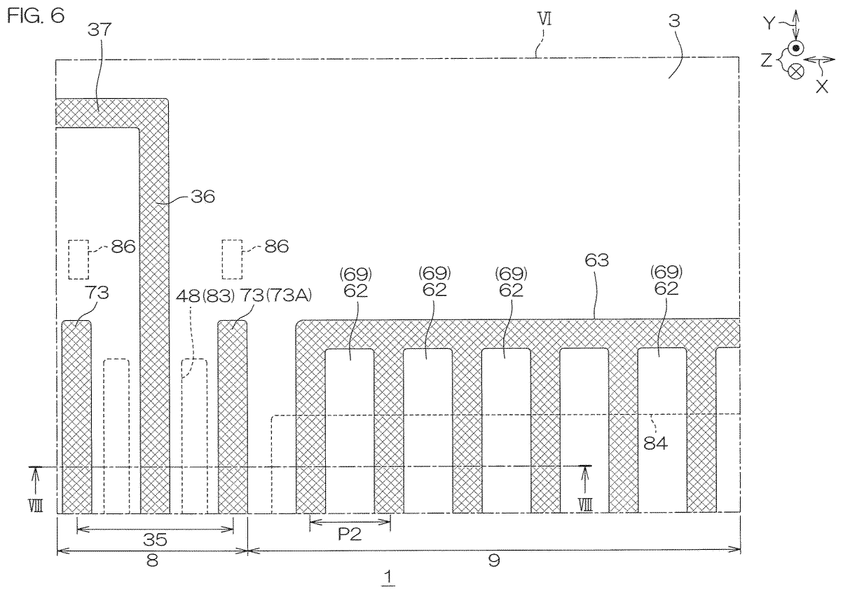

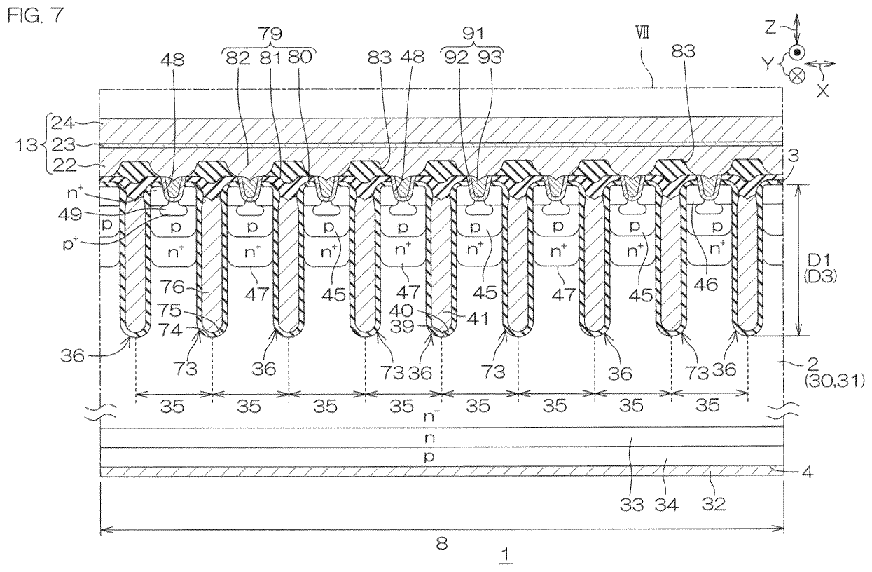

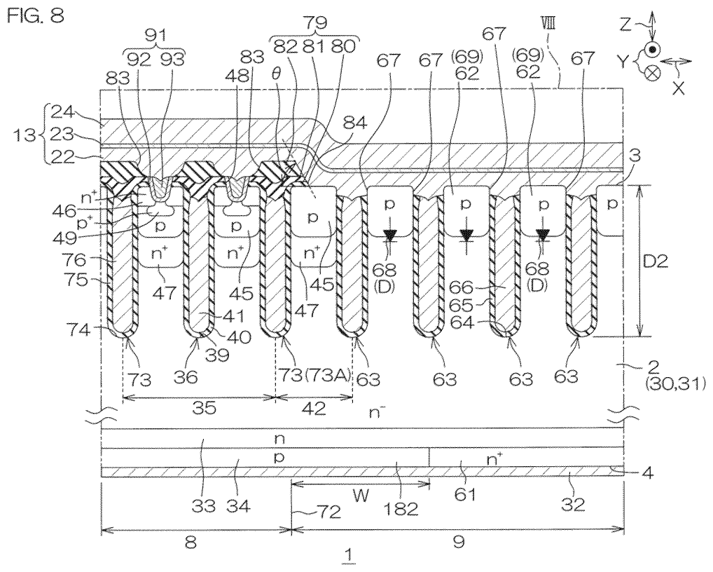

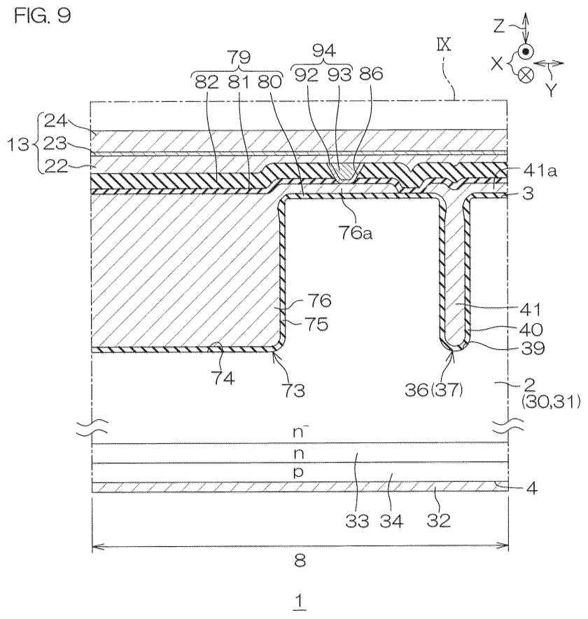

FIG. 4 is an enlarged view of a portion which is surrounded by an alternate long and short dashed line IV in FIG. 3. FIG. 5 is an enlarged view of a portion which is surrounded by an alternate long and short dashed line V in FIG. 4. FIG. 6 is an enlarged view of a portion which is surrounded by an alternate long and short dashed line VI in FIG. 4. FIG. 7 is a cross-sectional view taken along line VII-VII in FIG. 5. FIG. 8 is a cross-sectional view taken along line VIII-VIII in FIG. 6. FIG. 9 is a cross-sectional view taken along line IX-IX in FIG. 5.

With reference to FIG. 7 to FIG. 9, the semiconductor device 1 includes an n⁻ type drift region 30 which is formed in an interior of the semiconductor layer 2. Specifically, the drift region 30 is formed across an entirety of the semiconductor layer 2 in the first direction X and the second direction Y. The drift region 30 is formed in a surface layer portion of the first principal surface 3 of the semiconductor layer 2 in the normal direction Z (thickness direction of the semiconductor layer 2). An n type impurity concentration of the drift region 30 may be not less than 1.0×10¹³ cm⁻³ and not more than 1.0×10¹⁵ cm⁻³.

In this preferred embodiment, the semiconductor layer 2 has a single layer structure which includes an n-type semiconductor substrate 31. The semiconductor substrate 31 may be an FZ (floating zone) substrate made of silicon which is formed through an FZ method. The drift region 30 is formed by the semiconductor substrate 31.

The semiconductor device 1 includes a collector terminal electrode 32 as an example of the first electrode which is formed on the second principal surface 4 of the semiconductor layer 2. The collector terminal electrode 32 is electrically connected to the second principal surface 4. Specifically, the collector terminal electrode 32 is electrically connected to the IGBT region 8 (a collector region 34 to be described later) and the diode region 9 (a cathode region 61 to be described later). The collector terminal electrode 32 forms an ohmic contact with the second principal surface 4. The collector terminal electrode 32 transmits a collector signal to the IGBT region 8 and the diode region 9.

The collector terminal electrode 32 may include at least one among a Ti layer, an Ni layer, an Au layer, an Ag layer and an Al layer. The collector terminal electrode 32 may have a single layer structure that includes a Ti layer, an Ni layer, an Au layer, an Ag layer or an Al layer. The collector terminal electrode 32 may have a laminated structure in which at least two among a Ti layer, an Ni layer, an Au layer, an Ag layer and an Al layer are laminated in an arbitrary mode.

The semiconductor device 1 includes an n type buffer layer 33 which is formed in a surface layer portion of the second principal surface 4 of the semiconductor layer 2. The buffer layer 33 may be formed across an entirety of the surface layer portion of the second principal surface 4. An n type impurity concentration of the buffer layer 33 is greater than the n type impurity concentration of the drift region 30. The n type impurity concentration of the buffer layer 33 may be not less than 1.0×10¹⁵ cm⁻³ and not more than 1.0×10¹⁷ cm⁻³.

A thickness of the buffer layer 33 may be not less than 0.5 μm and not more than 30 μm. The thickness of the buffer layer 33 may be not less than 0.5 μm and not more than 5 μm, not less than 5 μm and not more than 10 μm, not less than 10 μm and not more than 15 μm, not less than 15 μm and not more than 20 μm, not less than 20 μm and not more than 25 μm, or not less than 25 μm and not more than 30 μm.

Each IGBT region 8 includes the p type collector region 34 which is formed in the surface layer portion of the second principal surface 4 of the semiconductor layer 2. The collector region 34 is exposed from the second principal surface 4. The collector region 34 may be formed across an entirety of the IGBT region 8 in the surface layer portion of the second principal surface 4. A p type impurity concentration of the collector region 34 may be not less than 1.0×10¹⁵ cm⁻³ and not more than 1.0×10¹⁸ cm⁻³. The collector region 34 forms an ohmic contact with the collector terminal electrode 32.

Each IGBT region 8 includes an FET structure 35 which is formed in the first principal surface 3 of the semiconductor layer 2. In this preferred embodiment, each IGBT region 8 includes the FET structure 35 of a trench gate type. Specifically, the FET structure 35 includes a trench gate structure 36 which is formed in the first principal surface 3. In FIG. 4 to FIG. 6, the trench gate structure 36 is shown with hatching.

The plurality of trench gate structures 36 are formed at an interval along the first direction X in the IGBT region 8. A distance between two trench gate structures 36 that are adjacent to each other in the first direction X may be not less than 1 μm and not more than 8 μm. The distance between the two trench gate structures 36 may be not less than 1 μm and not more than 2 μm, not less than 2 μm and not more than 3 μm, not less than 3 μm and not more than 4 μm, not less than 4 μm and not more than 5 μm, not less than 5 μm and not more than 6 μm, not less than 6 μm and not more than 7 μm, or not less than 7 μm and not more than 8 μm.

The plurality of trench gate structures 36 are formed as a band extending along the second direction Y in a plan view. The plurality of trench gate structures 36 are formed in stripes as a whole. The plurality of trench gate structures 36 each have one end portion at one side in the second direction Y and the other end portion at the other side in the second direction Y.

With reference to FIG. 3, the FET structure 35 includes a first outer trench gate structure 37 and a second outer trench gate structure 38. The first outer trench gate structure 37 extends along the first direction X and connects the one end portions of the plurality of trench gate structures 36. The second outer trench gate structure 38 extends along the first direction X and connects the other end portions of the plurality of trench gate structures 36.

The first outer trench gate structure 37 and the second outer trench gate structure 38 have the same structure as the trench gate structure 36 except that they are different in direction of extension. In the following, the structure of the trench gate structure 36 shall be described, and descriptions of the structure of the first outer trench gate structure 37 and the structure of the second outer trench gate structure 38 shall be omitted.

Each trench gate structure 36 includes a gate trench 39, a gate insulating layer 40 and a gate electrode layer 41. The gate trench 39 is formed in the first principal surface 3. The gate trench 39 includes side walls and a bottom wall. The side walls of the gate trench 39 may be formed perpendicular to the first principal surface 3.

The side wall of the gate trench 39 may be downwardly inclined from the first principal surface 3 toward the bottom wall. The gate trench 39 may be formed in a tapered shape in which an opening area at the opening side is larger than a bottom area. The bottom wall of the gate trench 39 may be formed parallel to the first principal surface 3. The bottom wall of the gate trench 39 may be formed in a shape curved toward the second principal surface 4. The gate trench 39 includes a bottom wall edge portion. The bottom wall edge portion connects the side walls and the bottom wall of the gate trench 39. The bottom wall edge portion may be formed in a shape curved toward the second principal surface 4.

A depth D1 of the gate trench 39 may be not less than 2 μm and not more than 10 μm. The depth D1 of the gate trench 39 may be not less than 2 μm and not more than 3 μm, not less than 3 μm and not more than 4 μm, not less than 4 μm and not more than 5 μm, not less than 5 μm and not more than 6 μm, not less than 6 μm and not more than 7 μm, not less than 7 μm and not more than 8 μm, not less than 8 μm and not more than 9 μm, or not less than 9 μm and not more than 10 μm. The depth D1 of the gate trench 39 may be defined as a distance between a depth position at the deepest portion of the bottom wall of the gate trench 39 and the first principal surface 3.

A width of the gate trench 39 may be not less than 0.5 μm and not more than 3 μm. The width of the gate trench 39 is a width of the gate trench 39 in the first direction X. The width of the gate trench 39 may be not less than 0.5 μm and not more than 1 μm, not less than 1 μm and not more than 1.5 μm, not less than 1.5 μm and not more than 2 μm, not less than 2 μm and not more than 2.5 μm, or not less than 2.5 μm and not more than 3 μm.

The gate insulating layer 40 is formed as a film along an inner wall of the gate trench 39. The gate insulating layer 40 demarcates a recess space inside the gate trench 39. In this preferred embodiment, the gate insulating layer 40 includes a silicon oxide film. The gate insulating layer 40 may include a silicon nitride film in place of or in addition to the silicon oxide film.

The gate electrode layer 41 is embedded across the gate insulating layer 40 in the gate trench 39. Specifically, the gate electrode layer 41 is embedded in the recess space of the gate trench 39 demarcated by the gate insulating layer 40. The gate electrode layer 41 is controlled by the gate signal. The gate electrode layer 41 may contain a conductive polysilicon.

The gate electrode layer 41 is formed in a wall shape extending along the normal direction Z in sectional view. The gate electrode layer 41 has an upper end portion which is positioned at the opening side of the gate trench 39. An upper end portion of the gate electrode layer 41 is positioned at the bottom wall side of the gate trench 39 with respect to the first principal surface 3.

A depression which is depressed toward the bottom wall of the gate trench 39 is formed at the upper end portion of the gate electrode layer 41. The depression at the upper end portion of the gate electrode layer 41 is formed in a convergent shape directed toward the bottom wall of the gate trench 39. The upper end portion of the gate electrode layer 41 has a constricted portion which is constricted to the inside of the gate electrode layer 41.

The FET structure 35 includes a p type body region 45 which is formed in the surface layer portion of the first principal surface 3 of the semiconductor layer 2. A p type impurity concentration of the body region 45 may be not less than 1.0×10¹⁷ cm⁻³ and not more than 1.0×10¹⁸ cm⁻³. The body region 45 is each formed at both sides of the trench gate structure 36. The body region 45 is formed as a band extending along the trench gate structure 36 in a plan view. The body region 45 is exposed from the side wall of the gate trench 39. A bottom portion of the body region 45 is formed in a region between the bottom wall of the gate trench 39 and the first principal surface 3 with regard to the normal direction Z.

The FET structure 35 includes an n⁺ type emitter region 46 which is formed in the surface layer portion of the body region 45. An n type impurity concentration of the emitter region 46 is greater than the n type impurity concentration of the drift region 30. The n type impurity concentration of the emitter region 46 may be not less than 1.0×10¹⁹ cm⁻³ and not more than 1.0×10²⁰ cm⁻³.

In this preferred embodiment, the FET structure 35 includes a plurality of the emitter regions 46 which are formed at both sides of the trench gate structure 36. The emitter region 46 is formed as a band extending along the trench gate structure 36 in a plan view. The emitter region 46 is exposed from the first principal surface 3 and a side wall of the gate trench 39. The bottom portion of the emitter region 46 is formed in a region between the upper end portion of the gate electrode layer 41 and the bottom portion of the body region 45 with regard to the normal direction Z.

In this preferred embodiment, the FET structure 35 includes an n⁺ type carrier storage region 47 which is formed in a region of the semiconductor layer 2 at the second principal surface 4 side with respect to the body region 45. An n type impurity concentration of the carrier storage region 47 is greater than the n type impurity concentration of the drift region 30. The n type impurity concentration of the carrier storage region 47 may be not less than 1.0×10¹⁵ cm⁻³ and not more than 1.0×10¹⁷ cm⁻³.

In this preferred embodiment, the FET structure 35 includes a plurality of the carrier storage regions 47 which are formed at both sides of the trench gate structure 36. The carrier storage region 47 is formed as a band extending along the trench gate structure 36 in a plan view. The carrier storage region 47 is exposed from a side wall of the gate trench 39. A bottom portion of the carrier storage region 47 is formed in a region between the bottom portion of the body region 45 and the bottom wall of the gate trench 39 with regard to the normal direction Z.

The carrier storage region 47 suppresses carriers (holes) supplied to the semiconductor layer 2 from being drawn back (drained) to the body region 45. The holes thereby accumulate in a region of the semiconductor layer 2 directly below the FET structure 35. As a result, a decrease of on-resistance and a decrease of on-voltage are achieved.

The FET structure 35 includes a contact trench 48 which is formed in the first principal surface 3 of the semiconductor layer 2. In this preferred embodiment, the FET structure 35 includes a plurality of the contact trenches 48 which are formed at both sides of the trench gate structure 36. The contact trench 48 exposes the emitter region 46. In this preferred embodiment, the contact trench 48 penetrates through the emitter region 46.

The contact trench 48 is formed at an interval from the trench gate structure 36 in the first direction X. The contact trench 48 extends as a band along the trench gate structure 36 in a plan view. A length of the contact trench 48 is not more than a length of the trench gate structure 36 with regard to the second direction Y. Specifically, the length of the contact trench 48 is less than the length of the trench gate structure 36.

The FET structure 35 includes a p⁺ type contact region 49 which is formed in a region of the body region 45 along a bottom wall of the contact trench 48. A p type impurity concentration of the contact region 49 is greater than the p type impurity concentration of the body region 45. The p type impurity concentration of the contact region 49 may be not less than 1.0×10¹⁹ cm⁻³ and not more than 1.0×10²⁰ cm⁻³.

The contact region 49 is exposed from the bottom wall of the contact trench 48. The contact region 49 extends as a band along the contact trench 48 in a plan view. A bottom portion of the contact region 49 is formed in a region between the bottom wall of the contact trench 48 and the bottom portion of the body region 45 with regard to the normal direction Z.

As described above, in the FET structure 35, the gate electrode layer 41 opposes the body region 45 and the emitter region 46 across the gate insulating layer 40. In this preferred embodiment, the gate electrode layer 41 also opposes the carrier storage region 47 across the gate insulating layer 40. A channel of the IGBT is formed in a region of the body region 45 between the emitter region 46 and the drift region 30 (carrier storage region 47). ON/OFF of the channel is controlled by the gate signal.

Each IGBT region 8 includes an emitter trench structure 73 in the first principal surface 3 of the semiconductor layer 2. Specifically, each IGBT region 8 includes a plurality of the emitter trench structures 73 at both sides of the FET structure 35. The emitter trench structure 73 is formed in a region adjacent to the FET structure 35 in the surface layer portion of the first principal surface 3. The emitter trench structure 73 is formed as a band extending along the second direction Y in a plan view. The plurality of emitter trench structures 73 are formed in stripes as a whole. The emitter trench structure 73 may be in a band shape parallel to the trench gate structure 36.

In each IGBT region 8, the trench gate structure 36 and the emitter trench structure 73 are arrayed alternately at an interval along the first direction X. These trench structures which are formed in the IGBT region 8 may be collectively referred to as a second trench structure. The trench gate structure 36 and the emitter trench structure 73 may be arrayed alternately, with an equal interval kept. A distance (first pitch P1) between the trench gate structure 36 and the emitter trench structure 73 that are adjacent to each other in the first direction X may be, for example, not less than 1.0 μm and not more than 3.5 μm.

Also, with reference to FIG. 8, in this preferred embodiment, a termination trench of the trench gate structures 36 and the emitter trench structures 73 arrayed alternately along the first direction X is the emitter trench structure 73. This termination emitter trench structure 73 (indicated as an emitter trench structure 73A in FIG. 4, FIG. 6 and FIG. 8) forms a boundary 72 between the IGBT region 8 and the diode region 9.

The emitter trench structure 73 includes an emitter trench 74, an emitter insulating layer 75 and an emitter potential electrode layer 76. The emitter trench 74 is formed in the first principal surface 3 of the semiconductor layer 2. The emitter trench 74 includes side walls and a bottom wall. The side wall of the emitter trench 74 may be formed perpendicular to the first principal surface 3.

The side wall of the emitter trench 74 may be downwardly inclined from the first principal surface 3 toward the bottom wall. The emitter trench 74 may be formed in a tapered shape in which an opening area at the opening side is larger than a bottom area. The emitter region 46, the body region 45 and the carrier storage region 47 are exposed from the side wall (outer side wall) of the emitter trench 74 which opposes the FET structure 35. The bottom wall of the emitter trench 74 may be formed parallel to the first principal surface 3. The bottom wall of the emitter trench 74 may be formed in a shape curved toward the second principal surface 4. The emitter trench 74 includes a bottom wall edge portion. The bottom wall edge portion connects the side walls and the bottom wall of the emitter trench 74. The bottom wall edge portion may be formed in a shape curved toward the second principal surface 4 of the semiconductor layer 2.

A depth D3 of the emitter trench 74 may be not less than 2 μm and not more than 10 μm. The depth D3 of the emitter trench 74 may be not less than 2 μm and not more than 3 μm, not less than 3 μm and not more than 4 μm, not less than 4 μm and not more than 5 μm, not less than 5 μm and not more than 6 μm, not less than 6 μm and not more than 7 μm, not less than 7 μm and not more than 8 μm, not less than 8 μm and not more than 9 μm, or not less than 9 μm and not more than 10 μm. The depth D3 of the emitter trench 74 may be equal to the depth D1 of the gate trench 39.

A width of the emitter trench 74 may be not less than 0.5 μm and not more than 3 μm. The width of the emitter trench 74 is a width of the emitter trench 74 in the first direction X. The width of the emitter trench 74 may be not less than 0.5 μm and not more than 1 μm, not less than 1 μm and not more than 1.5 μm, not less than 1.5 μm and not more than 2 μm, not less than 2 μm and not more than 2.5 μm, or not less than 2.5 μm and not more than 3 μm. The width of the emitter trench 74 may be equal to the width of the gate trench 39.

The emitter insulating layer 75 is formed as a film along an inner wall of the emitter trench 74. The emitter insulating layer 75 demarcates a recess space inside the emitter trench 74. In this preferred embodiment, the emitter insulating layer 75 includes a silicon oxide film. The emitter insulating layer 75 may include a silicon nitride film in place of or in addition to the silicon oxide film.

The emitter potential electrode layer 76 is embedded across the emitter insulating layer 75 in the emitter trench 74. Specifically, the emitter potential electrode layer 76 is embedded in a recess space of the emitter trench 74 which is demarcated by the emitter insulating layer 75. The emitter potential electrode layer 76 may include a conductive polysilicon. The emitter potential electrode layer 76 is controlled by an emitter signal.

The emitter potential electrode layer 76 is formed in a wall shape extending along the normal direction Z in sectional view. The emitter potential electrode layer 76 has an upper end portion which is positioned at the opening side of the emitter trench 74. The upper end portion of the emitter potential electrode layer 76 is positioned at the bottom wall side of the emitter trench 74 with respect to the first principal surface 3.

A depression which is depressed toward the bottom wall of the emitter trench 74 is formed in the upper end portion of the emitter potential electrode layer 76. The depression at the upper end portion of the emitter potential electrode layer 76 is formed in a convergent shape directed toward the bottom wall of the emitter trench 74. The upper end portion of the emitter potential electrode layer 76 has a constricted portion which is constricted to the inside of the emitter potential electrode layer 76.

Each diode region 9 includes the n⁺ type cathode region 61 (second impurity region) which is formed in the surface layer portion of the second principal surface 4 of the semiconductor layer 2. An n type impurity concentration of the cathode region 61 is greater than the n type impurity concentration of the drift region 30. The n type impurity concentration of the cathode region 61 may be not less than 1.0×10¹⁹ cm⁻³ and not more than 1.0×10²⁰ cm⁻³.

The cathode region 61 is exposed from the second principal surface 4. The cathode region 61 forms an ohmic contact with the collector terminal electrode 32. The cathode region 61 is electrically connected to the collector region 34 at a side along the second direction Y. In this preferred embodiment, the cathode region 61 is surrounded by the collector region 34 of the IGBT region 8. That is, the cathode region 61 is electrically connected to the collector region 34 at a side along the first direction X and at a side along the second direction Y.

Each diode region 9 includes a cell separating structure 63 which demarcates a diode cell region 69. In FIG. 4 and FIG. 6, the cell separating structure 63 is shown with hatching. Specifically, each diode region 9 includes a plurality of the cell separating structures 63 that respectively demarcate the plurality of diode cell regions 69.

The plurality of cell separating structures 63 are each formed in a region between the plurality of diode cell regions 69 that are adjacent to each other. Specifically, the plurality of cell separating structures 63 are each formed in an annular shape (quadrilateral annular shape in this preferred embodiment) surrounding the diode cell region 69 in a plan view. The cell separating structure 63 which demarcates one of the diode cell regions 69 and the cell separating structure 63 which demarcates the other of the diode cell regions 69 are integrally formed in a region between the plurality of diode cell regions 69 that are adjacent to each other.

In the first direction X, the plurality of cell separating structures 63 may be arrayed with an equal interval kept. The plurality of cell separating structures 63 are formed in stripes. With reference to FIG. 6, a distance (second pitch P2) between the two cell separating structures 63 that are adjacent to each other in the first direction X may be, for example, not less than 1.0 μm and not more than 10.0 μm. The second pitch P2 may be the same as the first pitch P1 (see FIG. 5).

In this preferred embodiment, the diode cell regions 69 which are demarcated by the plurality of cell separating structures 63 are formed, with an interval kept, along the first direction X in a plan view. The plurality of diode cell regions 69 are each formed as a band extending along the second direction Y in a plan view. The plurality of diode cell regions 69 are formed in stripes as a whole. In this preferred embodiment, a part of the diode cell region 69 overlaps with the collector region 34 in the normal direction Z and remaining parts thereof overlap with the cathode region 61. With regard to the second direction Y, a length of the diode cell region 69 may be not more than the length of the trench gate structure 36. The length of the diode cell region 69 may be less than the length of the trench gate structure 36.

The cell separating structure 63 includes a cell separating trench 64 as an example of the first trench, a cell separating insulating layer 65 as an example of the first insulating layer and a cell separating electrode layer 66 as an example of the first embedded conductive layer. The cell separating trench 64 is formed in the first principal surface 3. The cell separating trench 64 includes side walls and a bottom wall. The side wall of the cell separating trench 64 may be formed perpendicular to the first principal surface 3.

The side wall of the cell separating trench 64 may be downwardly inclined from the first principal surface 3 toward the bottom wall. The cell separating trench 64 may be formed in a tapered shape in which an opening area at the opening side is larger than a bottom area. The bottom wall of the cell separating trench 64 may be formed parallel to the first principal surface 3. The bottom wall of the cell separating trench 64 may be formed in a shape curved toward the second principal surface 4. The cell separating trench 64 includes a bottom wall edge portion. The bottom wall edge portion connects the side walls and the bottom wall of the cell separating trench 64. The bottom wall edge portion may be formed in a shape curved toward the second principal surface 4.

A depth D2 of the cell separating trench 64 may be not less than 2 μm and not more than 10 μm. The depth D2 of the cell separating trench 64 may be not less than 2 μm and not more than 3 μm, not less than 3 μm and not more than 4 μm, not less than 4 μm and not more than 5 μm, not less than 5 μm and not more than 6 μm, not less than 6 μm and not more than 7 μm, not less than 7 μm and not more than 8 μm, not less than 8 μm and not more than 9 μm, or not less than 9 μm and not more than 10 μm. The depth D2 of the cell separating trench 64 may be equal to the depth D1 of the gate trench 39 (see FIG. 7). The depth D2 of the cell separating trench 64 may be defined as a distance between a depth position at the deepest portion of the bottom wall of the cell separating trench 64 and the first principal surface 3.

A width of the cell separating trench 64 may be not less than 0.5 μm and not more than 3 μm. The width of the cell separating trench 64 is a width of the cell separating trench 64 in the first direction X. The width of the cell separating trench 64 may be not less than 0.5 μm and not more than 1 μm, not less than 1 μm and not more than 1.5 μm, not less than 1.5 μm and not more than 2 μm, not less than 2 μm and not more than 2.5 μm, or not less than 2.5 μm and not more than 3 μm. The width of the cell separating trench 64 may be equal to the width of the gate trench 39.

The cell separating insulating layer 65 is formed as a film along an inner wall of the cell separating trench 64. The cell separating insulating layer 65 demarcates a recess space inside the cell separating trench 64. In this preferred embodiment, the cell separating insulating layer 65 includes a silicon oxide film. The cell separating insulating layer 65 may include a silicon nitride film in place of or in addition to the silicon oxide film.

The cell separating electrode layer 66 is embedded across the cell separating insulating layer 65 in the cell separating trench 64. Specifically, the cell separating electrode layer 66 is embedded in a recess space of the cell separating trench 64 which is demarcated by the cell separating insulating layer 65. The cell separating electrode layer 66 is controlled by an emitter signal. The cell separating electrode layer 66 may contain a conductive polysilicon.

The cell separating electrode layer 66 is formed in a wall shape extending along the normal direction Z in sectional view. The cell separating electrode layer 66 has an upper end portion which is positioned at the opening side of the cell separating trench 64. The upper end portion of the cell separating electrode layer 66 is positioned at the bottom wall side of the cell separating trench 64 with respect to the first principal surface 3.

The upper end portion of the cell separating electrode layer 66 is formed in a convergent shape directed toward the first principal surface 3 side. A depression which is depressed toward the bottom wall of the cell separating trench 64 is formed in the upper end portion of the cell separating electrode layer 66. The depression of the cell separating electrode layer 66 is formed in a convergent shape directed toward the bottom wall of the cell separating trench 64.

Each diode region 9 includes a p⁻ type anode region 62 (second impurity region) which is formed in the surface layer portion of the first principal surface 3 of the semiconductor layer 2. A p type impurity concentration of the anode region 62 may be not more than the p type impurity concentration of the body region 45. The p type impurity concentration of the anode region 62 is preferably less than the p type impurity concentration of the body region 45. The p type impurity concentration of the anode region 62 may be not less than 1.0×10¹⁵ cm⁻³ and not more than 1.0×10¹⁸ cm⁻³.

The anode region 62 is formed in each diode cell region 69. Therefore, in the first direction X, the plurality of anode regions 62 are arrayed with an equal interval kept and formed in stripes as a whole.

The anode region 62 forms a pn junction portion 68 with the semiconductor layer 2. Thereby, a pn junction diode D in which the anode region 62 is given as an anode and the semiconductor layer 2 (cathode region 61) is given as a cathode is formed.

With reference to FIG. 8, in this preferred embodiment, the collector region 34 includes a lead-out region 182. The lead-out region 182 crosses the boundary 72 between the IGBT region 8 and the diode region 9 and is led out to a peripheral edge of the diode region 9. The lead-out region 182 is led out from the IGBT region 8 to the diode region 9 along the first direction X.

The lead-out region 182 overlaps with the diode region 9 over a predetermined overlap width W. A starting point of the overlap width W is set at the boundary 72 between the IGBT region 8 and the diode region 9. An end point of the overlap width W is set at a boundary between the lead-out region 182 and the cathode region 61.

A ratio of the overlap width W in relation to the width WD of the diode region 9, W/WD, may be not less than 0.001 and not more than 0.5. The ratio W/WD may be not less than 0.001 and not more than 0.01, not less than 0.01 and not more than 0.05, not less than 0.05 and not more than 0.1, not less than 0.1 and not more than 0.15, not less than 0.15 and not more than 0.2, not less than 0.2 and not more than 0.25, not less than 0.25 and not more than 0.3, not less than 0.3 and not more than 0.35, not less than 0.35 and not more than 0.4, not less than 0.4 and not more than 0.45, or not less than 0.45 and not more than 0.5.

The overlap width W may be not less than 1 μm and not more than 200 μm. The overlap width W may be not less than 1 μm and not more than 50 μm, not less than 50 μm and not more than 100 μm, not less than 100 μm and not more than 150 μm, or not less than 150 μm and not more than 200 μm.

The overlap width W may be not less than 1 μm and not more than 20 μm, not less than 20 μm and not more than 40 μm, not less than 40 μm and not more than 60 μm, not less than 60 μm and not more than 80 μm, not less than 80 μm and not more than 100 μm, not less than 100 μm and not more than 120 μm, not less than 120 μm and not more than 140 μm, not less than 140 μm and not more than 160 μm, not less than 160 μm and not more than 180 μm, or not less than 180 μm and not more than 200 μm. The overlap width W is preferably not less than 10 μm and not more than 150 μm.

The lead-out region 182 may oppose one or the plurality of anode regions 62 (diode cell region 69) with regard to the normal direction Z. The lead-out region 182 may face 1, 2, 3, 4, 5, 6, 7, 8, 9, 10, 11, 12, 13, 14, 15, 16, 17, 18, 19, or 20 anode regions 62. The lead-out region 182 preferably opposes not less than 1 and not more than 10 anode regions 62.

The lead-out region 182 may oppose one or the plurality of cell separating trenches 64 with regard to the normal direction Z. The lead-out region 182 may face 1, 2, 3, 4, 5, 6, 7, 8, 9, 10, 11, 12, 13, 14, 15, 16, 17, 18, 19, or 20 cell separating trenches 64. The lead-out region 182 preferably opposes not less than 1 and not more than 10 cell separating trenches 64.

Inside the cell separating trench 64, the recess 67 is demarcated by the side walls of the cell separating trench 64, the upper end portion of the cell separating electrode layer 66 and the upper end portion of the cell separating insulating layer 65. A wide portion of the cell separating trench 64 is formed by the recess 67. A side wall of the recess 67 (side wall of cell separating trench 64) exposes the anode region 62.

As described above, a structure which is closest to the diode region 9 among the plurality of emitter trench structures 73 is the termination emitter trench structure 73A. In this preferred embodiment, a side wall at the side closer to the diode region 9 of the termination emitter trench structure 73A forms the boundary 72 between the IGBT region 8 and the diode region 9. As with the FET structure 35, the body region 45 and the carrier storage region 47 are sequentially formed from the first principal surface 3 side in a region between the termination emitter trench structure 73A and the cell separating structure 63 which is most proximate to the IGBT region 8. On the other hand, since the emitter region 46 is not formed in this region and this region is not structured so as to form a channel, this region may be referred to as a dummy FET structure 42. The dummy FET structure 42 is formed in the diode region 9.

With reference to FIG. 7 to FIG. 9, the semiconductor device 1 includes an interlayer insulating layer 79 which is formed on the first principal surface 3 of the semiconductor layer 2. The interlayer insulating layer 79 is formed as a film along the first principal surface 3 and selectively covers the first principal surface 3. Specifically, the interlayer insulating layer 79 selectively covers the IGBT region 8 and the diode region 9.

The interlayer insulating layer 79 may contain silicon oxide or silicon nitride. The interlayer insulating layer 79 may contain at least one type of material among NSG (non-doped silicate glass), PSG (phosphor silicate glass) and BPSG (boron phosphor silicate glass).

A thickness of the interlayer insulating layer 79 may be not less than 0.1 μm and not more than 1 μm. The thickness of the interlayer insulating layer 79 may be not less than 0.1 μm and not more than 0.2 μm, not less than 0.2 μm and not more than 0.4 μm, not less than 0.4 μm and not more than 0.6 μm, not less than 0.6 μm and not more than 0.8 μm, or not less than 0.8 μm and not more than 1 μm.

In this preferred embodiment, the interlayer insulating layer 79 has a laminated structure which includes a first insulating layer 80, a second insulating layer 81 and a third insulating layer 82 that are laminated in that order from the first principal surface 3 side. The first insulating layer 80 preferably contains silicon oxide (for example, thermal oxide film). The second insulating layer 81 preferably includes an NGS layer. The second insulating layer 81 may include a PSG layer or a BPSG layer in place of the NGS layer. The third insulating layer 82 preferably includes a BPSG layer. The third insulating layer 82 may include an NGS layer or a PSG layer in place of the BPSG layer. The third insulating layer 82 preferably contains an insulating material which is different in property from the second insulating layer 81.

The first insulating layer 80 is formed as a film on the first principal surface 3. The first insulating layer 80 is continuous to the gate insulating layer 40, a region separating insulating layer 55 and the cell separating insulating layer 65. The second insulating layer 81 is formed as a film on the first insulating layer 80. The third insulating layer 82 is formed as a film on the second insulating layer 81.

A thickness of the first insulating layer 80 may be not less than 500 Å and not more than 2000 Å. The thickness of the first insulating layer 80 may be not less than 500 Å and not more than 1000 Å, not less than 1000 Å and not more than 1500 Å, or not less than 1500 Å and not more than 2000 Å.

A thickness of the second insulating layer 81 may be not less than 500 Å and not more than 4000 Å. The thickness of the second insulating layer 81 may be not less than 500 Å and not more than 1000 Å, not less than 1000 Å and not more than 1500 Å, not less than 1500 Å and not more than 2000 Å, not less than 2000 Å and not more than 2500 Å, not less than 2500 Å and not more than 3000 Å, not less than 3000 Å and not more than 3500 Å, or not less than 3500 Å and not more than 4000 Å.

A thickness of the third insulating layer 82 may be not less than 1000 Å and not more than 8000 Å. The thickness of the third insulating layer 82 may be not less than 1000 Å and not more than 2000 Å, not less than 2000 Å and not more than 4000 Å, not less than 4000 Å and not more than 6000 Å, or not less than 6000 Å and not more than 8000 Å.

With reference to FIG. 9, the gate electrode layer 41 of the FET structure 35 has a gate lead-out electrode layer 41a which is led out from the gate trench 39 onto the first principal surface 3. The gate lead-out electrode layer 41a is led out from the gate trench 39 of the first outer trench gate structure 37 onto the first principal surface 3. The gate lead-out electrode layer 41a is led out along the second direction Y.

Specifically, the gate lead-out electrode layer 41a is formed in an interior of the interlayer insulating layer 79. The gate lead-out electrode layer 41a is led out onto the first insulating layer 80 and interposed in a region between the first insulating layer 80 and the second insulating layer 81. The gate lead-out electrode layer 41a is electrically connected to the gate wiring 19 (see FIG. 1) in a region which is not shown. A gate signal applied to the gate terminal electrode 14 is transmitted to the gate electrode layer 41 via the gate wiring 19 and the gate lead-out electrode layer 41a.

With reference to FIG. 9, the emitter potential electrode layer 76 of the emitter trench structure 73 has a lead-out electrode layer 76a which is led out from the emitter trench 74 onto the first principal surface 3. The emitter potential electrode layer 76 is led out along the second direction Y.

Specifically, the lead-out electrode layer 76a is formed in an interior of the interlayer insulating layer 79. The lead-out electrode layer 76a is led out onto the first insulating layer 80 and interposed in a region between the first insulating layer 80 and the second insulating layer 81. The lead-out electrode layer 76a is electrically connected to the emitter terminal electrode 13. An emitter signal applied to the lead-out electrode layer 76a is transmitted to the emitter potential electrode layer 76 via the lead-out electrode layer 76a.

With reference to FIG. 7 and FIG. 8, the interlayer insulating layer 79 includes an emitter opening 83. The emitter opening 83 exposes the contact trench 48. The emitter opening 83 is in communication with the contact trench 48. In this preferred embodiment, the contact trench 48 is formed in the first principal surface 3 upon penetrating through the first insulating layer 80 and the second insulating layer 81.

The emitter opening 83 penetrates through the third insulating layer 82 and exposes the contact trench 48. The emitter opening 83 forms a single opening with the contact trench 48. An opening edge portion of the emitter opening 83 is formed in a shape curved toward the inside of the interlayer insulating layer 79. The emitter opening 83 thereby has an opening width greater than an opening width of the contact trench 48.

With reference to FIG. 8, the interlayer insulating layer 79 includes a diode opening 84. The diode opening 84 exposes the diode region 9. Specifically, the diode opening 84 penetrates through the interlayer insulating layer 79 and exposes the plurality of anode regions 62 (diode cell regions 69) and the plurality of cell separating structures 63.

A portion of an inner wall of each diode opening 84 that extends along the second direction Y may be positioned above the anode region 62. The portion of the inner wall of the diode opening 84 that extends along the second direction Y may be positioned above the anode separating structure 63. In this preferred embodiment, the portion of the inner wall of the diode opening 84 that extends along the second direction Y is positioned above the body region 45 of the dummy FET structure 42.

With reference to FIG. 9, the interlayer insulating layer 79 includes a first opening 86. The first opening 86 exposes the lead-out electrode layer 76a in the IGBT region 8. The first opening 86 is formed so as to become narrower in opening width from the opening side toward the bottom wall side.

With reference to FIG. 7 and FIG. 8, the semiconductor device 1 includes an emitter plug electrode 91 embedded in a portion of the interlayer insulating layer 79 which covers the IGBT region 8. The emitter plug electrode 91 penetrates through the interlayer insulating layer 79 and is electrically connected to the emitter region 46 and the contact region 49. Specifically, the emitter plug electrode 91 is embedded in the contact trench 48. The emitter plug electrode 91 is electrically connected to the emitter region 46 and the contact region 49 inside the contact trench 48.

In this preferred embodiment, the emitter plug electrode 91 has a laminated structure which includes a barrier electrode layer 92 and a principal electrode layer 93. The barrier electrode layer 92 is formed as a film along an inner wall of the contact trench 48 so as to be in contact with the interlayer insulating layer 79. The barrier electrode layer 92 demarcates a recess space inside the contact trench 48.

The barrier electrode layer 92 may have a single layer structure that includes a titanium layer or a titanium nitride layer. The barrier electrode layer 92 may have a laminated structure that includes a titanium layer and a titanium nitride layer. In this case, the titanium nitride layer may be laminated on the titanium layer.

The principal electrode layer 93 is embedded across the barrier electrode layer 92 in the contact trench 48. Specifically, the principal electrode layer 93 is embedded in a recess space of the contact trench 48 which is demarcated by the barrier electrode layer 92. The principal electrode layer 93 may contain tungsten.

With reference to FIG. 9, the semiconductor device 1 includes a first plug electrode 94 which is embedded in the first opening 86. The first plug electrode 94 is electrically connected to the lead-out electrode layer 76a inside the first opening 86. The first plug electrode 94 has a structure corresponding to the emitter plug electrode 91. A description of the emitter plug electrode 91 shall be applied to a description of the first plug electrode 94. Structures corresponding to the structures described for the emitter plug electrode 91 in the first plug electrode 94 shall be given the same reference signs, with the description thereof omitted.

With reference to FIG. 7 to FIG. 9, the emitter terminal electrode 13 described above is formed on the interlayer insulating layer 79. The emitter terminal electrode 13 may contain at least one type of material among aluminum, copper, an aluminum-silicon-copper alloy, an aluminum-silicon alloy, and an aluminum-copper alloy.

The emitter terminal electrode 13 may have a single layer structure which contains at least one type among these conductive materials. The emitter terminal electrode 13 may have a laminated structure in which at least two types among these conductive materials are laminated in an arbitrary order.

A thickness of the emitter terminal electrode 13 may be not less than 1.0 μm and not more than 6.0 μm. The thickness of the emitter terminal electrode 13 may be not less than 1.0 μm and not more than 2.0 μm, not less than 2.0 μm and not more than 4.0 μm, or not less than 4.0 μm and not more than 6.0 μm.

In this preferred embodiment, the emitter terminal electrode 13 has a laminated structure which includes a first electrode layer 22, a second electrode layer 23 and a third electrode layer 24 that are laminated in that order from the first principal surface 3 side. The first electrode layer 22 preferably contains an aluminum-silicon-copper alloy (Al—Si—Cu). The second electrode layer 23 preferably contains titanium nitride (TiN). The second electrode layer 23 may be referred to as a barrier layer. The third electrode layer 24 preferably contains an aluminum-copper alloy (Al—Cu).

The emitter terminal electrode 13 is electrically connected to the emitter region 46 and the contact region 49 on the interlayer insulating layer 79 via the emitter plug electrode 91. Specifically, the emitter terminal electrode 13 enters into the emitter opening 83 from above the interlayer insulating layer 79. The emitter terminal electrode 13 is electrically connected to the emitter plug electrode 91 at the emitter opening 83. The emitter terminal electrode 13 is thereby electrically connected to the emitter region 46 and the contact region 49 via the emitter plug electrode 91.

Further, with reference to FIG. 8, the emitter terminal electrode 13 enters into the diode opening 84 from above the interlayer insulating layer 79 via an inner wall of the diode opening 84. The emitter terminal electrode 13 functions as an anode terminal electrode in the diode region 9.

The emitter terminal electrode 13 is in contact with the inner wall of the diode opening 84. The emitter terminal electrode 13 is electrically connected to the anode region 62 at the diode opening 84. The emitter terminal electrode 13 is electrically connected to the cell separating electrode layer 66 at the diode opening 84. In this preferred embodiment, the emitter terminal electrode 13 is directly connected to the anode region 62 and the cell separating electrode layer 66.

Specifically, the emitter terminal electrode 13 enters into the recess 67 (cell separating trench 64) from above the first principal surface 3 inside the diode opening 84. The emitter terminal electrode 13 is connected to the cell separating electrode layer 66 inside the recess 67. Also, the emitter terminal electrode 13 is connected to the anode region 62 on the first principal surface 3 and inside the recess 67. The emitter terminal electrode 13 forms an ohmic contact with the anode region 62.

An angle θ that the inner wall of the diode opening 84 forms with the first principal surface 3 is preferably not less than 45° and not more than 90°. The angle θ is an angle that the inner wall of the diode opening 84 forms with the first principal surface 3 inside a covering portion of the interlayer insulating layer 79 that covers the first principal surface 3.

Specifically, the angle θ is an angle that a line which joins an apex portion of the inner wall of the diode opening 84 and a base portion thereof which are positioned respectively at the opening side of the diode opening 84 and at the bottom portion side of the diode opening 84 forms with the first principal surface 3 inside the interlayer insulating layer 79.

The angle θ may be not less than 45° and not more than 50°, not less than 50° and not more than 55°, not less than 55° and not more than 60°, not less than 60° and not more than 65°, not less than 65° and not more than 70°, not less than 70° and not more than 75°, not less than 75° and not more than 80°, not less than 80° and not more than 85°, or not less than 85° and not more than 90°. The angle θ is preferably not less than 60° and not more than 90°.

When the angle θ is less than 45°, a thin film portion is formed at a portion of the interlayer insulating layer 79 which covers the diode region 9. When the thin film portion is formed in the interlayer insulating layer 79, the emitter terminal electrode 13 opposes the first principal surface 3 (and/or anode region 62 and/or cell separating electrode layer 66) across the thin film portion of the interlayer insulating layer 79. In this case, there is a possibility that as a consequence of the electric field concentrating at the thin film portions of the interlayer insulating layer 79, dielectric breakdown resistance decreases with the thin film portions of the interlayer insulating layer 79 as starting points.

Thus, in this preferred embodiment, the inner walls of the diode openings 84 are formed so that the angle θ is not less than 45° (preferably not less than) 60° to suppress the forming of the thin film portions in the interlayer insulating layer 79. It is thereby possible to suppress a decrease in dielectric breakdown resistance due to an undesirable electric field concentration.

With reference to FIG. 9, the emitter terminal electrode 13 is electrically connected to the first plug electrode 94 on the interlayer insulating layer 79. The emitter signal is transmitted to the emitter potential electrode layer 76 via the first plug electrode 94.

Although a specific illustration is omitted, when a lead wire (for example, bonding wire) is to be connected to the emitter terminal electrode 13, a single layer electrode which is constituted of a nickel layer or a gold layer or a laminated electrode which includes a nickel layer and a gold layer may be formed on the emitter terminal electrode 13. In the laminated electrode, the gold layer may be formed on the nickel layer.

Although a specific illustration is omitted, the gate terminal electrode 14, the first sense terminal electrode 15, the second sense terminal electrode 16, the current detection terminal electrode 17 and the open terminal electrode 18 are formed on the interlayer insulating layer 79, as with the emitter terminal electrode 13.

The plurality of terminal electrodes 14 to 18 may each contain at least one type of material among aluminum, copper, an aluminum-silicon-copper alloy, an aluminum-silicon alloy and an aluminum-copper alloy. The plurality of terminal electrodes 14 to 18 may each have a single layer structure which contains one type of any of the above conductive materials. The plurality of terminal electrodes 14 to 18 may each have a laminated structure in which at least two types among the conductive materials are laminated in an arbitrary order. In this preferred embodiment, the plurality of terminal electrodes 14 to 18 contain the same conductive material as the emitter terminal electrode 13.

When a lead wire (for example, bonding wire) is to be connected to each of the plurality of terminal electrodes 14 to 18, a single layer electrode which is constituted of a nickel layer or a gold layer or a laminated electrode which includes a nickel layer and a gold layer may be formed on each of the plurality of terminal electrodes 14 to 18. In the laminated electrode, the gold layer may be formed on the nickel layer.

### [Method of Manufacturing Basic Structure 1 of Semiconductor Device]

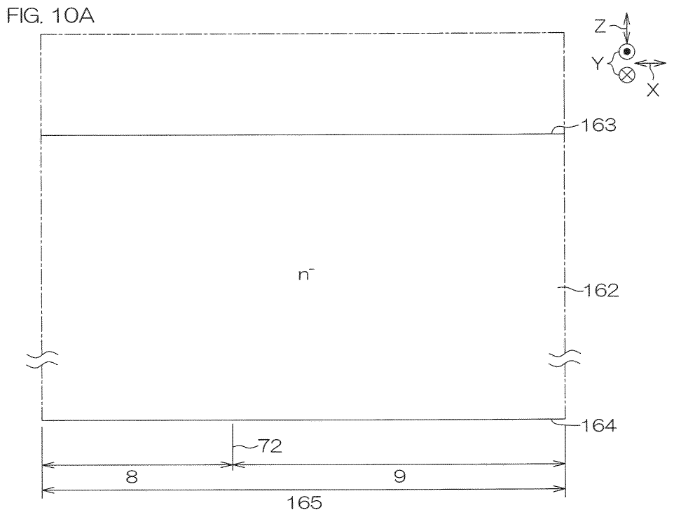

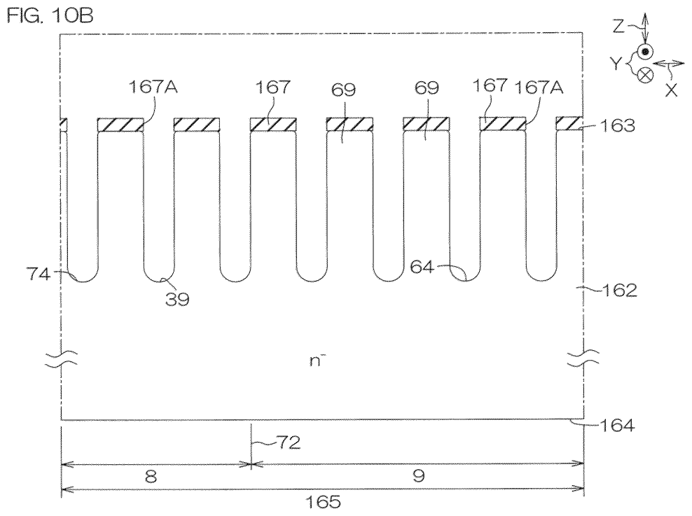

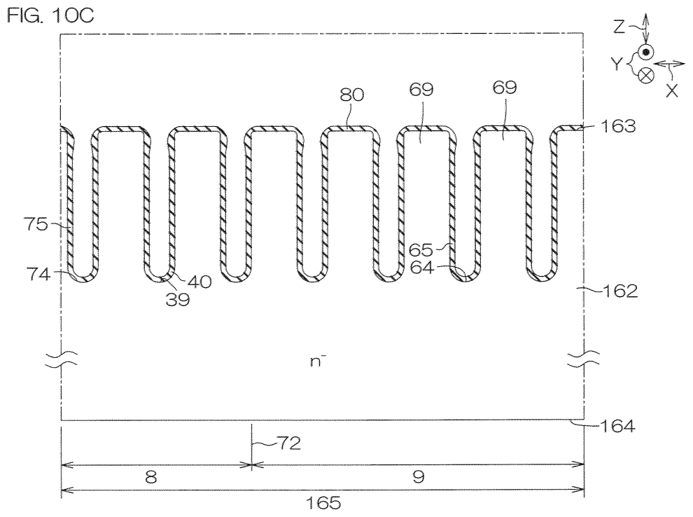

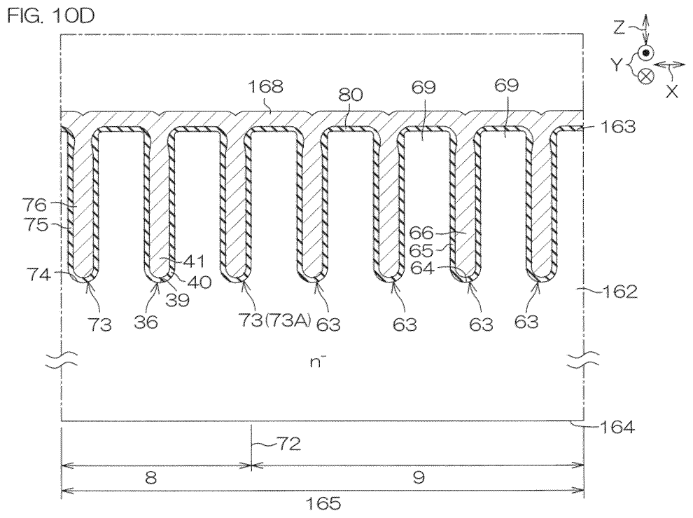

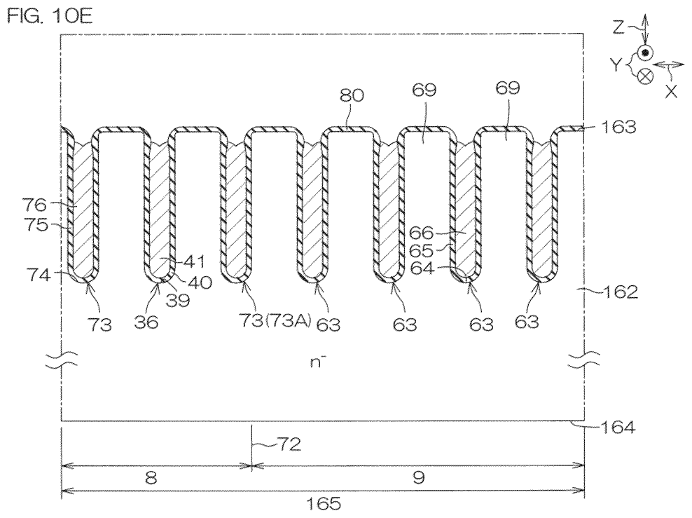

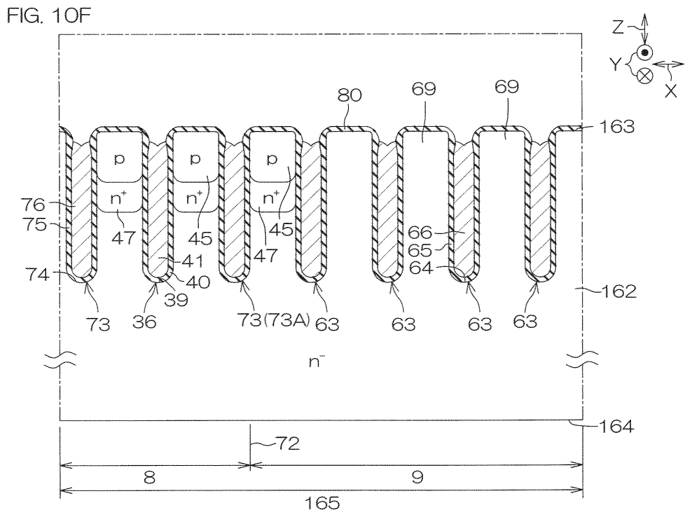

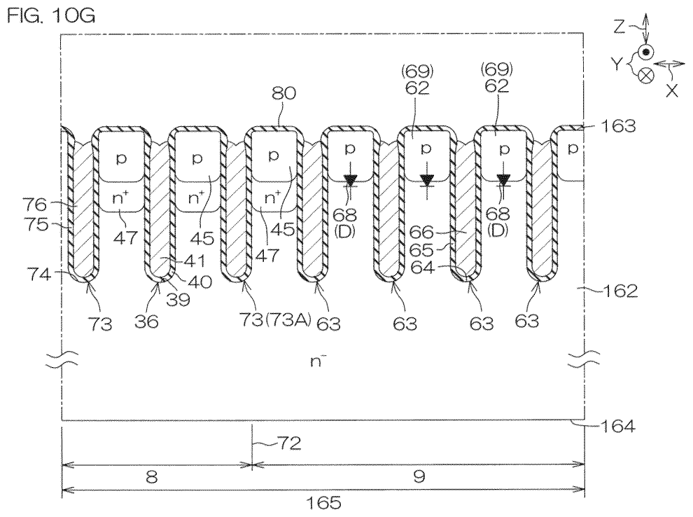

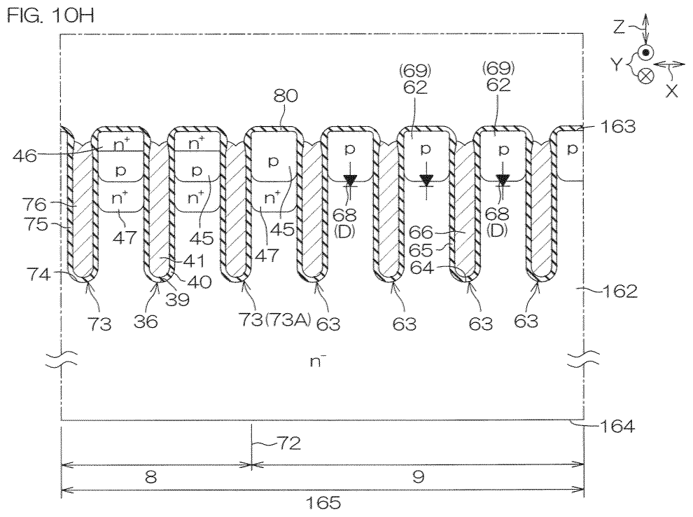

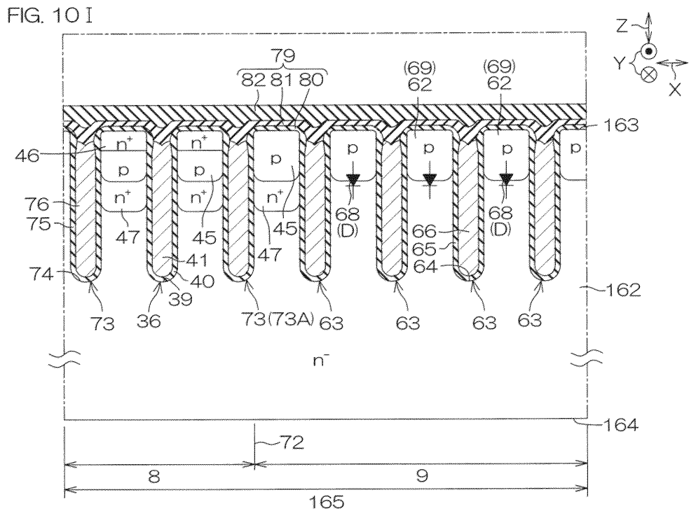

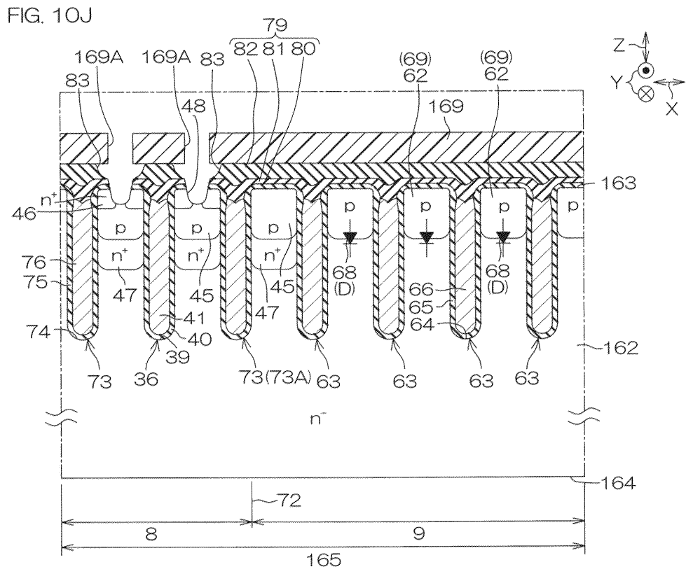

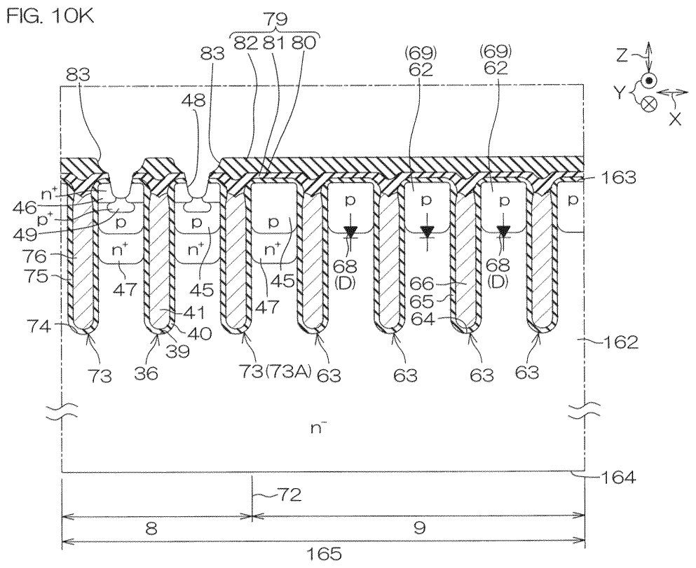

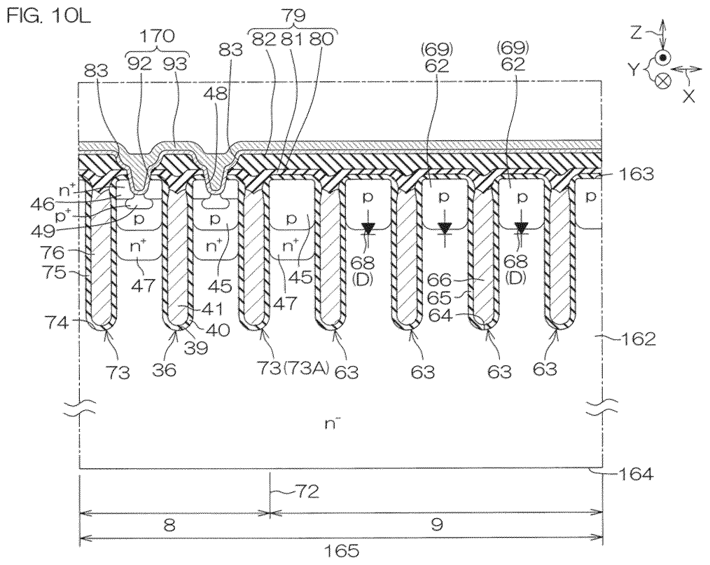

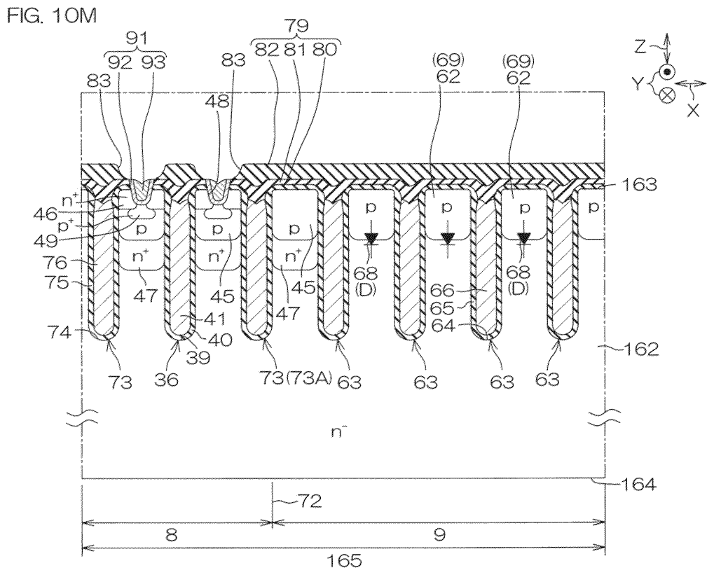

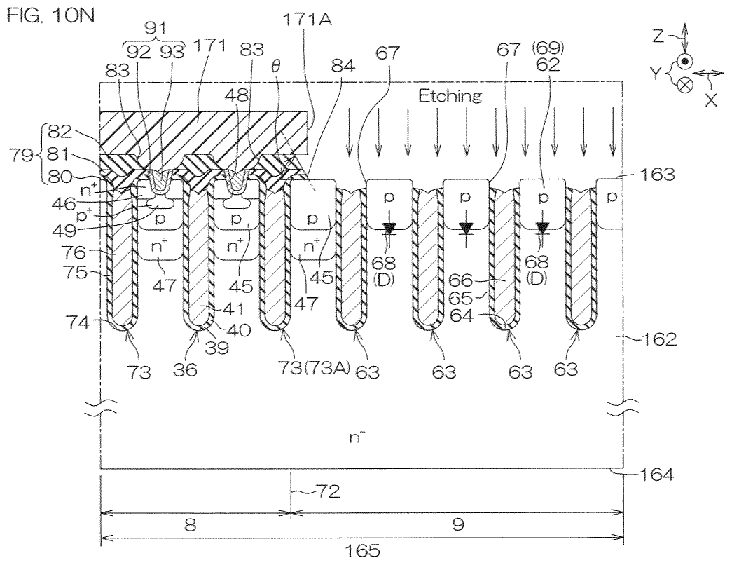

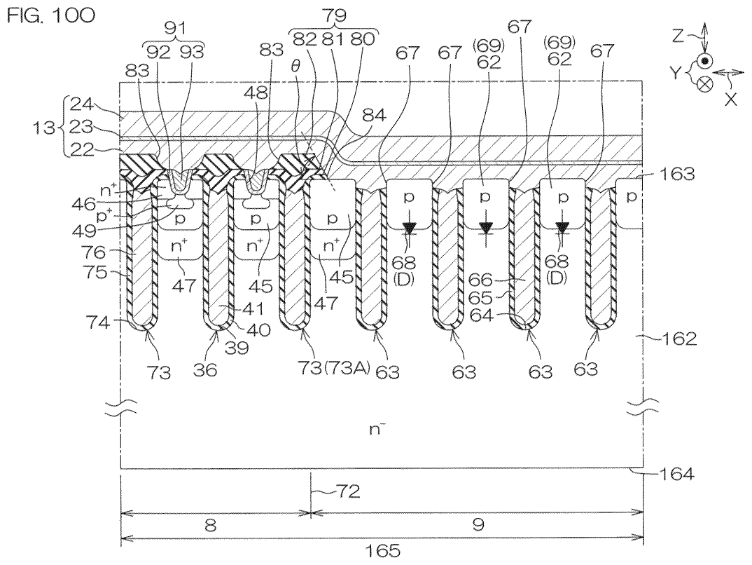

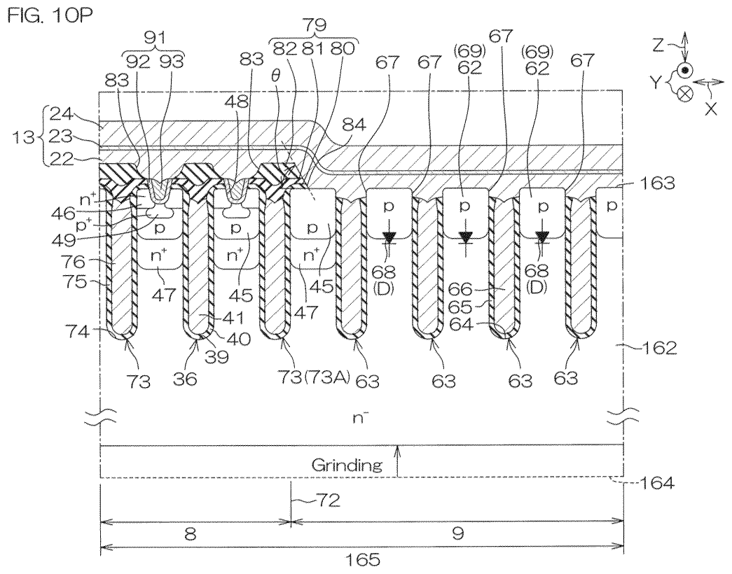

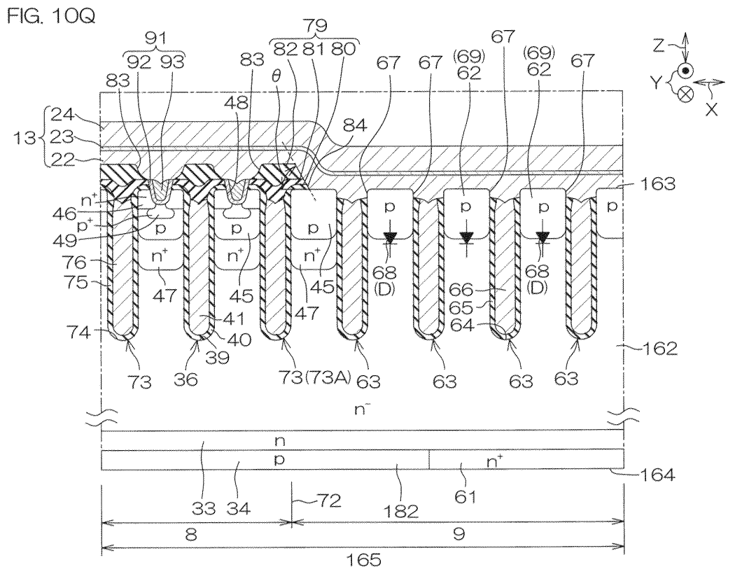

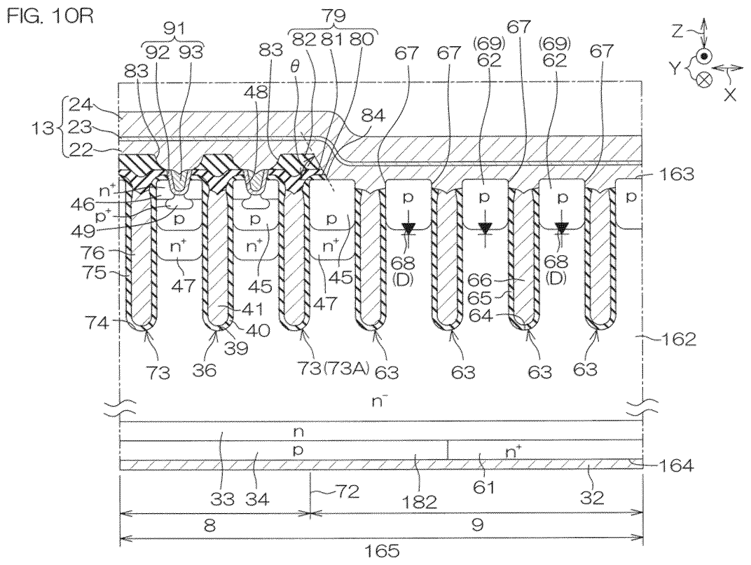

FIG. 10A to FIG. 10T are each a cross-sectional view of a region corresponding to FIG. 8, and a cross-sectional view for describing one example of a method of manufacturing the semiconductor device 1 shown in FIG. 1 (Basic Structure 1). In the following, a description shall be given of steps for manufacturing the IGBT region 8 and the diode region 9.

With reference to FIG. 10A, in manufacturing the semiconductor device 1, first, an n⁻ type semiconductor wafer 162 is prepared. The semiconductor wafer 162 has a first wafer principal surface 163 and a second wafer principal surface 164. The first wafer principal surface 163 and the second wafer principal surface 164 of the semiconductor wafer 162 respectively correspond to the first principal surface 3 and the second principal surface 4 of the semiconductor layer 2.

Next, a plurality of device forming regions 165, each of which corresponds to the semiconductor device 1, are set on the semiconductor wafer 162. Each device forming region 165 includes the active region 6 and the outer region 7. The active region 6 includes the IGBT region 8 and the diode region 9. The same structure is formed in the plurality of device forming regions 165 at the same time. After a predetermined structure is fabricated in each device forming region 165, the semiconductor wafer 162 is cut along a peripheral edge of each device forming region 165. In the following, a description shall be given of a structure of one device forming region 165.

Next, with reference to FIG. 10B, the gate trench 39 and the emitter trench 74 are formed in the IGBT region 8, and the cell separating trench 64 is formed in the diode region 9. In this step, first, a hard mask 167 having a predetermined pattern is formed on the first wafer principal surface 163. The hard mask 167 has a plurality of openings 167A which respectively expose regions in which the gate trench 39, the emitter trench 74 and the cell separating trench 64 are to be formed. The hard mask 167 may be formed by an oxidation treatment method which is performed on the first wafer principal surface 163.

Next, unnecessary portions of the semiconductor wafer 162 are removed by an etching method via the hard mask 167. Thereby, the gate trench 39 and the emitter trench 74 are formed in the IGBT region 8, and the cell separating trench 64 is formed in the diode region 9. The diode cell region 69 is demarcated in the diode region 9. Thereafter, the hard mask 167 is removed.

Next, with reference to FIG. 10C, the gate insulating layer 40, the emitter insulating layer 75, the cell separating insulating layer 65 and the first insulating layer 80 are formed in the first wafer principal surface 163. The gate insulating layer 40, the emitter insulating layer 75, the cell separating insulating layer 65 and the first insulating layer 80 may be formed by a CVD (chemical vapor deposition) method or an oxidation treatment method (for example, thermal oxidation treatment method).

Next, with reference to FIG. 10D, a base electrode layer 168 is formed. The base electrode layer 168 serves as a base for the gate electrode layer 41, the gate lead-out electrode layer 41a, the emitter potential electrode layer 76, the lead-out electrode layer 76a and the cell separating electrode layer 66. The base electrode layer 168 contains a conductive polysilicon. The base electrode layer 168 may be formed by a CVD method.

Next, with reference to FIG. 10E, unnecessary portions of the base electrode layer 168 are removed. In this step, first, a mask (not shown) having a predetermined pattern is formed on the base electrode layer 168. The mask respectively covers regions in which the gate lead-out electrode layer 41a and the lead-out electrode layer 76a are to be formed and has openings that expose regions besides these.

Next, the unnecessary portions of the base electrode layer 168 are removed by an etching method via the mask. The etching method may be a wet etching method. The unnecessary portions of the base electrode layer 168 are removed until the first insulating layer 80 is exposed. The gate electrode layer 41, the gate lead-out electrode layer 41a, the emitter potential electrode layer 76, the lead-out electrode layer 76a and the cell separating electrode layer 66 are thereby formed. Thereafter, the mask is removed.

Next, with reference to FIG. 10F, the plurality of n⁺ type carrier storage regions 47 are formed. In this step, first, an ion introducing mask (not shown) having a predetermined pattern is formed on the first wafer principal surface 163. The ion introducing mask has a plurality of openings which respectively expose regions in which the plurality of carrier storage regions 47 are to be formed.

Next, an n type impurity is introduced into the semiconductor wafer 162 via the ion introducing mask. The plurality of carrier storage regions 47 are thereby formed. Thereafter, the ion introducing mask is removed.

Next, a plurality of the p type body regions 45 are formed. In this step, first, an ion introducing mask (not shown) having a predetermined pattern is formed on the first wafer principal surface 163. The ion introducing mask has a plurality of openings which respectively expose regions in which the plurality of body regions 45 are to be formed.

Next, a p type impurity is introduced into the semiconductor wafer 162 via the ion introducing mask. The plurality of body regions 45 are formed. Thereafter, the ion introducing mask is thereby removed.

Next, with reference to FIG. 10G, the plurality of p⁻ type anode regions 62 are formed in the diode cell region 69. A p type impurity concentration of each anode region 62 is less than the p type impurity concentration of each body region 45. In this step, first, an ion introducing mask (not shown) having a predetermined pattern is formed on the first wafer principal surface 163. The ion introducing mask has a plurality of openings which respectively expose regions in which the plurality of anode regions 62 are to be formed.

Next, a p type impurity is introduced via the ion introducing mask into the semiconductor wafer 162. The plurality of anode regions 62 are thereby formed in the diode cell region 69. Thereafter, the ion introducing mask is removed.

Next, with reference to FIG. 10H, the plurality of n⁺ type emitter regions 46 are formed in the IGBT region 8. In this step, first, an ion introducing mask (not shown) having a predetermined pattern is formed on the first wafer principal surface 163. The ion introducing mask has a plurality of openings which respectively expose regions in which the plurality of emitter regions 46 are to be formed.

Next, an n type impurity is introduced via the ion introducing mask into the semiconductor wafer 162. The plurality of emitter regions 46 are thereby formed in the IGBT region 8. Thereafter, the ion introducing mask is removed.

Next, with reference to FIG. 10I, the second insulating layer 81 and the third insulating layer 82 are formed from the first wafer principal surface 163 side in that order. The second insulating layer 81 includes an NSG layer. The second insulating layer 81 may be formed by a CVD method. The third insulating layer 82 includes a BPSG layer. The third insulating layer 82 may be formed by a CVD method. The interlayer insulating layer 79 which includes the first insulating layer 80, the second insulating layer 81 and the third insulating layer 82 is thereby formed.

Next, with reference to FIG. 10J, the plurality of contact trenches 48 and the plurality of emitter openings 83 are formed in the IGBT region 8. Also, a first opening 86 is formed in the IGBT region 8 in this step.

In this step, first, a mask 169 having a predetermined pattern is formed on the interlayer insulating layer 79. The mask 169 has a plurality of openings 169A which respectively expose regions in which the contact trench 48, the emitter opening 83 and the first opening 86 are to be formed.

Next, unnecessary portions of the interlayer insulating layer 79 are removed by an etching method via the mask 169. The etching method may be a wet etching method. In this step, unnecessary portions of the third insulating layer 82, unnecessary portions of the second insulating layer 81 and unnecessary portions of the first insulating layer 80 are sequentially removed by the etching method.

In this step, after removal of the first insulating layer 80, a part of the first wafer principal surface 163 which is exposed from the mask 169 is further removed. The contact trench 48, the emitter opening 83 and the first opening 86 are thereby formed. Thereafter, the mask 169 is removed.

Next, with reference to FIG. 10K, a plurality of the p⁺ type contact regions 49 are formed in the IGBT region 8. In this step, first, an ion introducing mask (not shown) having a predetermined pattern is formed on the interlayer insulating layer 79. The ion introducing mask has a plurality of openings which respectively expose the plurality of contact trenches 48 (emitter openings 83) as regions in which the plurality of contact regions 49 are to be formed.

Next, a p type impurity is introduced via the ion introducing mask into the semiconductor wafer 162. The plurality of contact regions 49 are thereby formed in the IGBT region 8. Thereafter, the ion introducing mask is removed.

Next, with reference to FIG. 10L, a plug base electrode layer 170 is formed on the interlayer insulating layer 79. The plug base electrode layer 170 serves as a base for the emitter plug electrode 91 and the first plug electrode 94. This step includes a step of forming the barrier electrode layer 92 and the principal electrode layer 93 from the interlayer insulating layer 79 side in that order.

The step of forming the barrier electrode layer 92 includes a step of forming a titanium layer and a titanium nitride layer from the interlayer insulating layer 79 side in that order. The titanium layer and the titanium nitride layer may be each formed by a sputtering method. The barrier electrode layer 92 having a single layer structure which includes a titanium layer or a titanium nitride layer may be formed. The principal electrode layer 93 contains tungsten. The principal electrode layer 93 may be formed by a sputtering method. The plug base electrode layer 170 is thereby formed on the interlayer insulating layer 79.

Next, with reference to FIG. 10M, unnecessary portions of the plug base electrode layer 170 are removed. The unnecessary portions of the plug base electrode layer 170 may be removed by an etching method. The unnecessary portions of the plug base electrode layer 170 are removed until the interlayer insulating layer 79 is exposed.

Specifically, the unnecessary portions of the plug base electrode layer 170 are removed until the emitter opening 83 is exposed and the plug base electrode layer 170 is embedded in the contact trench 48 and the first opening 86. The emitter plug electrode 91 and the first plug electrode 94 are thereby formed.

Next, with reference to FIG. 10N, the diode opening 84 is formed in the diode region 9. In this step, first, a mask 171 having a predetermined pattern is formed on the interlayer insulating layer 79. The mask 171 has an opening 171A which exposes a region in which the diode opening 84 is to be formed.

Next, the unnecessary portions of the interlayer insulating layer 79 are removed by an etching method via the mask 171. The etching method is preferably an anisotropic etching method. The anisotropic etching method may be a dry etching method (specifically, an RIE (reactive ion etching) method).

In this step, the unnecessary portions of the first insulating layer 80, the unnecessary portions of the second insulating layer 81 and the unnecessary portions of the third insulating layer 82 are sequentially removed by the anisotropic etching method. The diode opening 84 is thereby formed. Also, a recess 67 is formed inside the cell separating trench 64. Thereafter, the mask 171 is removed.

In the step of forming the diode opening 84, processing conditions of the anisotropic etching method are adjusted so that an angle θ that the inner wall of the diode opening 84 forms with the first wafer principal surface 163 inside the interlayer insulating layer 79 is not less than 45° and not more than 90°.

The angle θ may be not less than 45° and not more than 50°, not less than 50° and not more than 55°, not less than 55° and not more than 60°, not less than 60° and not more than 65°, not less than 65° and not more than 70°, not less than 70° and not more than 75°, not less than 75° and not more than 80°, not less than 80° and not more than 85°, or not less than 85° and not more than 90°. The angle θ is preferably not less than 60° and not more than 90°.

Next, with reference to FIG. 10O, the emitter terminal electrode 13, a gate terminal electrode 14, the first sense terminal electrode 15, the second sense terminal electrode 16, the current detection terminal electrode 17 and the open terminal electrode 18 are formed on the first wafer principal surface 163.

In this step, first, a base terminal electrode layer which serves as a base of the plurality of terminals 13 to 18 is formed. The base terminal electrode layer contains an aluminum-silicon-copper alloy. The base terminal electrode layer may be formed by a sputtering method.

Next, a mask (not shown) having a predetermined pattern is formed on the base terminal electrode layer. The mask respectively covers regions in which the plurality of terminals 13 to 18 are to be formed and has openings that expose regions besides these. Next, unnecessary portions of the base terminal electrode layer are removed by an etching method via the mask. The etching method may be a wet etching method. The plurality of terminals 13 to 18 are thereby formed. Thereafter, the mask is removed.

Next, with reference to FIG. 10P, the semiconductor wafer 162 is thinned to a predetermined thickness. The thinning step includes a step of thinning the semiconductor wafer 162 by a grinding method performed on the second wafer principal surface 164. The grinding method may be a CMP (chemical mechanical polishing) method.

The thinning step may include a step of thinning the semiconductor wafer 162 by an etching method performed on the second wafer principal surface 164 in place of the grinding method. The etching method may be a wet etching method.

The thinning step may include a step of thinning the semiconductor wafer 162 by a grinding method and an etching method performed on the second wafer principal surface 164. The semiconductor wafer 162 may be thinned by performing the grinding method and the etching method in this order. The semiconductor wafer 162 may be thinned by performing the etching method and the grinding method in this order.

When only the grinding method is performed, the second wafer principal surface 164 of the semiconductor wafer 162 becomes a ground surface having grinding marks. In this case, the second principal surface 4 of the semiconductor layer 2 becomes a ground surface having grinding marks. The thinning step of the semiconductor wafer 162 is performed when necessary and may be omitted.

Next, with reference to FIG. 10Q, the n type buffer layer 33 is formed in the surface layer portion of the second wafer principal surface 164. In this step, an n type impurity is introduced into an entirety of the second wafer principal surface 164 of the semiconductor wafer 162. The n type buffer layer 33 is thereby formed.

Next, the p type collector region 34 is formed in the surface layer portion of the second wafer principal surface 164. In this step, first, an ion introducing mask (not shown) having a predetermined pattern is formed on the second wafer principal surface 164. The ion introducing mask has an opening which exposes a region in which the collector region 34 is to be formed. Next, a p type impurity is introduced via the ion introducing mask into the second wafer principal surface 164. The collector region 34 is thereby formed. Thereafter, the ion introducing mask is removed.

Next, a plurality of the n⁺ type cathode regions 61 are formed in the surface layer portion of the second wafer principal surface 164. In this step, first, an ion introducing mask (not shown) having a predetermined pattern is formed on the second wafer principal surface 164. The ion introducing mask has a plurality of openings which respectively expose regions in which the plurality of cathode regions 61 are to be formed. Next, an n type impurity is introduced via the ion introducing mask into the second wafer principal surface 164. The plurality of cathode regions 61 are thereby formed. Thereafter, the ion introducing mask is removed.

Next, with reference to FIG. 10R, the collector terminal electrode 32 is formed in the second wafer principal surface 164. The collector terminal electrode 32 may include at least one among a Ti layer, an Ni layer, an Au layer, an Ag layer and an Al layer. The collector terminal electrode 32 may be formed by a sputtering method. Thereafter, the semiconductor wafer 162 is cut along a peripheral edge of each device forming region 165 and the semiconductor device 1 is cut out. Through the steps including the above, the semiconductor device 1 according to Basic Structure 1 is manufactured.

An annealing treatment may be performed on the second wafer principal surface 164 after the step of thinning the semiconductor wafer 162 and prior to the step of forming the collector terminal electrode 32. The annealing treatment may be a laser annealing treatment. In this case, an Si amorphous layer may be formed in the surface layer portion of the second wafer principal surface 164. Also, in this case, a lattice defect region including lattice defects may be formed in a surface layer portion of the second wafer principal surface 164.

The Si amorphous layer may be formed in the surface layer portion of the second principal surface 4 of the semiconductor layer 2 that has been cut out from the semiconductor wafer 162. Also, the lattice defect region including lattice defects may be formed in the surface layer portion of the second principal surface 4 of the semiconductor layer 2. According to the above structure, it is possible to enhance an ohmic property of the collector terminal electrode 32 with respect to the second principal surface 4 (the collector region 34 and the cathode region 61).

### [Basic Structure 2 of Semiconductor Device]

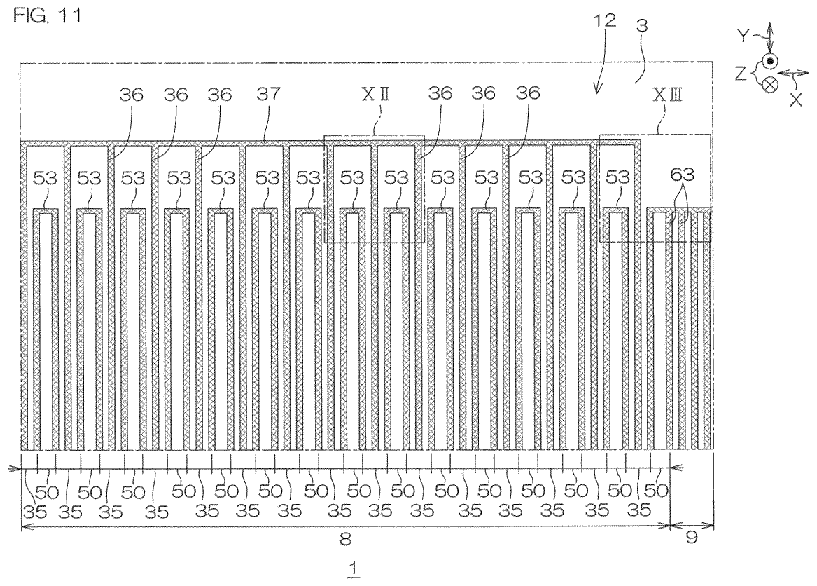

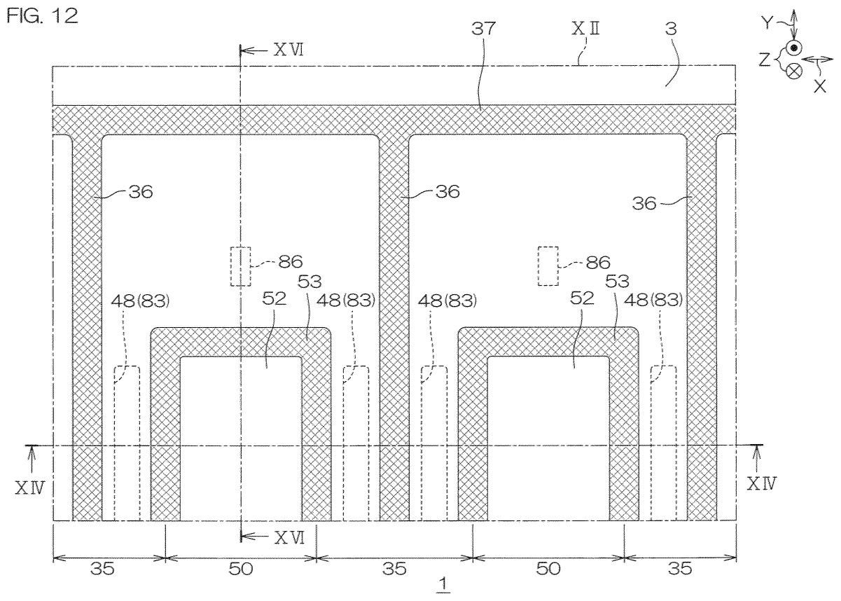

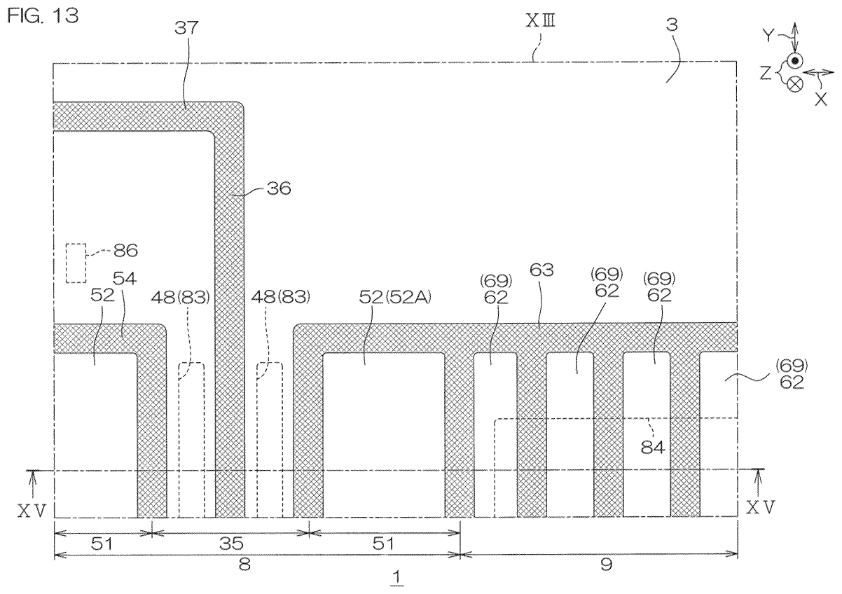

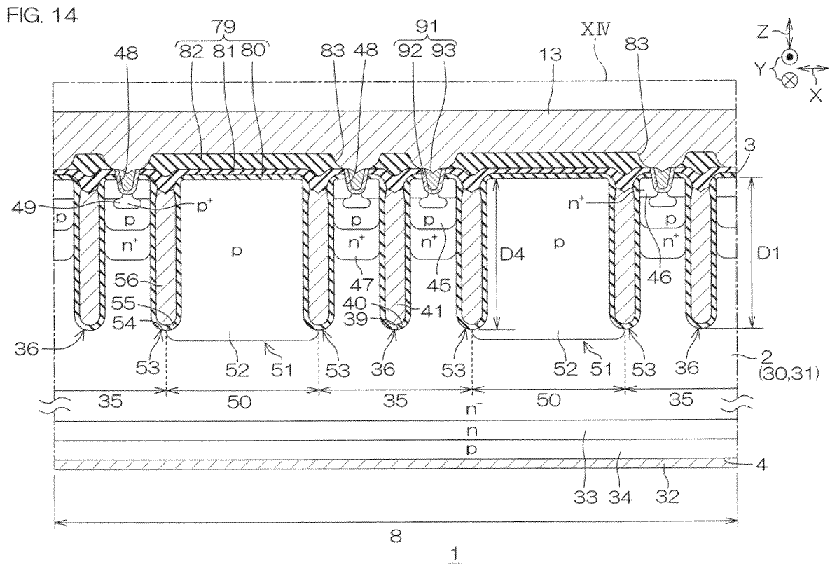

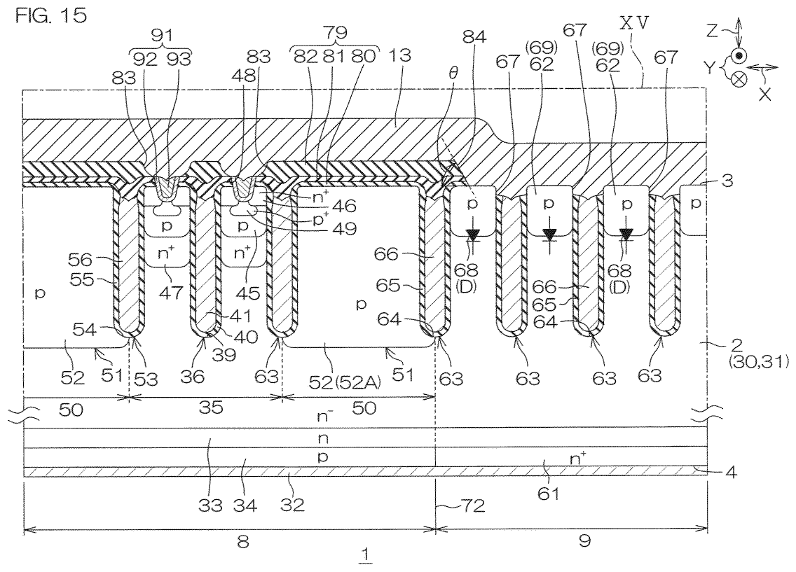

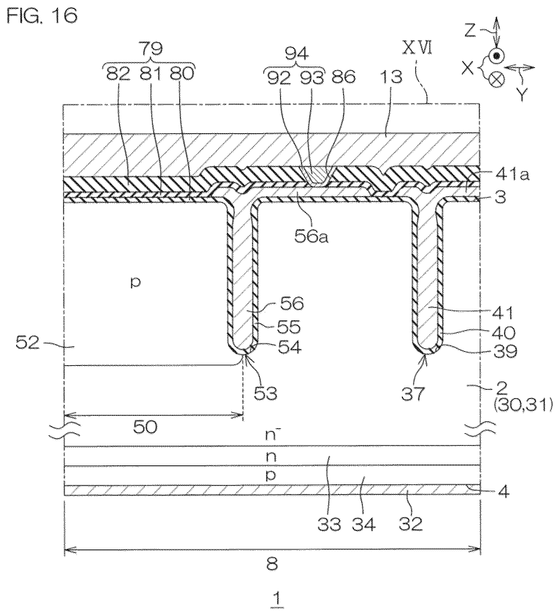

FIG. 11 is a schematic enlarged plan view which shows a part of Basic Structure 2 of the semiconductor device 1, and an enlarged view of a portion corresponding to FIG. 4. FIG. 12 is an enlarged view of a portion which is surrounded by an alternate long and short dashed line XII in FIG. 11. FIG. 13 is an enlarged view of a portion which is surrounded by an alternate long and short dashed line XIII in FIG. 11. FIG. 14 is a cross-sectional view taken along line XIV-XIV in FIG. 12. FIG. 15 is a cross-sectional view taken along line XV-XV in FIG. 13. FIG. 16 is a cross-sectional view taken along line XVI-XVI in FIG. 12.

Structures of the IGBT region 8 and the diode region 9 of the semiconductor device 1 may be Basic Structure 2 which is shown in FIG. 11 to FIG. 16 in place of Basic Structure 1 shown in FIG. 4 to FIG. 9. In the following, Basic Structure 2 of the semiconductor device 1 shall be described with reference to FIG. 11 to FIG. 16. A structure common to the structure described in the aforementioned Basic Structure 1 shall be given the same reference sign, and a description thereof shall be omitted.

Mainly with reference to FIG. 11, FIG. 12 and FIG. 14, in Basic Structure 2 of the semiconductor device 1, each IGBT region 8 includes a region separating structure 50 which demarcates the FET structure 35 from other regions in the first principal surface 3 of the semiconductor layer 2. Specifically, each IGBT region 8 includes a plurality of the region separating structures 50 which are formed at both sides of the FET structure 35. The region separating structure 50 is formed in a region adjacent to the FET structure 35 in a surface layer portion of the first principal surface 3. The region separating structure 50 is each formed in a region between the plurality of FET structures 35 that are adjacent to each other. Thereby, the plurality of FET structures 35 are each separated by the region separating structure 50.

In the IGBT region 8, an IE (injection enhanced: carrier injection enhanced) structure 51 is formed by the FET structure 35 and the region separating structure 50. In the IE structure 51, the plurality of FET structures 35 are disposed in a mode of being separated from each other by the region separating structure 50.

The region separating structure 50 restricts a movement of holes injected into the semiconductor layer 2. That is, the holes bypass the region separating structure 50 and flow into the FET structure 35. Thereby, the holes are accumulated in a region of the semiconductor layer 2 directly below the FET structure 35 and the holes are increased in density. As a result, a decrease in on-resistance and a decrease in on-voltage are achieved.

The region separating structure 50 includes a p⁺ type floating region 52 which is formed in a region adjacent to the FET structure 35 in the surface layer portion of the first principal surface 3 of the semiconductor layer 2. The floating region 52 is formed in an electrically floating state. A p type impurity concentration of the floating region 52 may be not less than a p type impurity concentration of the body region 45. The p type impurity concentration of the floating region 52 may be greater than the p type impurity concentration of the body region 45 and that of the anode region 62. The p type impurity concentration of the floating region 52 may be not less than 1.0×10¹⁶ cm⁻³ and not more than 1.0×10²⁰ cm⁻³. The p type impurity concentration of the floating region 52 is preferably not less than 1.0×10¹⁸ cm⁻³ and not more than 1.0×10²⁰ cm⁻³.

A bottom portion of the floating region 52 is formed in a region between a bottom portion of the carrier storage region 47 and the second principal surface 4 with regard to the normal direction Z. In this preferred embodiment, the bottom portion of the floating region 52 is formed in a region between a bottom wall of the gate trench 39 and the second principal surface 4 with regard to the normal direction Z. The floating region 52 is formed as a band extending along the FET structure 35 in a plan view. With regard to the second direction Y, a length of the floating region 52 is smaller than the length of the gate trench 39.

The region separating structure 50 includes a region separating trench structure 53 which demarcates the floating region 52 from the FET structure 35. The region separating trench structure 53 is formed in an annular shape (quadrilateral annular shape in this preferred embodiment) which surrounds the floating region 52 in a plan view.

The region separating trench structure 53 includes a region separating trench 54, the region separating insulating layer 55 and a region separating electrode layer 56. The region separating trench 54 is formed in the first principal surface 3 of the semiconductor layer 2. The region separating trench 54 includes side walls and a bottom wall. The side wall of the region separating trench 54 may be formed perpendicular to the first principal surface 3.

The side wall of the region separating trench 54 may be downwardly inclined from the first principal surface 3 toward the bottom wall. The region separating trench 54 may be formed in a tapered shape in which an opening area at the opening side is larger than a bottom area. A bottom wall of the region separating trench 54 may be formed parallel to the first principal surface 3. The bottom wall of the region separating trench 54 may be formed in a shape curved toward the second principal surface 4. The bottom wall of the region separating trench 54 is covered by the bottom portion of the floating region 52. That is, the floating region 52 has a covering portion which covers the bottom wall of the region separating trench 54. The region separating trench 54 includes a bottom wall edge portion. The bottom wall edge portion connects the side walls and the bottom wall of the region separating trench 54. The bottom wall edge portion may be formed in a shape curved toward the second principal surface 4 of the semiconductor layer 2.

A depth D4 of the region separating trench 54 may be not less than 2 μm and not more than 10 μm. The depth D4 of the region separating trench 54 may be not less than 2 μm and not more than 3 μm, not less than 3 μm and not more than 4 μm, not less than 4 μm and not more than 5 μm, not less than 5 μm and not more than 6 μm, not less than 6 μm and not more than 7 μm, not less than 7 μm and not more than 8 μm, not less than 8 μm and not more than 9 μm, or not less than 9 μm and not more than 10 μm. The depth D4 of the region separating trench 54 may be equal to the depth D1 of the gate trench 39.

A width of the region separating trench 54 may be not less than 0.5 μm and not more than 3 μm. The width of the region separating trench 54 is a width of the region separating trench 54 in the first direction X. The width of the region separating trench 54 may be not less than 0.5 μm and not more than 1 μm, not less than 1 μm and not more than 1.5 μm, not less than 1.5 μm and not more than 2 μm, not less than 2 μm and not more than 2.5 μm, or not less than 2.5 μm and not more than 3 μm. The width of the region separating trench 54 may be equal to the width of the gate trench 39.

The region separating insulating layer 55 is formed as a film along an inner wall of the region separating trench 54. The region separating insulating layer 55 demarcates a recess space inside the region separating trench 54. In this preferred embodiment, the region separating insulating layer 55 includes a silicon oxide film. The region separating insulating layer 55 may include a silicon nitride film in place of or in addition to the silicon oxide film.

The region separating electrode layer 56 is embedded across the region separating insulating layer 55 in the region separating trench 54. Specifically, the region separating electrode layer 56 is embedded in a recess space of the region separating trench 54 which is demarcated by the region separating insulating layer 55. The region separating electrode layer 56 is controlled by an emitter signal. The region separating electrode layer 56 may contain a conductive polysilicon.

The region separating electrode layer 56 is formed in a wall shape extending along the normal direction Z in sectional view. The region separating electrode layer 56 has an upper end portion which is positioned at the opening side of the region separating trench 54. The upper end portion of the region separating electrode layer 56 is positioned at the bottom wall side of the region separating trench 54 with respect to the first principal surface 3.

A depression which is depressed toward the bottom wall of the region separating trench 54 is formed at an upper end portion of the region separating electrode layer 56. The depression at the upper end portion of the region separating electrode layer 56 is formed in a convergent shape directed toward the bottom wall of the region separating trench 54. The upper end portion of the region separating electrode layer 56 has a constricted portion which is constricted to the inside of the region separating electrode layer 56.

Mainly with reference to FIG. 13 and FIG. 15, the plurality of floating regions 52 each include a proximate floating region 52A which is most proximate to the diode region 9. In this preferred embodiment, the proximate floating region 52A is demarcated from the FET structure 35 and the anode region 62 by the cell separating structure 63.

The proximate floating region 52A overlaps entirely with the collector region 34 in the normal direction Z. That is, the cell separating structure 63 which demarcates the proximate floating region 52A overlaps with the collector region 34 in the normal direction Z. In this preferred embodiment, the boundary 72 between the IGBT region 8 and the diode region 9 is demarcated by a portion extending in a region of the cell separating structure 63 between the proximate floating region 52A and the anode region 62.

As a matter of course, the proximate floating region 52A may be demarcated from the FET structure 35 and the anode region 62 by the region separating trench structure 53 in place of the cell separating structure 63. In this case, the boundary 72 between the IGBT region 8 and the diode region 9 is demarcated by a portion extending in a region of the region separating trench structure 53 between the proximate floating region 52A and the anode region 62.

The proximate floating region 52A may be omitted. In this case, the boundary 72 between the IGBT region 8 and the diode region 9 is demarcated by a portion extending along a region of the cell separating structure 63 between the FET structure 35 and the anode region 62.

Mainly with reference to FIG. 12 and FIG. 16, the region separating electrode layer 56 of the region separating structure 50 has a separating lead-out electrode layer 56a which is led out from the region separating trench 54 onto the first principal surface 3. The region separating electrode layer 56 is led out along the second direction Y. Specifically, the separating lead-out electrode layer 56a is formed in an interior of the interlayer insulating layer 79. The separating lead-out electrode layer 56a is led out onto the first insulating layer 80 and interposed in a region between the first insulating layer 80 and the second insulating layer 81. The separating lead-out electrode layer 56a is electrically connected to the emitter terminal electrode 13 via the first plug electrode 94. An emitter signal applied to the separating lead-out electrode layer 56a is transmitted to the region separating electrode layer 56 via the separating lead-out electrode layer 56a.

### [Method of Manufacturing Basic Structure 2 of Semiconductor Device]

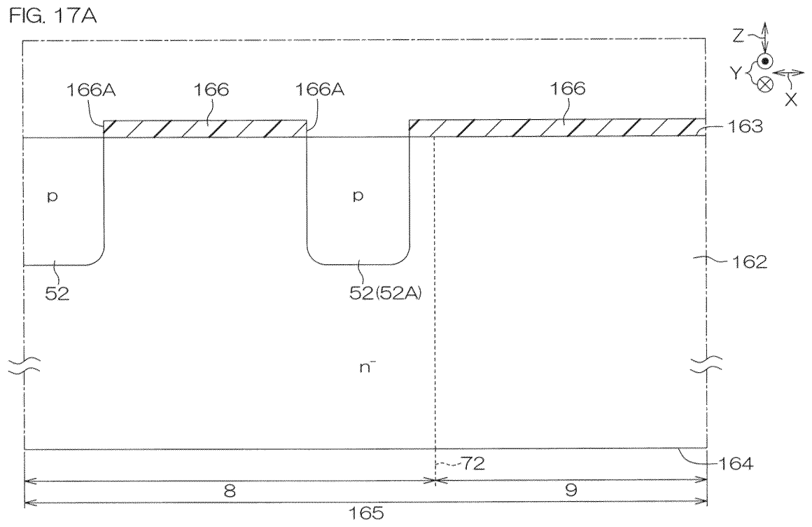

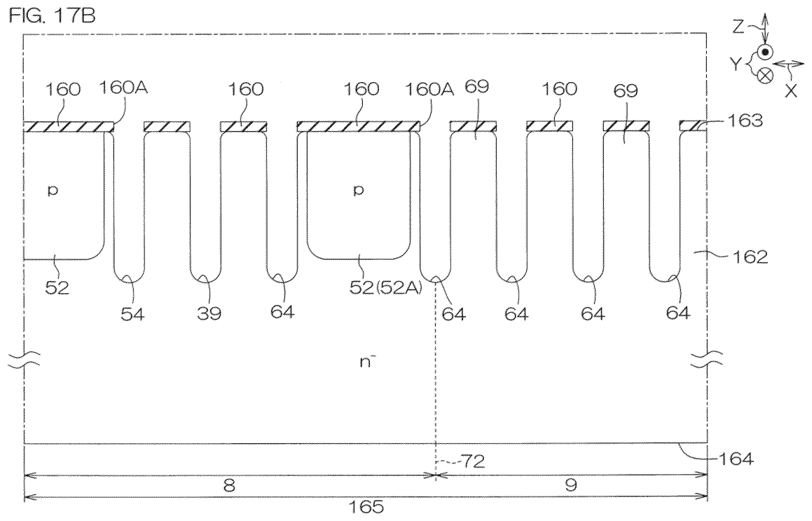

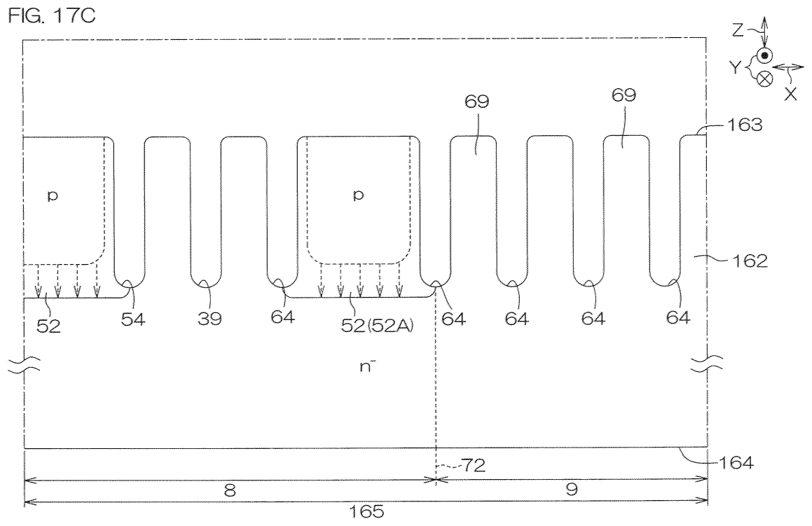

FIG. 17A to FIG. 17C are each a cross-sectional view of a region corresponding to FIG. 15, and a cross-sectional view for describing one example of a method of manufacturing the semiconductor device 1 shown in FIG. 1 (Basic Structure 2). In the following, a description shall be given of steps different from the steps of manufacturing Basic Structure 1 shown in FIG. 10A to FIG. 10R, and an illustration or a description of the common steps shall be omitted.

As to the method of manufacturing the semiconductor device 1 of Basic Structure 2, for example, it suffices to replace the aforementioned steps of FIG. 10A and FIG. 10B with the steps of FIG. 17A to FIG. 17C.

First, with reference to FIG. 17A, after the device forming region 165 is set at a semiconductor wafer 162, the plurality of p⁺ type floating regions 52 are formed in the IGBT region 8. In this step, first, an ion introducing mask 166 having a predetermined pattern is formed on the first wafer principal surface 163. The ion introducing mask 166 has a plurality of openings 166A which respectively expose regions in which the plurality of floating regions 52 are to be formed.

Next, a p type impurity is introduced via the ion introducing mask 166 into the semiconductor wafer 162. The plurality of floating regions 52 are thereby formed in the IGBT region 8. Thereafter, the ion introducing mask 166 is removed.

Next, with reference to FIG. 17B, the gate trench 39 and the region separating trench 54 are formed in the IGBT region 8, and the cell separating trench 64 is formed in the diode region 9. In this step, first, a hard mask 160 having a predetermined pattern is formed on the first wafer principal surface 163. The hard mask 160 has a plurality of openings 160A which respectively expose regions in which the gate trench 39, the region separating trench 54 and the cell separating trench 64 are to be formed. The hard mask 160 may be formed by an oxidation treatment method performed on the first wafer principal surface 163.

Next, the unnecessary portions of the semiconductor wafer 162 are removed by an etching method via the hard mask 160. Thereby, the gate trench 39 and the region separating trench 54 are formed in the IGBT region 8, and the cell separating trench 64 is formed in the diode region 9. The diode cell region 69 is demarcated in the diode region 9. Thereafter, the hard mask 160 is removed.

Next, with reference to FIG. 17C, the plurality of floating regions 52 are diffused inside the semiconductor wafer 162. The plurality of floating regions 52 are diffused to a depth position which covers a bottom wall of the region separating trench 54.

Thereafter, by executing the same steps as FIG. 10C to FIG. 10R, the semiconductor device 1 according to Basic Structure 2 is manufactured.

### [Evaluation 1 on Problem of Reverse Recovery Characteristics of pn Junction Diode]

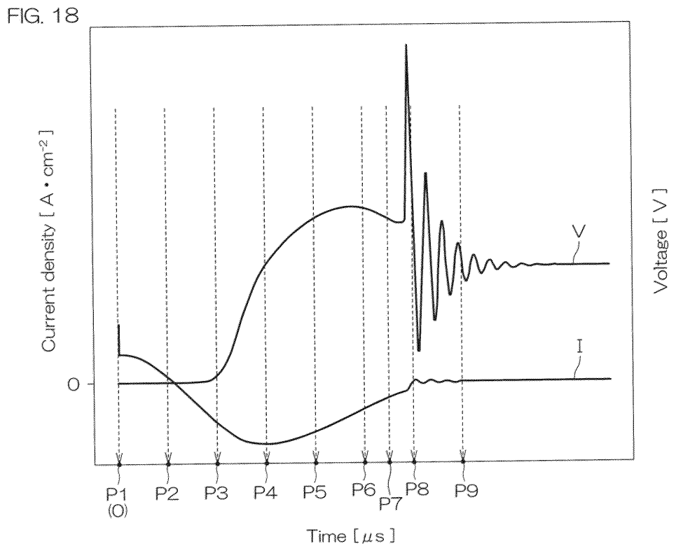

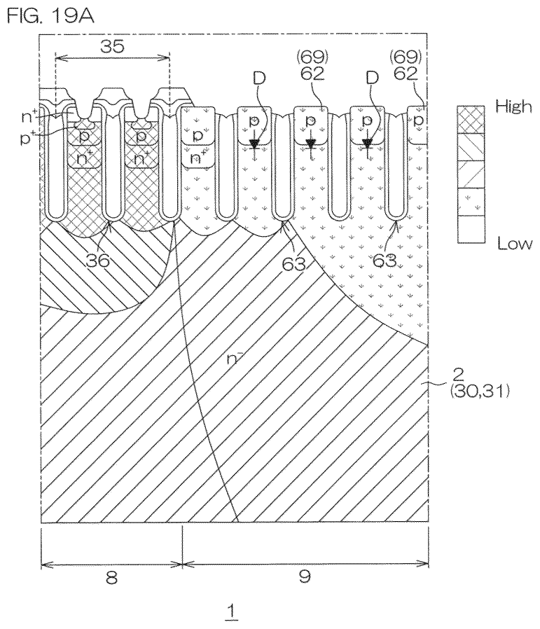

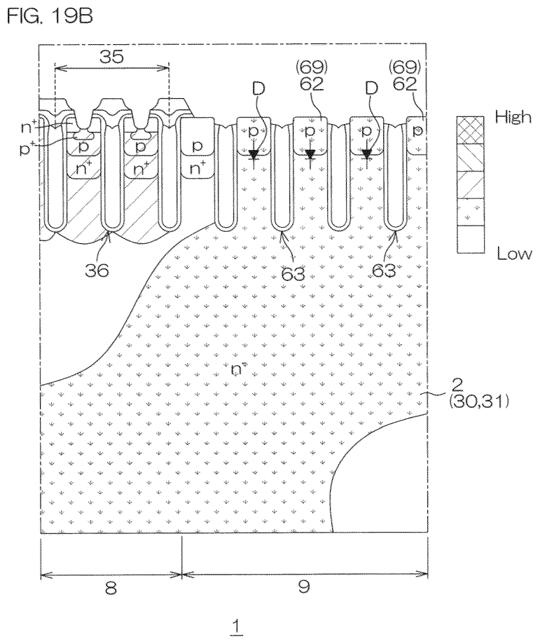

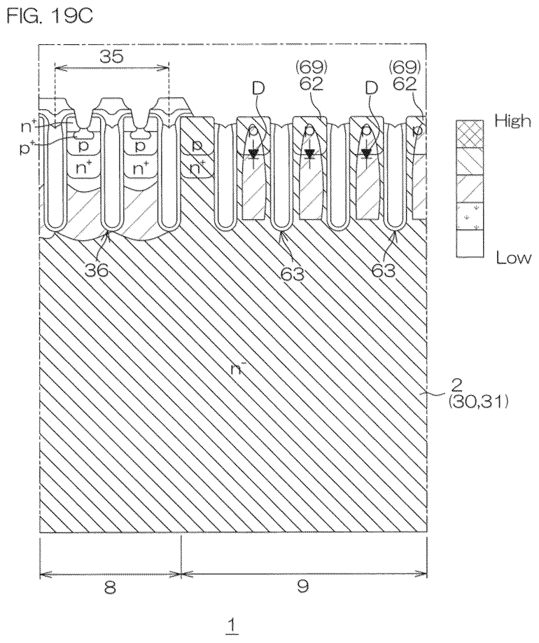

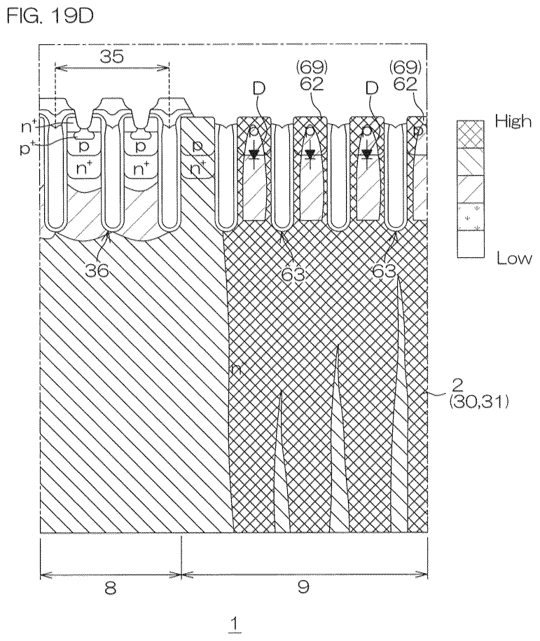

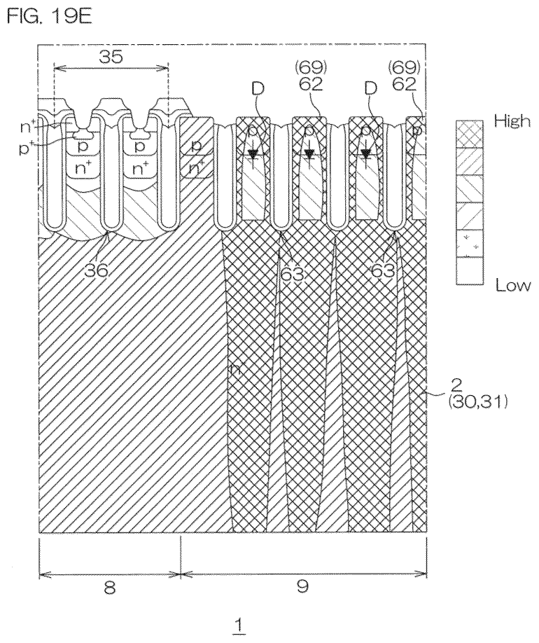

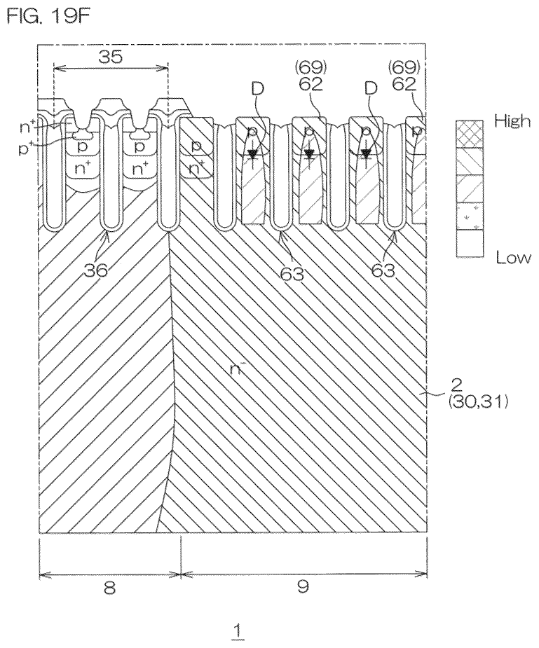

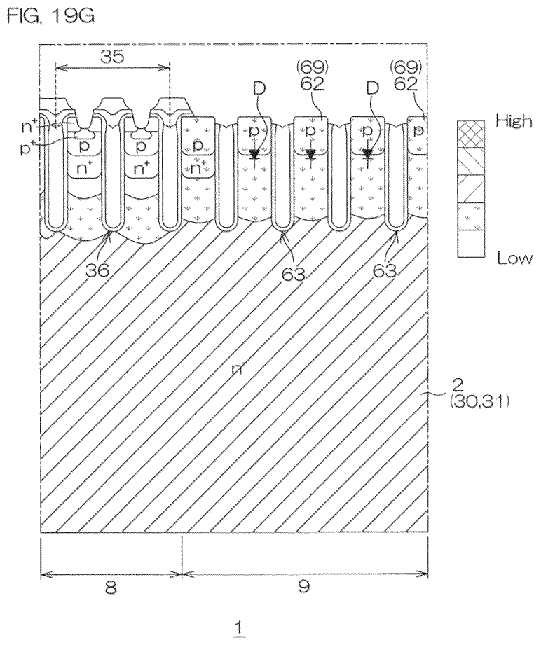

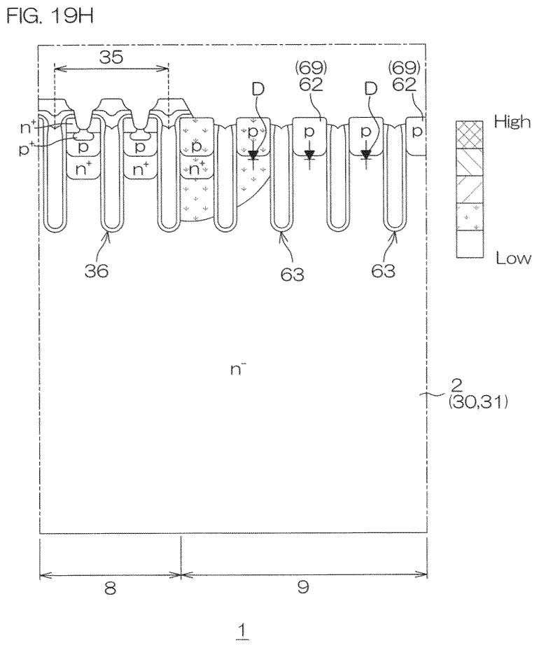

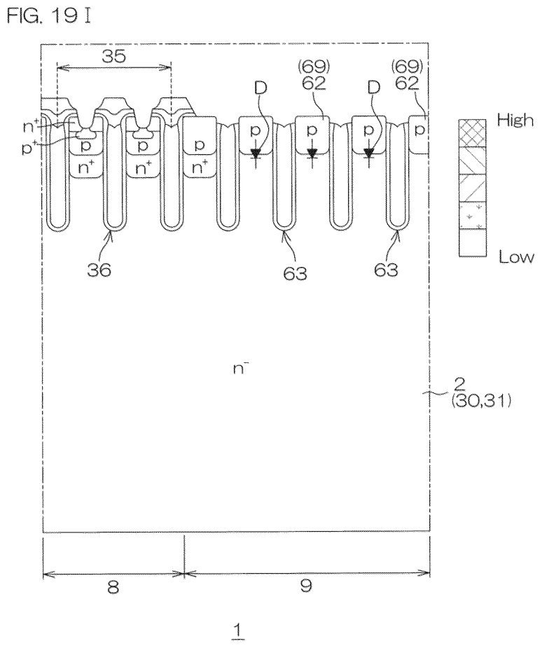

Next, various evaluations are made on a problem of reverse recovery characteristics of the pn junction diode D included in an RC-IGBT such as the semiconductor device 1 according to Basic Structure 1 and Basic Structure 2 and the evaluations are shown below. First, with reference to FIG. 18 and FIG. 19A to FIG. 19I, an evaluation is made on a factor of increasing a hole current density between the trenches of the diode region 9 at the time of reverse recovery of the pn junction diode D.

FIG. 18 is a graph of results of examining the reverse recovery characteristics of the pn junction diode D by a simulation. In FIG. 18, the vertical axis at the left side indicates a current density [A·cm⁻²], the vertical axis at the right side indicates a voltage [V], and the horizontal axis indicates time [μs].

When the pn junction diode D is switched from an on state to an off state, a reverse recovery current flows to the pn junction diode D to generate a reverse recovery voltage. In FIG. 18, reverse recovery current characteristics I and reverse recovery voltage characteristics V are each shown by a solid line. The reverse recovery current characteristics I and the reverse recovery voltage characteristics V show the characteristics of the pn junction diode D of the semiconductor device 1 according to Reference Example 1.

FIG. 19A to FIG. 19I are each a drawing of results of examining a hole current density of the semiconductor device 1 at a first measurement point P1, a second measurement point P2, a third measurement point P3, a fourth measurement point P4, a fifth measurement point P5, a sixth measurement point P6, a seventh measurement point P7, an eighth measurement point P8 and a ninth measurement point P9 shown in FIG. 18 by a simulation. In FIG. 19A to FIG. 19I, a degree of the hole current density is classified into five grades, and a distribution of the hole current density is indicated with a hatching given for each grade. It is noted that hatching is not given to a region with the lowest grade density among the five grades.

The first measurement point P1 is a phase in which, after the pn junction diode D was changed from an on state to an off state, a forward current flows to the pn junction diode D. The second measurement point P2 is a phase immediately before a current which flows through the pn junction diode D is changed from the forward current to a reverse current. The third measurement point P3 is a phase immediately before the reverse current reaches a peak. The fourth measurement point P4 is a phase in which the reverse current reaches the peak. The fifth measurement point P5 is a phase immediately after the reverse current reached the peak. The sixth measurement point P6 and the seventh measurement point P7 are each a phase in which the reverse current starts to converge. The eighth measurement point P8 is a phase immediately before the reverse current converges. The ninth measurement point P9 is a phase after the reverse current has converged.

With reference to FIG. 19A, at the first measurement point P1, while the forward current flows to the pn junction diode D, the holes which have been distributed to the IGBT region 8 and the diode region 9 are drawn back to the FET structure 35 and the anode region 62. In the IGBT region 8, the holes which are to be drawn back stay near the FET structure 35, resulting in formation of a relatively high hole density. Thereafter, with reference to FIG. 19B and FIG. 19C, at the second measurement point P2 in which the forward current changes to the reverse current in the pn junction diode D and at the third measurement point P3 in which the reverse current increases, while a hole current density in the IGBT region 8 is relaxed with the elapse of time, a hole current density in the diode region 9 becomes high. This is due to an increase in density of the holes which are drawn back to the anode region 62.

Then, with reference to FIG. 19D and FIG. 19E, at the fourth measurement point P4 and the fifth measurement point P5 respectively at the peak time of the reverse current flowing through the pn junction diode D and immediately after the peak time, while the pn junction diode D is switched from an on state to an off state and the reverse current converges, the hole current density in the diode region 9 becomes highest. In particular, the hole current density at a high level is not uniformly distributed across an entirety of the diode region 9 including the cell separating structure 63, but rather the hole current density is clearly distributed so as to extend perpendicularly in a thickness direction of the semiconductor layer 2 from the diode cell region 69, as compared with a region directly below the cell separating structure 63. This is due to the fact that holes which are a small number of carriers are concentrated at a narrow passage which is formed by a part of the n⁻ type drift region 30 sandwiched between the cell separating structures 63. Therefore, it is considered that if this hole current concentration can be relaxed, the hole current density can be decreased to attain a soft recovery and a recovery loss can be decreased.

Thereafter, with reference to FIG. 19F to FIG. 19H (sixth measurement point P6 to eighth measurement point P8), the holes which stay in the n⁻ type drift region 30 are drawn back to the anode region 62 with the elapse of time, and finally, as shown in FIG. 19I (ninth measurement point P9), the holes which are a small number of carriers are completely recovered.

### [Evaluation 2 on Problem of Reverse Recovery Characteristics of Pn Junction Diode]

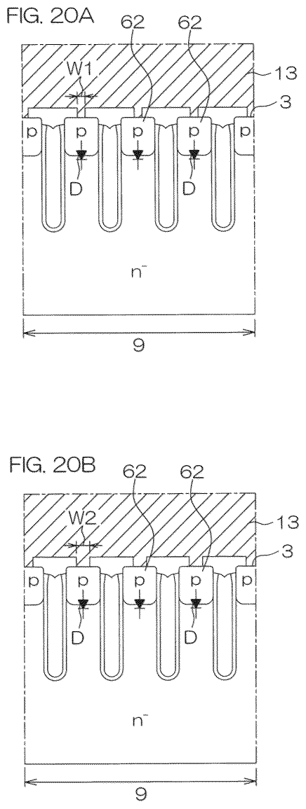

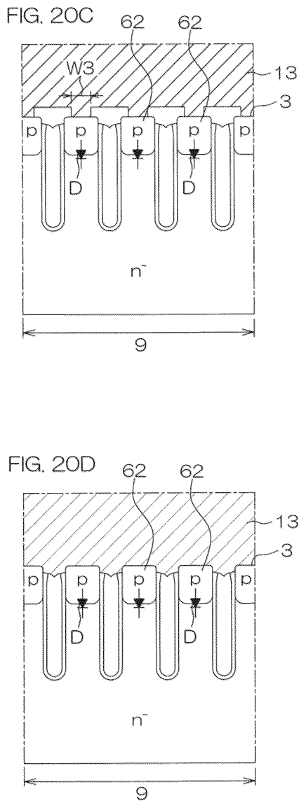

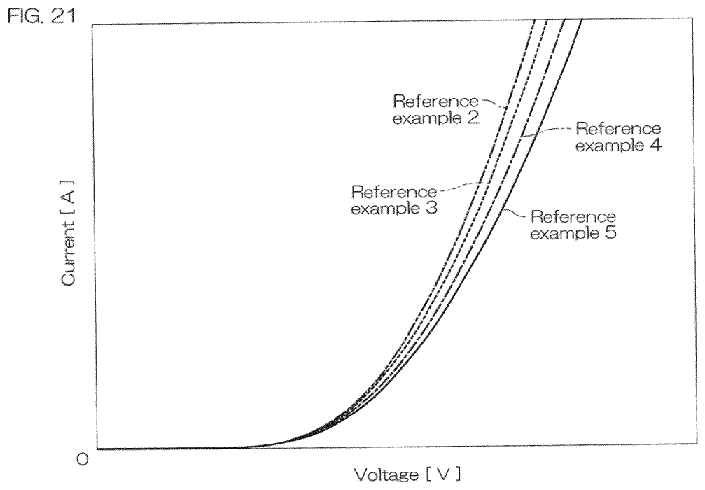

Next, with reference to FIG. 20A to FIG. 20D and FIG. 21 to FIG. 23, an evaluation is made on a change in characteristics of the pn junction diode D according to an increase or decrease in the area of the anode contact with respect to the anode region 62.

FIG. 20A to FIG. 20D are each a schematic view of the semiconductor devices according to Reference Examples 2 to 5 used in evaluating this section. In Reference Examples 2 to 5 according to FIG. 20A to FIG. 20D, a mask which is selectively formed in the first principal surface 3 of the semiconductor layer 2 is increased or decreased in opening width, thereby increasing or decreasing an area of the anode contact (emitter terminal electrode 13) with respect to the anode region 62. An opening width W1 of Reference Example 2 in FIG. 20A is narrowest, and an opening width W2 and an opening width W3 becomes wider in the order of Reference Example 3 of FIG. 20B and Reference Example 4 of FIG. 20C. In Reference Example 5 of FIG. 20D, the anode region 62 is entirely exposed.

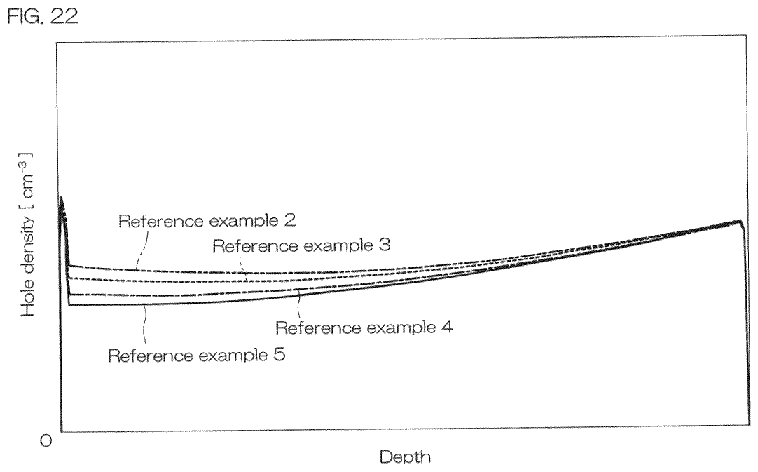

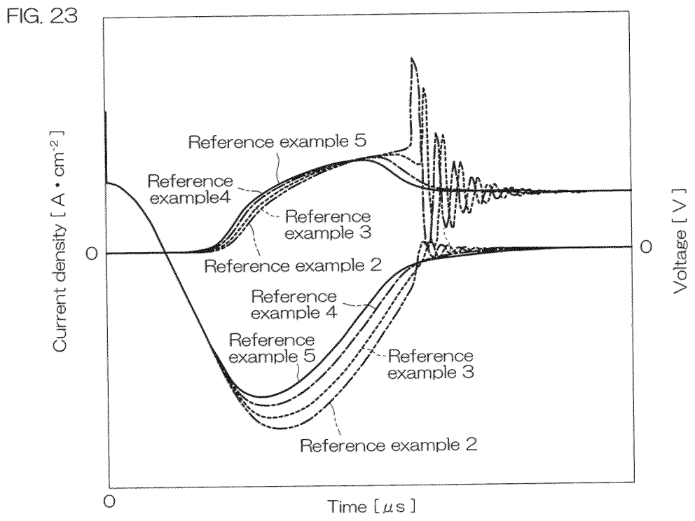

FIG. 21 is a drawing of results of examining forward characteristics of the pn junction diode D according to Reference Examples 2 to 5 by a simulation. In FIG. 21, the vertical axis indicates a forward current [A] and the horizontal axis indicates a forward voltage [V]. FIG. 22 is a drawing of results of examining a degree of the forward hole density of the pn junction diode D according to Reference Examples 2 to 5 by a simulation. In FIG. 22, the vertical axis indicates a hole density [cm⁻³] and the horizontal axis indicates a depth from the first principal surface 3. FIG. 23 is a drawing of results of examining reverse recovery characteristics of the pn junction diode D according to Reference Examples 2 to 5 by a simulation. In FIG. 23, the vertical axis at the left side indicates a current density [A·cm⁻²], the vertical axis at the right side indicates a voltage [V], and the horizontal axis indicates time [μs].

With reference to FIG. 21 and FIG. 22, it is found that the forward characteristics of the pn junction diode D according to Reference Examples 2 to 5 are more favorable as an area of the anode contact with respect to the anode region 62 becomes smaller. With reference to FIG. 21, the pn junction diode D of Reference Example 2 which is smallest in the area of the anode contact is lowest in forward voltage, and the pn junction diode D according to Reference Example 5 which is largest in the area of the anode contact is highest in forward voltage. Also, with reference to FIG. 22, the pn junction diode D of Reference Example 2 which is smallest in the area of the anode contact is highest in hole density near an anode contact portion (the first principal surface 3), and the pn junction diode D according to Reference Example 5 which is largest in the area of the anode contact is lowest in hole density. From FIG. 21 and FIG. 22, it is found that when the anode contact is made small in area, the hole density near the first principal surface 3 becomes high and the forward voltage is decreased.

On the other hand, with reference to FIG. 23, it is found that at the time of reverse recovery, the reverse recovery characteristics are more favorable as an area of the anode contact with respect to the anode region 62 becomes larger. Specifically, it is found that in terms of a peak value of the reverse current, the pn junction diode D of Reference Example 5 which is largest in the area of the anode contact is lowest in hole current density, and the pn junction diode D according to Reference Example 2 which is smallest in the area of the anode contact is highest in hole current density. It is therefore considered that when the anode contact is made large in area, the hole current density can be decreased to achieve a soft recovery and a recovery loss can be decreased, although the forward characteristics may be affected to a certain extent.

Without being limited to the above evaluation 1 and evaluation 2, various evaluations can be made on the problem of improving the reverse recovery characteristics of the pn junction diode and the problems can be solved by adopting improvement measures according to each problem. In the following, a plurality of Improved Structures which are preferable in improving the reverse recovery characteristics of the pn junction diode shall be adopted as an example.

### [Improved Structure 1 of Semiconductor Device 1]

### (1) Improved Structure 1-1

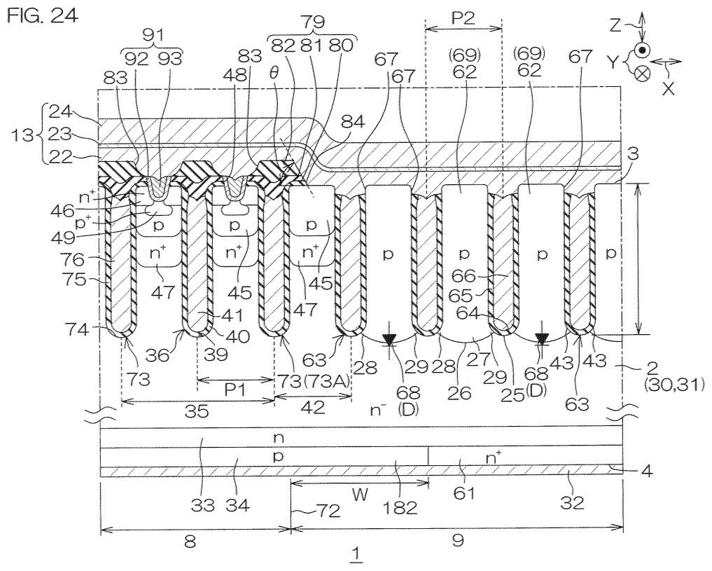

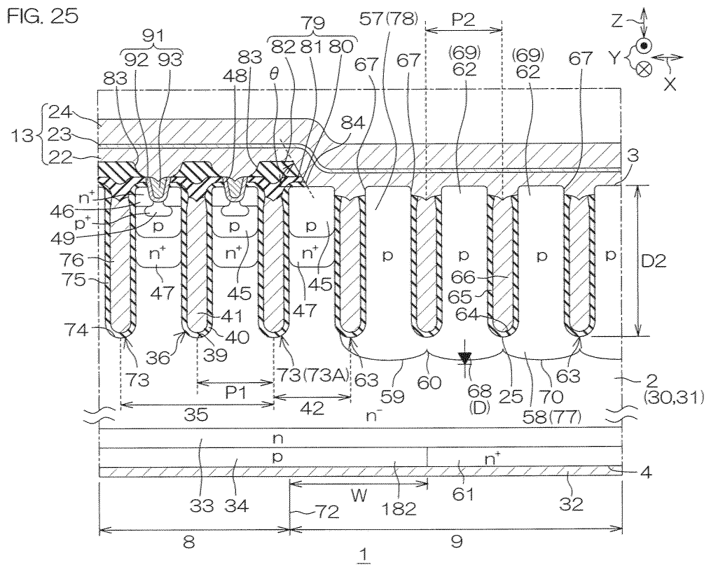

FIG. 24 is a schematic cross-sectional view which shows Improved Structure 1-1 of the semiconductor device 1. FIG. 25 is a schematic cross-sectional view which shows Improved Structure 1-1 of the semiconductor device 1. It is noted that a structure common to the aforementioned structure shall be given the same reference sign, and a description thereof shall be omitted. FIG. 24 and FIG. 25 are each a cross-sectional view corresponding to FIG. 8.

With reference to FIG. 24 and FIG. 25, the anode region 62 extends in the diode cell region 69 deeper than a bottom wall of the cell separating trench 64 from the first principal surface 3 along a side wall of the cell separating trench 64. The anode region 62 covers at least a part of the bottom walls of the adjacent cell separating trenches 64.

With reference to FIG. 24, the anode region 62 may include the plurality of anode regions 62 that are mutually divided in a region directly below the cell separating trench 64. The region directly below the cell separating trench 64 may be a part of the drift region 30 which overlaps with the cell separating trench 64 in the normal direction Z.

In this preferred embodiment, the anode region 62 is formed across an entire area from the first principal surface 3 of each diode cell region 69 up to the bottom wall of the cell separating trench 64. The anode region 62 is formed in each diode cell region 69 in a physically independent manner and forms the pn junction portion 68 on a lateral side of the bottom wall of the cell separating trench 64. More specifically, each anode region 62 has a bottom portion 27 which is formed in a curved shape and has an apex portion 26 which is positioned further at the second principal surface 4 side than a curved-shaped apex portion 25 (curved apex portion) of the bottom wall of the cell separating trench 64 which is formed in a curved shape. Here, the apex portion 25 and the apex portion 26 may be defined as parts which are closest to the second principal surface 4 respectively at the bottom wall of the cell separating trench 64 and at the bottom portion 27 of the anode region 62.

A depth of the deepest portion of the anode region 62 from the bottom wall of the cell separating trench 64 may be not less than 0.1 μm and not more than 3.0 μm. In this preferred embodiment, a distance between the apex portion 26 of the anode region 62 and the apex portion 25 of the cell separating trench 64 in the normal direction Z may be not less than 0.6 μm and not more than 3.6 μm.

Thereby, the pn junction portion 68 has a first end portion 28 at a bottom wall of one of the adjacent cell separating trenches 64 and has a second end portion 29 at a bottom wall of the other of the adjacent cell separating trenches 64. The second end portion 29 of the anode region 62 which is adjacent to a side closer to the IGBT region 8 with respect to the cell separating trench 64 and the first end portion 28 of the anode region 62 adjacent to the opposite side thereof are in contact with the bottom wall of each cell separating trench 64. With the first end portion 28 and the second end portion 29 given as both end portions, the pn junction portion 68 is formed in a curved shape that is raised toward the second principal surface 4 side with respect to the both end portions 28, 29.

While the bottom wall of the curved-shaped cell separating trench 64 is partially in contact with the bottom portion 27 of the anode region 62, the apex portion 25 is in contact with the drift region 30. That is, the bottom wall of the cell separating trench 64 includes the apex portion 25 which is in contact with an n type semiconductor region (the drift region 30 in this preferred embodiment) and an end portion 43 which is in contact with the p type semiconductor region (the anode region 62 in this preferred embodiment) at both sides of the apex portion 25.

Next, with reference to FIG. 25, the anode region 62 may include the anode region 62 which collectively covers the bottom walls of the plurality of cell separating trenches 64 and is formed across the plurality of diode cell regions 69.

In this preferred embodiment, the anode region 62 includes a first portion 57 which is formed in each diode cell region 69 and a second portion 58 which couples the first portions 57 of the plurality of diode cell regions 69.

The first portion 57 of the anode region 62 is formed across an entire area from the first principal surface 3 of each diode cell region 69 up to the bottom wall of the cell separating trench 64. That is, the diode cell region 69 sandwiched between the mutually adjacent cell separating trenches 64 in the n type drift region 30 is completely replaced by the p type anode region 62.

The second portion 58 of the anode region 62 extends along the first principal surface 3 so as to cross the plurality of cell separating trenches 64 and integrally covers the bottom walls of the plurality of cell separating trenches 64 including the apex portion 25 from the second principal surface 4 side. Therefore, the single anode region 62 which opposes the cell separating trench 64 in the normal direction Z is formed below the cell separating trench 64 in the normal direction Z. Thereby, the side walls and the bottom walls of the plurality of cell separating trenches 64 are in their entirety formed by the p type anode region 62. In other words, the anode region 62 which is constituted of a single layer may be formed in the surface layer portion of the first principal surface 3 of the semiconductor layer 2, and the plurality of cell separating trenches 64 may be formed up to an intermediate portion of the anode region 62 in the normal direction Z.

The second portion 58 of the anode region 62 couples the first portions 57 of the plurality of diode cell regions 69, and forms the pn junction portion 68 (the pn junction diode D) with the n type drift region 30. The pn junction portion 68 has a sectional shape which alternately rises and falls at the first principal surface 3 side and at the second principal surface 4 side along the first principal surface 3. The pn junction portion 68 may have a corrugated shape with ups and downs alternately in the normal direction Z.

In this preferred embodiment, the pn junction portion 68 is raised toward the second principal surface 4 side directly below the diode cell region 69 and raised toward the first principal surface 3 side directly below the cell separating trench 64. More specifically, the pn junction portion 68 includes a first bulging portion 59 which overlaps with the diode cell region 69 in the normal direction Z and bulges toward the second principal surface 4 and a second bulging portion 60 which overlaps with the cell separating trench 64 and bulges toward the first principal surface 3. The first bulging portion 59 and the second bulging portion 60 are alternately formed along the first principal surface 3 in such a direction that crosses the plurality of cell separating trenches 64.

A depth of the deepest portion of the anode region 62 from the bottom wall of the cell separating trench 64 may be not less than 0.1 μm and not more than 3.0 μm. In this preferred embodiment, a distance between an apex portion 70 of the first bulging portion 59 of the anode region 62 and the apex portion 25 of the cell separating trench 64 in the normal direction Z may be not less than 0.6 μm and not more than 3.6 μm.

It is noted that the shape of the anode region 62 may be expressed by defining the second portion 58 and the first portion 57 of the anode region 62 as a base portion 77 and a branch portion 78, respectively. For example, the anode region 62 may integrally include the base portion 77 which is formed across the plurality of cell separating trenches 64 below the bottom walls of the plurality of cell separating trenches 64 and the branch portion 78 which is formed so as to project from the base portion 77 toward the first principal surface 3 at a position of each diode cell region 69. In this case, the base portion 77 forms the pn junction portion 68 between the base portion 77 and the n type drift region 30.

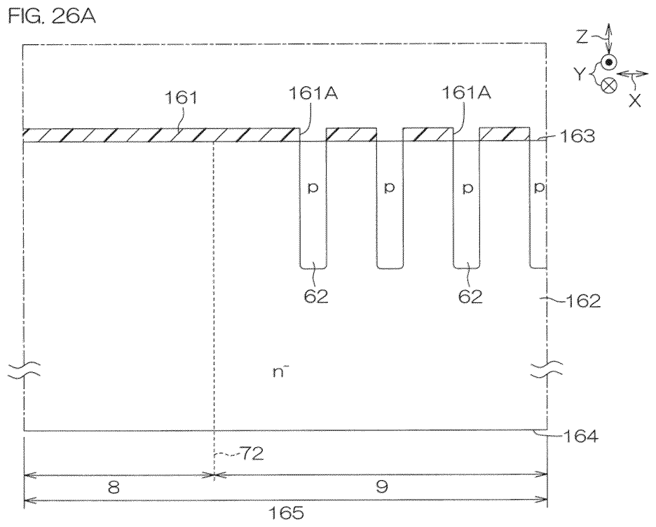

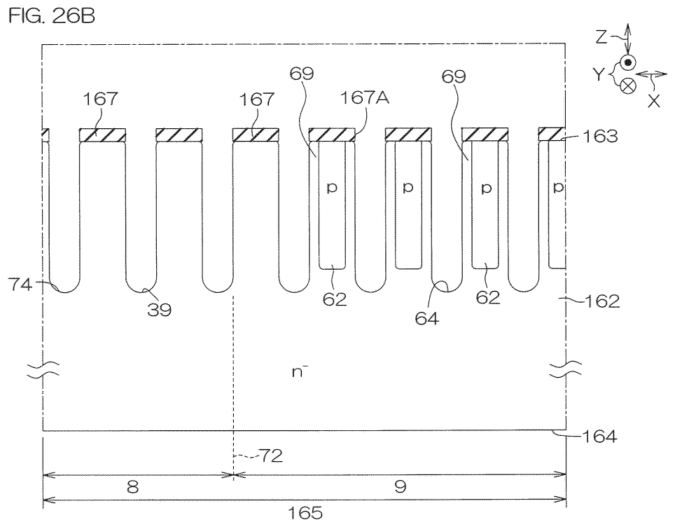

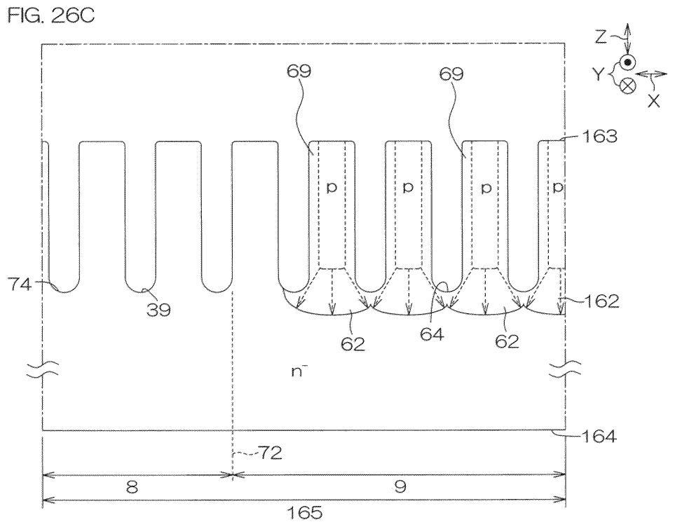

FIG. 26A to FIG. 26C are each a cross-sectional view of a region corresponding to FIG. 24 and FIG. 25, and a cross-sectional view which shows a step in relation to formation of the structure of FIG. 24 and FIG. 25. As to the manufacture of the semiconductor device 1 in FIG. 24 and FIG. 25, for example, the aforementioned steps of the FIG. 10A and FIG. 10B may be replaced with the steps of FIG. 26A to FIG. 26C.

First, with reference to FIG. 26A, after the device forming region 165 is set at the semiconductor wafer 162, the p type anode region 62 is formed in the diode region 9. In this step, first, an ion introducing mask 161 having a predetermined pattern is formed on the first wafer principal surface 163. The ion introducing mask 161 has a plurality of openings 161A which respectively expose regions in which the plurality of anode regions 62 are to be formed. The regions in which the plurality of anode regions 62 are to be formed may be, for example, smaller than a region in which the diode cell region 69 is formed.

Next, a p type impurity is introduced via the ion introducing mask 161 into the semiconductor wafer 162. The plurality of anode regions 62 are thereby formed in the diode region 9. At this point, the plurality of anode regions 62 are physically separated from each other. Thereafter, the ion introducing mask 161 is removed.

Next, with reference to FIG. 26B, the gate trench 39 and the emitter trench 74 are formed in the IGBT region 8, and the cell separating trench 64 is formed in the diode region 9. In this step, first, the hard mask 167 which is the same as FIG. 10B is formed on the first wafer principal surface 163. The opening 167A of the hard mask 167 exposes a region between the plurality of anode regions 62 that are adjacent to each other. Then, the unnecessary portions of the semiconductor wafer 162 are removed by an etching method via the hard mask 167. Thereby, the gate trench 39 and the emitter trench 74 are formed in the IGBT region 8, and the cell separating trench 64 is formed in the diode region 9. The cell separating trench 64 may be formed at an interval from each anode region 62. Thereafter, the hard mask 167 is removed.

Next, with reference to FIG. 26C, the plurality of anode regions 62 are diffused inside the semiconductor wafer 162 by a thermal treatment. Each anode region 62 thereby expands along the side walls of the cell separating trench 64 in a direction toward the second principal surface 4 (vertical direction) and also expands along the first principal surface 3 in a direction toward the cell separating trench 64 (horizontal direction). The bottom wall of the cell separating trench 64 is thereby covered by the anode region 62. At this time, the anode region 62 of FIG. 24 and the anode region 62 of FIG. 25 can be separately made by adjusting a diffusion time.

For example, as the diffusion time is longer, the anode region 62 expands deeper into the semiconductor layer 2. Therefore, when the diffusion time is made relatively long, the plurality of anode regions 62 expand so as to be connected directly below the bottom wall of the cell separating trench 64, and the anode region 62 which collectively covers the bottom walls of the plurality of cell separating trenches 64 as shown in FIG. 25 is formed. On the other hand, when the diffusion time is made relatively short, the physically independent anode region 62 is formed in each diode cell region 69 as shown in FIG. 24.

Thereafter, by executing the same steps as FIG. 10C to FIG. 10R, the semiconductor device 1 as shown in FIG. 24 and FIG. 25 is manufactured.

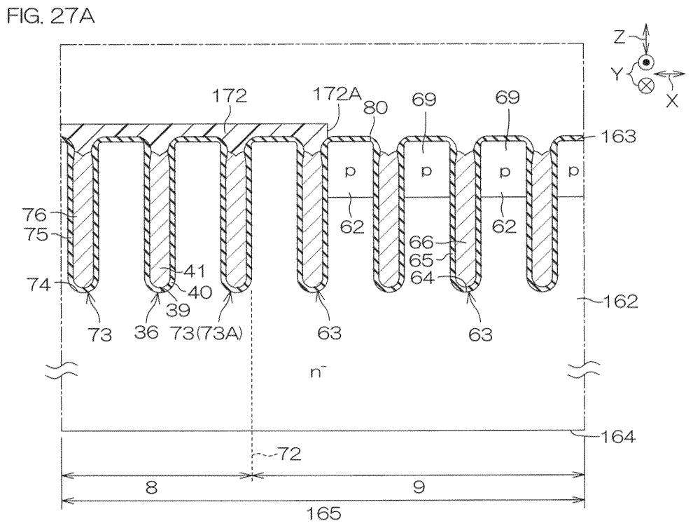

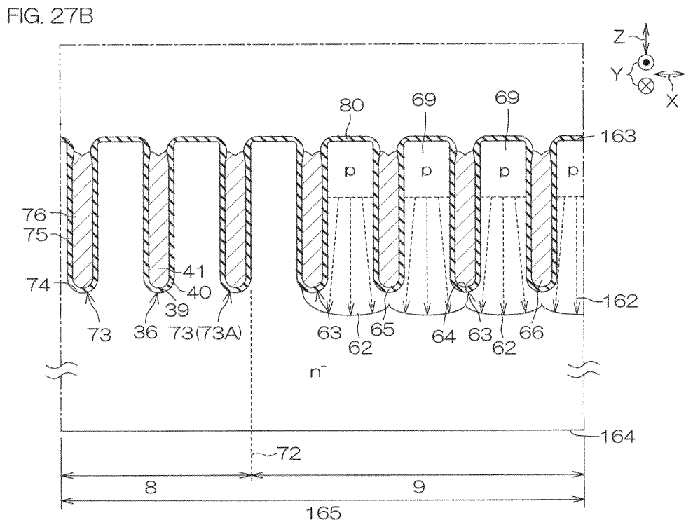

FIG. 27A and FIG. 27B are each a cross-sectional view of a region corresponding to FIG. 24 and FIG. 25, and a cross-sectional view which shows a step in relation to formation of the structure of FIG. 24 and FIG. 25. As to the manufacture of the semiconductor device 1 shown in FIG. 24 and FIG. 25, the steps of FIG. 27A and FIG. 27B may be adopted, in addition to the steps of FIG. 26A to FIG. 26C. In this case, for example, the steps of FIG. 27A and FIG. 27B may be added between the step of FIG. 10E and the step of FIG. 10F.

For example, in the step of FIG. 10E, after the gate electrode layer 41, the cell separating electrode layer 66, etc., are formed, as shown in FIG. 27A, the p type anode region 62 is formed in the diode region 9. In this step, first, an ion introducing mask 172 having a predetermined pattern is formed on the first wafer principal surface 163. The ion introducing mask 172 has a plurality of openings 172A which expose the diode region 9. Next, a p type impurity is introduced via the ion introducing mask 172 into the semiconductor wafer 162. The anode region 62 is thereby formed in the surface layer portion of the first principal surface 3 of each diode cell region 69. Thereafter, the ion introducing mask 172 is removed.

Next, with reference to FIG. 27B, the plurality of anode regions 62 are diffused inside the semiconductor wafer 162 by a thermal treatment. Each anode region 62 thereby expands along the side walls of the cell separating trench 64 in a direction toward the second principal surface 4 (vertical direction) and also expands along the first principal surface 3 in a direction toward the cell separating trench 64 (horizontal direction). The bottom wall of the cell separating trench 64 is thereby covered by the anode region 62. At this time as well, as with the step of FIG. 26C, the anode region 62 of FIG. 24 and the anode region 62 of FIG. 25 can be separately made by adjusting the diffusion time.

Thereafter, by executing the same steps as FIG. 10F to FIG. 10R, the semiconductor device 1 as shown in FIG. 24 and FIG. 25 is manufactured.

As described above, according to Improved Structure 1-1, the anode region 62 is formed deeper than the bottom wall of the cell separating trench 64, by which the bottom wall of the cell separating trench 64 is covered by the anode region 62. The pn junction portion 68 thereby strides over the bottom wall of the adjacent cell separating trench 64. Therefore, for example, as found in Basic Structure 1 of FIG. 8 and Basic Structure 2 of FIG. 15, as compared with a case where the pn junction portion 68 connects the side walls of the mutually adjacent cell separating trenches 64, an area of the pn junction portion 68 can be widely secured in the structure of FIG. 24 and FIG. 25. As a result, it is possible to recover carriers from the anode region 62 having a wide area at the time of recovery, and it is therefore possible to promote the recovery of the carriers and decrease a recovery loss.

### (2) Improved Structure 1-2

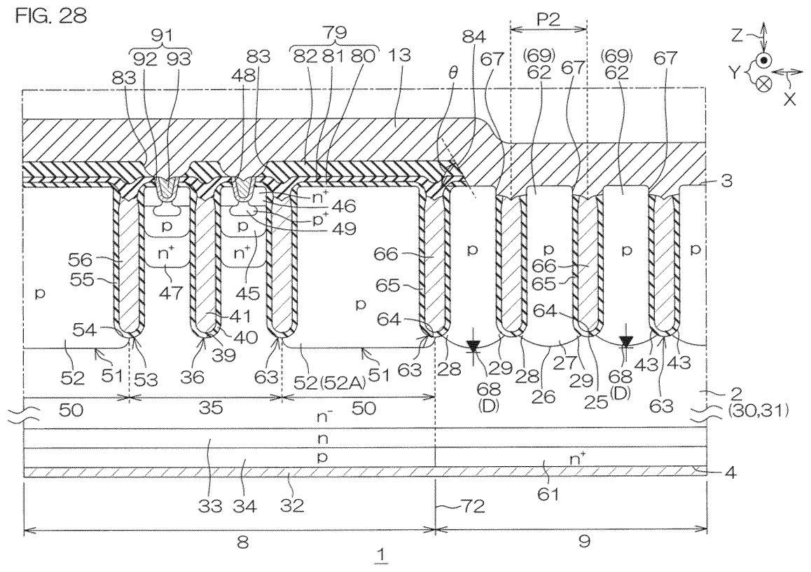

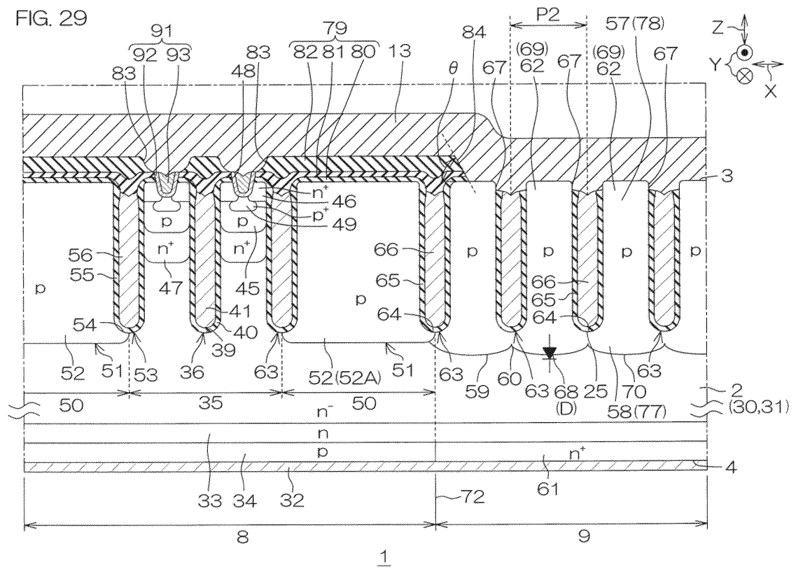

FIG. 28 is a schematic cross-sectional view which shows Improved Structure 1-2 of the semiconductor device 1. FIG. 29 is a schematic cross-sectional view which shows Improved Structure 1-2 of the semiconductor device 1. It is noted that a structure common to the aforementioned structure shall be given the same reference sign, and a description thereof shall be omitted. FIG. 28 and FIG. 29 are each a cross-sectional view corresponding to FIG. 15.

FIG. 28 shows the semiconductor device 1 in which the structure of the anode region 62 of FIG. 24 described above is applied to the diode region 9 of the semiconductor device 1 of Basic Structure 2 in FIG. 15. FIG. 29 shows the semiconductor device 1 in which the structure of the anode region 62 of FIG. 25 described above is applied to the diode region 9 of the semiconductor device 1 of Basic Structure 2 in FIG. 15. That is, the anode region 62 shown in FIG. 24 and FIG. 25 is also applicable to the semiconductor device 1 which has the floating region 52.

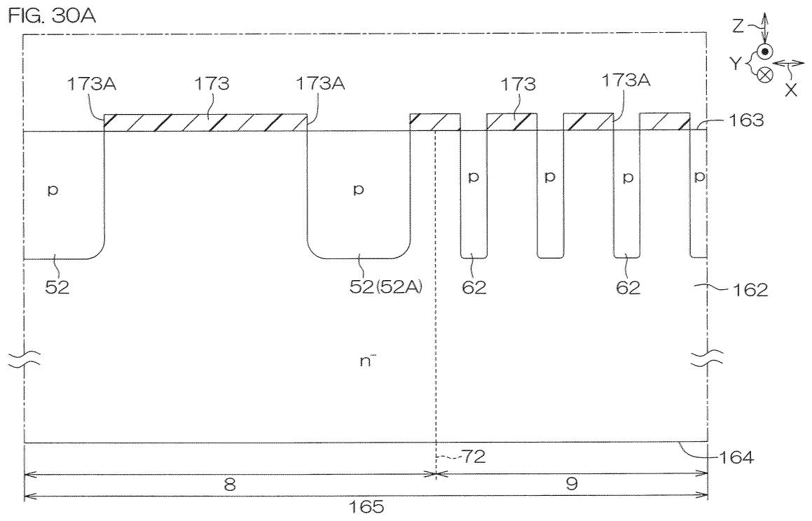

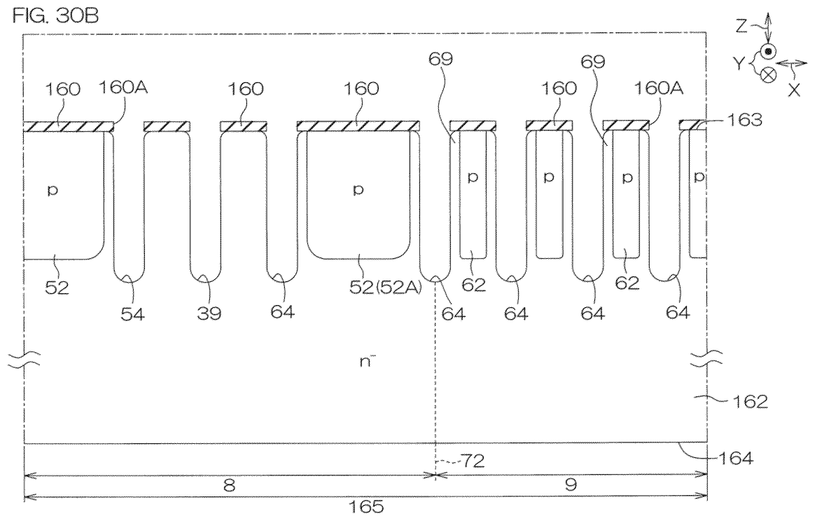

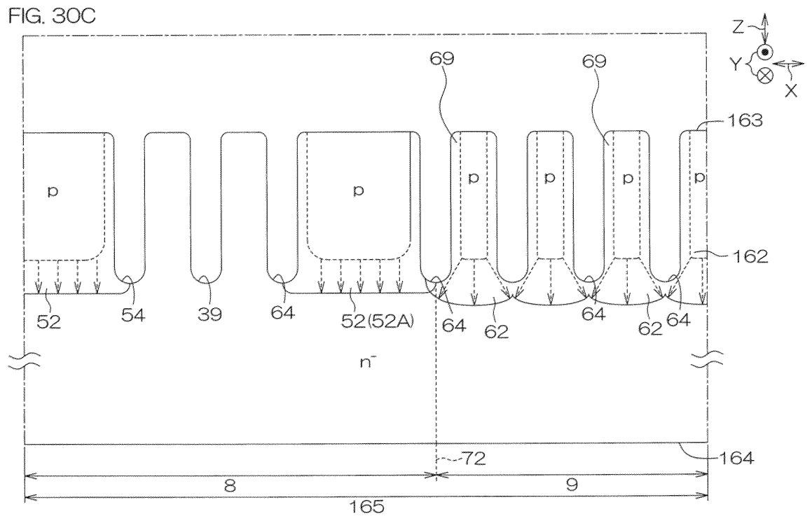

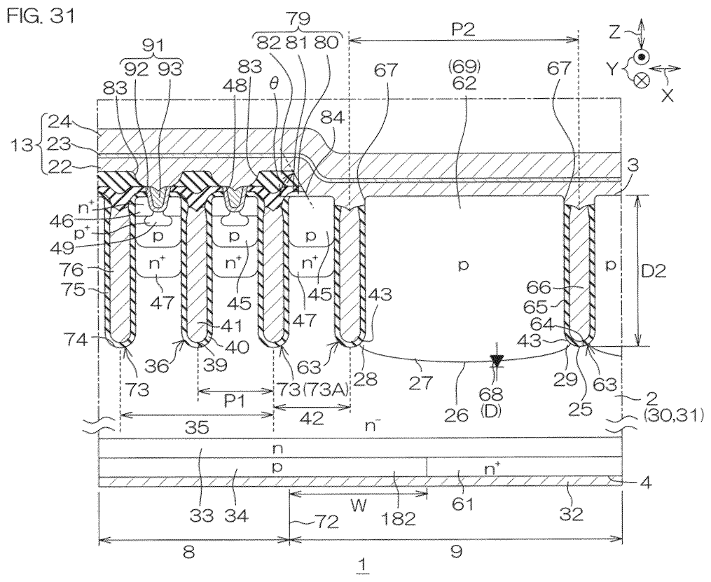

FIG. 30A to FIG. 30C are each a cross-sectional view of a region corresponding to FIG. 28 and FIG. 29, and a cross-sectional view which shows a step in relation to formation of the structure of FIG. 28 and FIG. 29. As to the manufacture of the semiconductor device 1 shown in FIG. 28 and FIG. 29, for example, the aforementioned steps of FIG. 10A and FIG. 10B may be replaced with the steps of FIG. 30A to FIG. 30C.

First, with reference to FIG. 30A, after the device forming region 165 is set at the semiconductor wafer 162, the plurality of p⁺ type floating regions 52 are formed in the IGBT region 8, and the p type anode region 62 is formed in the diode region 9. In this step, first, an ion introducing mask 173 having a predetermined pattern is formed on the first wafer principal surface 163. The ion introducing mask 173 has a plurality of openings 173A which respectively expose regions in which the plurality of floating regions 52 are to be formed and regions in which the plurality of anode regions 62 are to be formed.

Next, a p type impurity is introduced via the ion introducing mask 173 into the semiconductor wafer 162. Thereby, the plurality of floating regions 52 are formed in the IGBT region 8, and the plurality of anode regions 62 are formed in the diode region 9. Thereafter, the ion introducing mask 173 is removed.

Next, with reference to FIG. 30B, the gate trench 39 and the region separating trench 54 are formed in the IGBT region 8, and the cell separating trench 64 is formed in the diode region 9. In this step, first, the hard mask 160 which is the same as FIG. 17B is formed on the first wafer principal surface 163. Then, the unnecessary portions of the semiconductor wafer 162 are removed by an etching method via the hard mask 160. Thereby, the gate trench 39 and the region separating trench 54 are formed in the IGBT region 8, and the cell separating trench 64 is formed in the diode region 9.

Next, with reference to FIG. 30C, the plurality of floating regions 52 and the plurality of anode regions 62 are diffused inside the semiconductor wafer 162 by a thermal treatment. Thereby, each floating region 52 and each anode region 62 expand in a direction toward the second principal surface 4 (vertical direction) and also expand in a direction toward the first principal surface 3 (horizontal direction). Thereby, the bottom wall of the region separating trench 54 is covered by the floating region 52, and the bottom wall of the cell separating trench 64 is covered by the anode region 62.

Thereafter, by executing the same steps as FIG. 10C to FIG. 10R, the semiconductor device 1 shown in FIG. 28 and FIG. 29 is manufactured.

It is noted that the steps shown in FIG. 30A to FIG. 30B are applied to a case where a target value of the impurity concentration of the floating region 52 and that of the anode region 62 are the same with each other. That is, if the floating region 52 and the anode region 62 have the same impurity concentrations with each other, they can be formed in the same step. On the other hand, when the floating region 52 is higher in impurity concentration than the anode region 62, the step of FIG. 17A for forming the floating region 52 may be executed separately from the step of FIG. 26A for forming the anode region 62.

As described above, Improved Structure 1-2 is also able to widely secure an area of the pn junction portion 68, as with Improved Structure 1-1. As a result, it is possible to recover carriers from the anode region 62 having a wide area at the time of recovery, and it is therefore possible to promote the recovery of the carriers and decrease a recovery loss.

Also, when the floating region 52 and the anode region 62 have the same impurity concentration with each other in Improved Structure 1-2, these regions 52, 62 can be formed in the same step. Therefore, the steps of manufacturing the semiconductor device 1 can be made simple.

### (3) Improved Structure 1-3

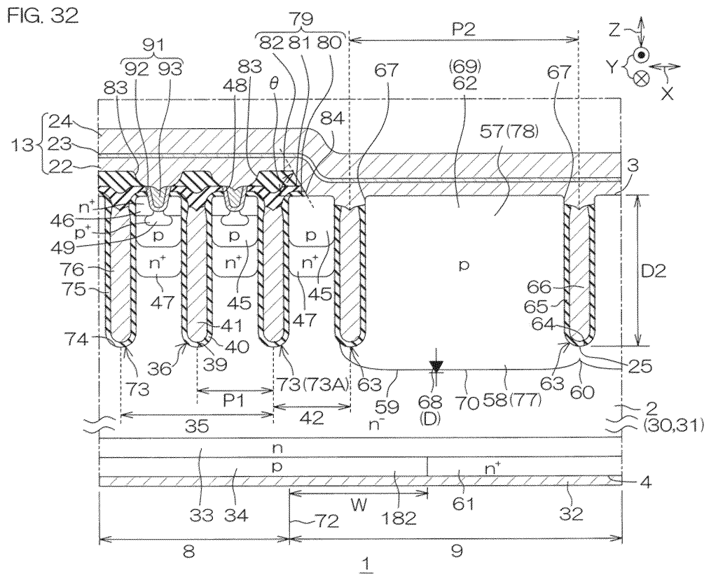

FIG. 31 is a schematic cross-sectional view which shows Improved Structure 1-3 of the semiconductor device 1. FIG. 32 is a schematic cross-sectional view which shows Improved Structure 1-3 of the semiconductor device 1. It is noted that a structure common to the aforementioned structure shall be given the same reference sign, and a description thereof shall be omitted. FIG. 31 and FIG. 32 are cross-sectional views corresponding respectively to FIG. 24 and FIG. 25.

In the semiconductor device 1 of FIG. 31, as compared with the structure of FIG. 24, a distance (second pitch P2) between the mutually adjacent two cell separating structures 63 is greater than a distance (first pitch P1) between the trench gate structure 36 and the emitter trench structure 73. For example, the second pitch P2 may be not less than 2.0 times and not more than 3.0 times larger than the first pitch P1. Specifically, the first pitch P1 may be not less than 1.2 μm and not more than 3.5 μm, and the second pitch P2 may be not less than 2.4 μm and not more than 10.5 μm.

In the semiconductor device 1 shown in FIG. 32, as compared with the structure of FIG. 25, the distance (second pitch P2) between the mutually adjacent two cell separating structures 63 is made larger than the distance (first pitch P1) between the two trench gate structures 36 and the emitter trench structures 73. For example, the second pitch P2 may be not less than 2.0 times and not more than 3.0 times larger than the first pitch P1. Specifically, the first pitch P1 may be not less than 1.2 μm and not more than 3.5 μm, and the second pitch P2 may be not less than 2.4 μm and not more than 10.5 μm.

As described above, Improved Structure 1-3 is also able to widely secure an area of the pn junction portion 68, as with Improved Structure 1-1. As a result, it is possible to recover carriers from the anode region 62 having a wide area at the time of recovery, and it is therefore possible to promote the recovery of the carriers and decrease a recovery loss.

Also, in Improved Structure 1-3, by setting a relationship of the second pitch P2>the first pitch P1, it is made possible to enlarge an area of the anode region 62 which is exposed to the first principal surface 3 between the mutually adjacent cell separating trenches 64. It is thereby possible to widely secure an area of the anode contact of the pn junction diode D. As a result, it is possible to relax the carrier storage effects at the time of recovery, and it is therefore possible to decrease a recovery loss.

### (4) Improved Structure 1-4

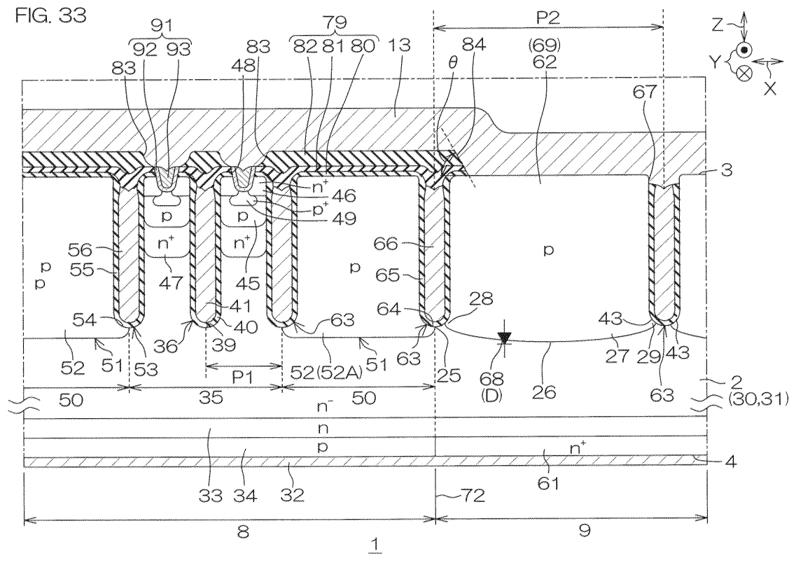

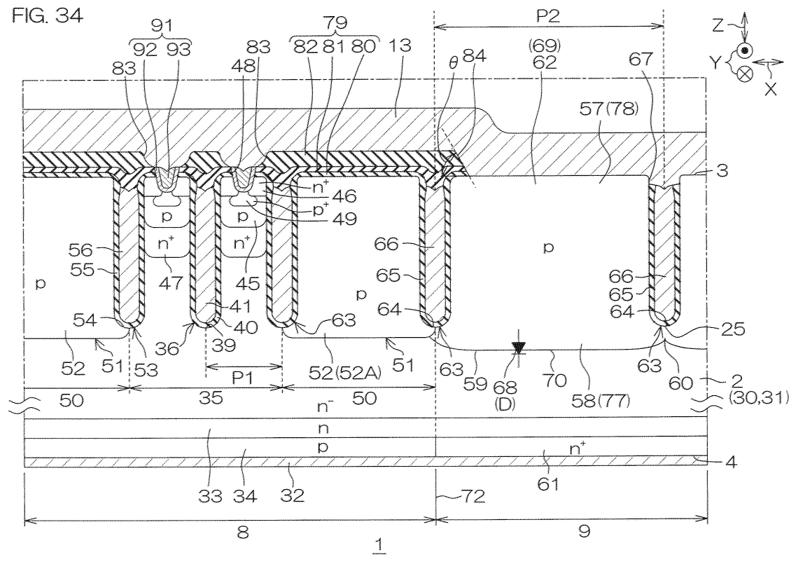

FIG. 33 is a schematic cross-sectional view which shows Improved Structure 1-4 of the semiconductor device 1. FIG. 34 is a schematic cross-sectional view which shows Improved Structure 1-4 of the semiconductor device 1. It is noted that a structure common to the aforementioned structure shall be given the same reference sign, and a description thereof shall be omitted. FIG. 33 and FIG. 34 are cross-sectional views corresponding respectively to FIG. 28 and FIG. 29.

In the semiconductor device 1 shown in FIG. 33, as compared with the structure of FIG. 28, a distance (second pitch P2) between the mutually adjacent two cell separating structures 63 is made larger than a distance (first pitch P1) between the trench gate structure 36 and the region separating trench structure 53. For example, the second pitch P2 may be not less than 2.0 times and not more than 3.0 times larger than the first pitch P1. Specifically, the first pitch P1 may be not less than 1.2 μm and not more than 3.5 μm, and the second pitch P2 may be not less than 2.4 μm and not more than 10.5 μm.

In the semiconductor device 1 shown in FIG. 34, as compared with the structure of FIG. 29, a distance (second pitch P2) between the mutually adjacent two cell separating structures 63 is made larger than a distance (first pitch P1) between the two trench gate structures 36 and the region separating trench structures 53. For example, the second pitch P2 may be not less than 2.0 times and not more than 3.0 times larger than the first pitch P1. Specifically, the first pitch P1 may be not less than 1.2 μm and not more than 3.5 μm, and the second pitch P2 may be not less than 2.4 μm and not more than 10.5 μm.

As described above, Improved Structure 1-4 is also able to widely secure an area of the pn junction portion 68, as with Improved Structure 1-1. As a result, it is possible to recover carriers from the anode region 62 having a wide area at the time of recovery, and it is therefore possible to promote the recovery of the carriers and decrease a recovery loss.

Also, in Improved Structure 1-4, by setting a relationship of the second pitch P2>the first pitch P1, it is made possible to enlarge an area of the anode region 62 which is exposed to the first principal surface 3 between the mutually adjacent cell separating trenches 64. It is thereby possible to widely secure an area of the anode contact of the pn junction diode D. As a result, it is possible to relax the carrier storage effects at the time of recovery, and it is therefore possible to decrease a recovery loss.

### [Improved Structure 2 of Semiconductor Device 1]

### (1) Improved Structure 2-1

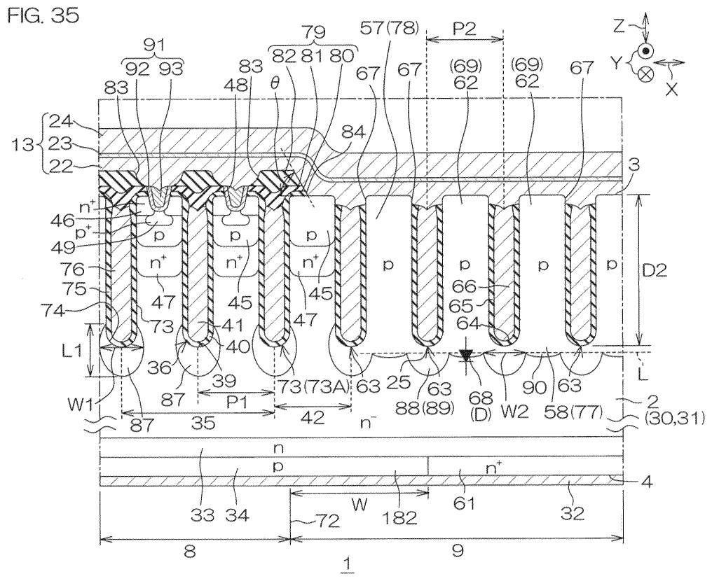

FIG. 35 is a schematic cross-sectional view which shows Improved Structure 2-1 of the semiconductor device 1. It is noted that a structure common to the aforementioned structure shall be given the same reference sign, and a description thereof shall be omitted. FIG. 35 is a cross-sectional view corresponding to FIG. 25.

In Improved Structure 2-1, a p⁻ type trench bottom portion impurity structure 87 as an example of the third impurity region is selectively formed at bottom portions of the gate trench 39 and the emitter trench 74. A p type impurity concentration of the trench bottom portion impurity structure 87 may be not more than the p type impurity concentration of the body region 45. The p type impurity concentration of the trench bottom portion impurity structure 87 may be the same as the p type impurity concentration of the anode region 62. The p type impurity concentration of the trench bottom portion impurity structure 87 is preferably less than the p type impurity concentration of the body region 45. The p type impurity concentration of the trench bottom portion impurity structure 87 may be not less than 1.0×10¹⁵ cm⁻³ and not more than 1.0×10¹⁸ cm⁻³.

One each of the trench bottom portion impurity structures 87 is formed in each gate trench 39 and in each emitter trench 74 so as to be individually physically independent. The trench bottom portion impurity structure 87 covers a bottom wall of the gate trench 39 and that of the emitter trench 74 as well as a part of a side wall near the bottom wall. The trench bottom portion impurity structure 87 projects in a semi-circular shape or a semi-elliptical shape from the bottom portion of each gate trench 39 and that of each emitter trench 74 toward the second principal surface 4 side. A depth position of the trench bottom portion impurity structure 87 may be, for example, not less than 5.0 μm and not more than 8.0 μm from the first principal surface 3. Also, the trench bottom portion impurity structure 87 may be formed in an elongated shape in which a length L1 in the normal direction Z is larger than the width W1 in the first direction X.

The second portion 58 of the anode region 62 includes a p⁻ type projecting portion 88 which selectively projects at the second principal surface 4 side. A p type impurity concentration of the projecting portion 88 may be not more than the p type impurity concentration of the body region 45. The p type impurity concentration of the projecting portion 88 may be the same as the p type impurity concentration of the anode region 62. The p type impurity concentration of the projecting portion 88 may be the same as the p type impurity concentration of the trench bottom portion impurity structure 87. The p type impurity concentration of the projecting portion 88 is preferably less than the p type impurity concentration of the body region 45. The p type impurity concentration of the projecting portion 88 may be not less than 1.0×10¹⁵ cm⁻³ and not more than 1.0×10¹⁸ cm⁻³. In this preferred embodiment, one each of the projecting portions 88 is formed directly below each cell separating trench 64 so as to be individually physically independent. The projecting portion 88 projects in a semi-circular shape or a semi-elliptical shape from a bottom portion of the second portion 58 of the anode region 62 toward the second principal surface 4 side. A depth position of the projecting portion 88 may be, for example, not less than 5.0 μm and not more than 8.0 μm from the first principal surface 3. The depth position of the projecting portion 88 may be the same as the depth position of the trench bottom portion impurity structure 87. Also, the projecting portion 88 may have the width W2 which is wider than the width of the cell separating trench 64.

The projecting portion 88 is in a mesa shape which bulges in an arc shape with respect to the second portion 58 (the base portion 77) of the anode region 62 extending so as to continuously cross the plurality of cell separating trenches 64, and may therefore be referred to as a mesa region 89.

The second portion 58 of the anode region 62 further has a curved portion 90 between the mutually adjacent projecting portions 88. The curved portion 90 is formed in a curved shape which is raised toward the second principal surface 4 side and connects the both end portions of the mutually adjacent projecting portions 88 (mesa regions 89). For example, a projection amount with respect to a reference line L which connects connection points between the projecting portion 88 and the curved portion 90 along the first principal surface 3 is made larger at the projecting portion 88 than at the curved portion 90.

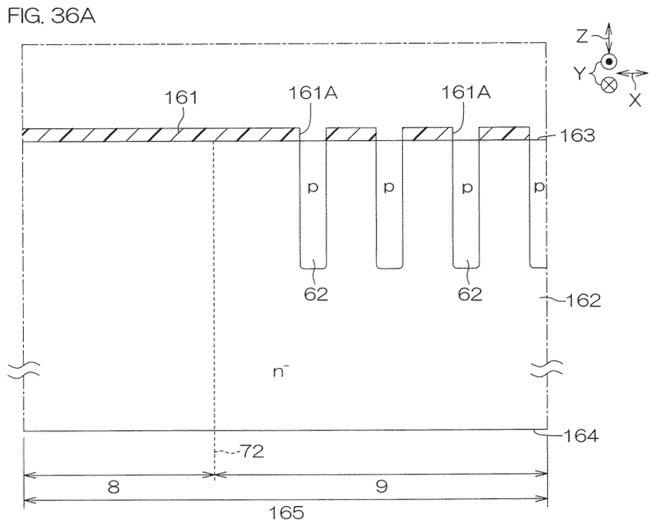

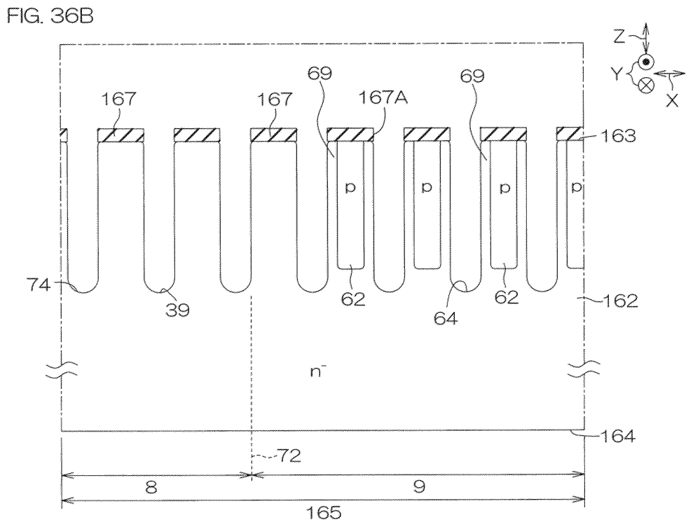

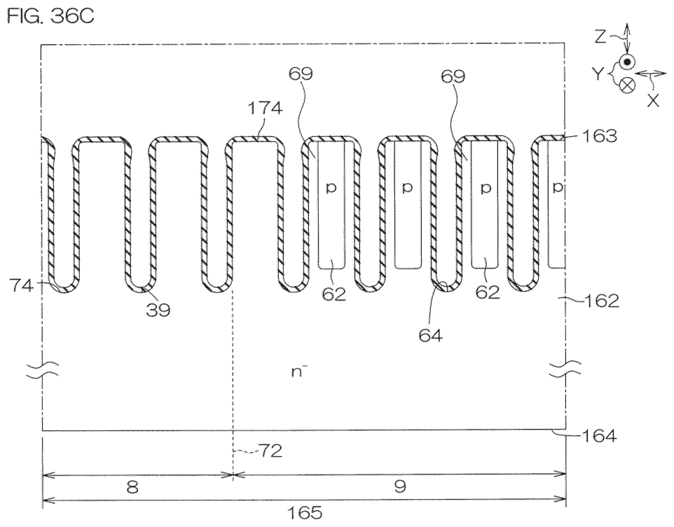

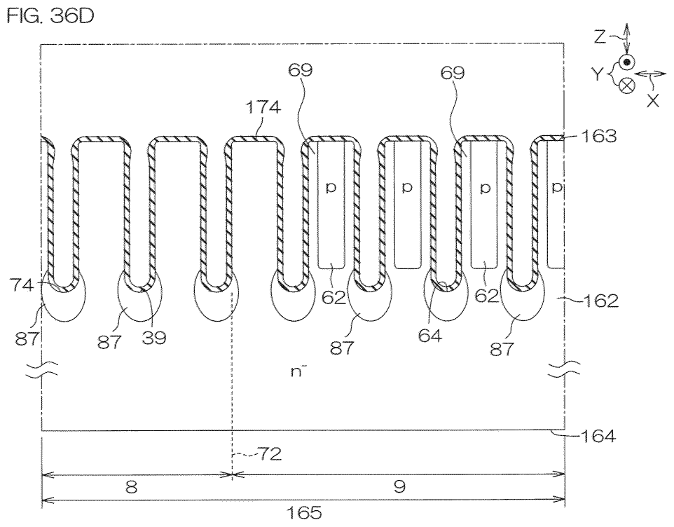

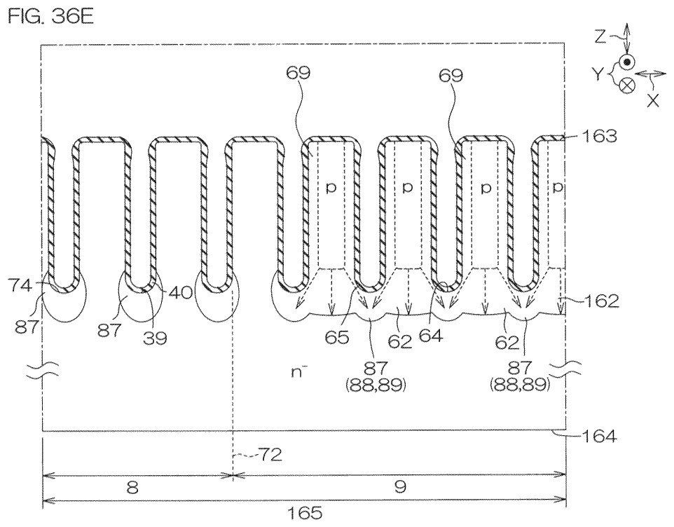

FIG. 36A to FIG. 36E are each a cross-sectional view of a region corresponding to FIG. 35, and a cross-sectional view which shows a step in relation to formation of the structure of FIG. 35. As to the manufacture of the semiconductor device 1 of FIG. 35, for example, the steps of the FIG. 10A and FIG. 10B described above may be replaced with the steps of the FIG. 36A to FIG. 36E.

First, with reference to FIG. 36A, after the device forming region 165 is set at the semiconductor wafer 162, the p type anode region 62 is formed in the diode region 9. In this step, first, the ion introducing mask 161 which is the same as FIG. 26A is formed on the first wafer principal surface 163. The ion introducing mask 161 has the plurality of openings 161A which respectively expose regions in which the plurality of anode regions 62 are to be formed. The regions in which the plurality of anode regions 62 are to be formed may be smaller than, for example, a region in which the diode cell region 69 is formed.

Next, a p type impurity is introduced into the semiconductor wafer 162 via the ion introducing mask 161. The plurality of anode regions 62 are thereby formed in the diode region 9. At this point, the plurality of anode regions 62 are physically separated from each other. Thereafter, the ion introducing mask 161 is removed.

Next, with reference to FIG. 36B, the gate trench 39 and the emitter trench 74 are formed in the IGBT region 8, and the cell separating trench 64 is formed in the diode region 9. In this step, first, the hard mask 167 which is the same as FIG. 10B is formed on the first wafer principal surface 163. The opening 167A of the hard mask 167 exposes a region between the plurality of mutually adjacent anode regions 62. Then, the unnecessary portions of the semiconductor wafer 162 are removed by an etching method via the hard mask 167. Thereby, the gate trench 39 and the emitter trench 74 are formed in the IGBT region 8, and the cell separating trench 64 is formed in the diode region 9. The cell separating trench 64 may be formed at an interval from each anode region 62. Thereafter, the hard mask 167 is removed.

Next, with reference to FIG. 36C, a sacrificial insulating layer 174 is formed in an inner surface of the gate trench 39, an inner surface of the emitter trench 74, an inner surface of the cell separating trench 64 and in the first wafer principal surface 163. The sacrificial insulating layer 174 may be formed by a CVD (chemical vapor deposition) method or an oxidation treatment method (for example, thermal oxidation treatment method).

Next, with reference to FIG. 36D, the trench bottom portion impurity structure 87 is formed. In this step, first, an ion introducing mask (not shown) having a predetermined pattern is formed on the first wafer principal surface 163. The ion introducing mask has a plurality of openings corresponding to the gate trench 39, the emitter trench 74 and the cell separating trench 64. Next, a p type impurity is introduced via the ion introducing mask into the semiconductor wafer 162. The trench bottom portion impurity structure 87 is thereby formed in each of the bottom portions of the gate trench 39, the emitter trench 74 and the cell separating trench 64. Thereafter, the ion introducing mask is removed.

Next, with reference to FIG. 36E, the plurality of anode regions 62 are diffused inside the semiconductor wafer 162 by a thermal treatment. Thereby, each anode region 62 expands along the side walls of the cell separating trench 64 in a direction toward the second principal surface 4 (vertical direction) and also expands along the first principal surface 3 in a direction toward the cell separating trench 64 (horizontal direction). The bottom wall of the cell separating trench 64 is thereby covered by the anode region 62. At this time, in the diode region 9, the anode region 62 which is diffused is made integral with the trench bottom portion impurity structure 87, and the trench bottom portion impurity structure 87 is given as the projecting portion 88 (mesa region 89).

Thereafter, by executing the same steps as FIG. 10C to FIG. 10R, the semiconductor device 1 shown in FIG. 35 is manufactured.

It is noted that, in the steps of FIG. 36A to FIG. 36E, although the steps of FIG. 26A to FIG. 26C are adopted as a method of forming the anode region 62, the anode region 62 may be formed according to the steps of FIG. 27A and FIG. 27B.

As described above, Improved Structure 2-1 is also able to widely secure an area of the pn junction portion 68, as with Improved Structure 1-1. Further, in Improved Structure 2-1, the projecting portion 88 (mesa region 89) is formed in the anode region 62, and the projecting portion 88 also forms the pn junction portion 68 with the drift region 30. The area of the pn junction portion 68 can thereby be more widely secured. As a result, it is possible to recover carriers from the anode region 62 having a wide area at the time of recovery, and it is therefore possible to promote the recovery of the carriers and decrease a recovery loss.

### (2) Improved Structure 2-2

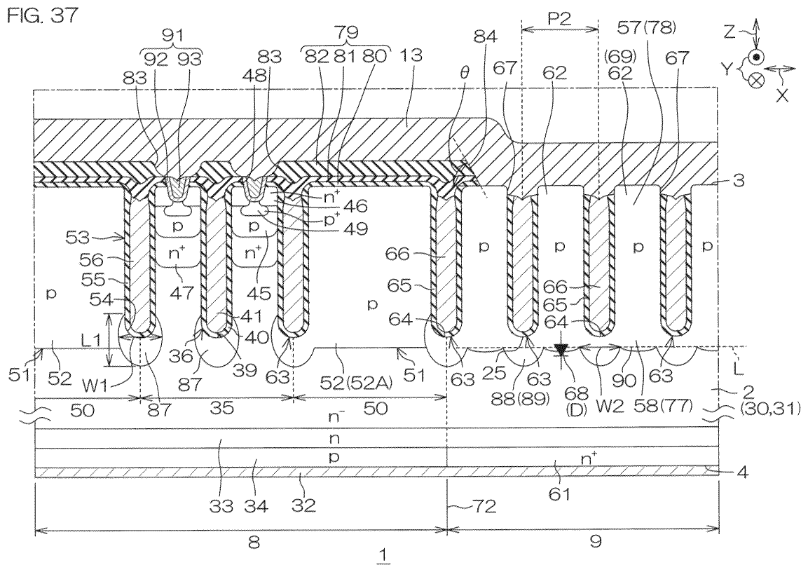

FIG. 37 is a schematic cross-sectional view which shows Improved Structure 2-2 of the semiconductor device 1. It is noted that a structure common to the aforementioned structure shall be given the same reference sign, and a description thereof shall be omitted. FIG. 37 is a cross-sectional view which corresponds to FIG. 29.

FIG. 37 shows the semiconductor device 1 in which the structure of the anode region 62 in FIG. 35 as described above is applied to the diode region 9 of the semiconductor device 1 of Improved Structure 1-2 shown in FIG. 29. That is, the anode region 62 shown in FIG. 35 is also applicable to the semiconductor device 1 which has the floating region 52.

As described above, this Improved Structure 2-2 is also able to widely secure an area of the pn junction portion 68, as with Improved Structure 2-1. As a result, it is possible to recover carriers from the anode region 62 having a wide area at the time of recovery, and it is therefore possible to promote the recovery of the carriers and decrease a recovery loss.

### (3) Improved Structure 2-3

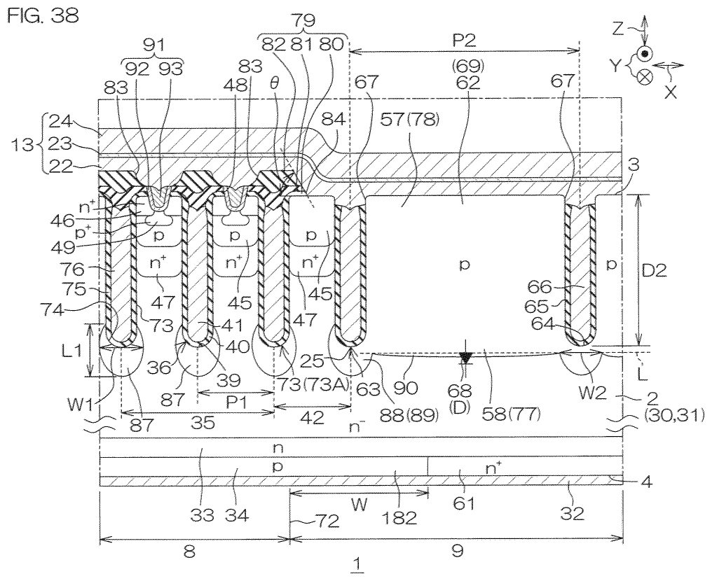

FIG. 38 is a schematic cross-sectional view which shows Improved Structure 2-3 of the semiconductor device 1. It is noted that a structure common to the aforementioned structure shall be given the same reference sign, and a description thereof shall be omitted. FIG. 38 is a cross-sectional view which corresponds to FIG. 35.

In the semiconductor device 1 shown in FIG. 38, as compared with the structure of FIG. 35, a distance (second pitch P2) between the two mutually adjacent cell separating structures 63 is made larger than a distance (first pitch P1) between the two trench gate structures 36 and the emitter trench structures 73. For example, the second pitch P2 may be not less than 2.0 times and not more than 3.0 times larger than the first pitch P1. Specifically, the first pitch P1 may be not less than 1.2 μm and not more than 3.5 μm, and the second pitch P2 may be not less than 2.4 μm and not more than 10.5 μm.

As described above, Improved Structure 2-3 is also able to widely secure an area of the pn junction portion 68, as with Improved Structure 2-1. As a result, it is possible to recover carriers from the anode region 62 having a wide area at the time of recovery, and it is therefore possible to promote the recovery of the carriers and decrease a recovery loss.

Also, in Improved Structure 2-3, by setting a relationship of the second pitch P2>the first pitch P1, it is made possible to enlarge an area of the anode region 62 which is exposed to the first principal surface 3 between the mutually adjacent cell separating trenches 64. It is thereby possible to widely secure an area of the anode contact of the pn junction diode D. As a result, it is possible to relax the carrier storage effects at the time of recovery, and it is therefore possible to decrease a recovery loss.

### (4) Improved Structure 2-4

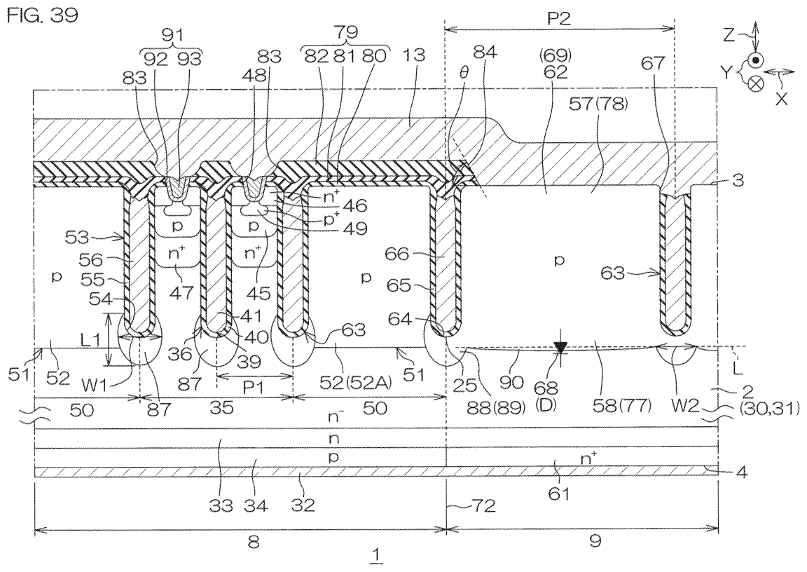

FIG. 39 is a schematic cross-sectional view which shows Improved Structure 2-4 of the semiconductor device 1. It is noted that a structure common to the aforementioned structure shall be given the same reference sign, and a description thereof shall be omitted. FIG. 39 is a cross-sectional view which corresponds to FIG. 37.

In the semiconductor device 1 of FIG. 39, as compared with the structure of FIG. 37, a distance (second pitch P2) between the mutually adjacent two cell separating structures 63 is made larger than a distance (first pitch P1) between the two trench gate structures 36 and the region separating trench structures 53. For example, the second pitch P2 may be not less than 2.0 times and not more than 3.0 times larger than the first pitch P1. Specifically, the first pitch P1 may be not less than 1.2 μm and not more than 3.5 μm, and the second pitch P2 may be not less than 2.4 μm and not more than 10.5 μm.

As described above, Improved Structure 2-4 is also able to widely secure an area of the pn junction portion 68, as with Improved Structure 2-1. As a result, it is possible to recover carriers from the anode region 62 having a wide area at the time of recovery, and it is therefore possible to promote the recovery of the carriers and decrease a recovery loss.

Also, in Improved Structure 2-4, by setting a relationship of the second pitch P2>the first pitch P1, it is made possible to enlarge an area of the anode region 62 which is exposed to the first principal surface 3 between the mutually adjacent cell separating trenches 64. It is thereby possible to widely secure an area of the anode contact of the pn junction diode D. As a result, it is possible to relax the carrier storage effects at the time of recovery, and it is therefore possible to decrease a recovery loss.

### [Improved Structure 3 of Semiconductor Device 1]

### (1) Improved Structure 3-1

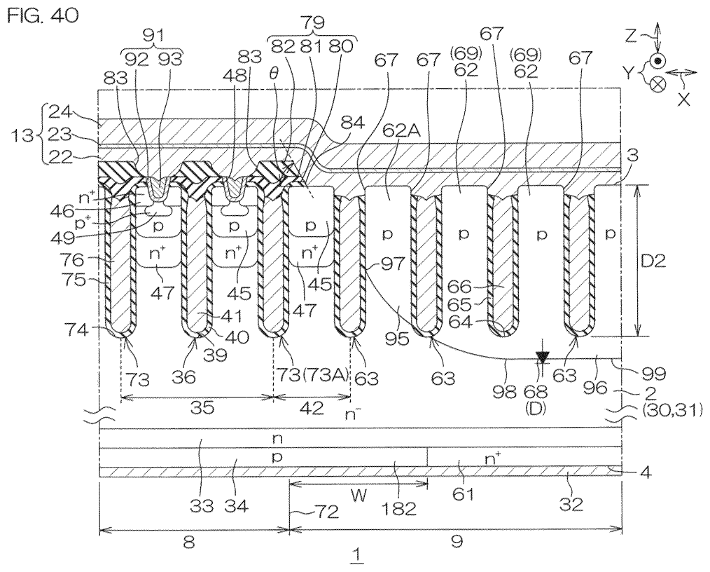

FIG. 40 is a schematic cross-sectional view which shows Improved Structure 3-1 of the semiconductor device 1. It is noted that a structure common to the aforementioned structure shall be given the same reference sign, and a description thereof shall be omitted. FIG. 40 is a cross-sectional view which corresponds to FIG. 25.

In Improved Structure 3-1, the anode region 62 integrally includes an inclined portion 95 and a flat portion 96. The inclined portion 95 is downwardly inclined to a position deeper than the bottom wall of the cell separating trench 64 in a direction away from the IGBT region 8 from the side wall of at least one of the cell separating trenches 64 ( ) toward the second principal surface 4. In this preferred embodiment, it is downwardly inclined toward the second principal surface 4, with the cell separating trench 64 adjacent to the termination emitter trench structure 73A (the cell separating trench 64 which is closest to the IGBT region 8 among the plurality of cell separating trenches 64) given as a starting point 97. The inclined portion 95 may be a curved portion which is curved in a circular-arc shape toward the IGBT region 8.

Also, the inclined portion 95 may be divided by the cell separating trench 64. In this preferred embodiment, it is divided by the cell separating trench 64 adjacent to the cell separating trench 64 which forms the starting point 97 of the inclined portion 95. The anode region 62 which is downwardly inclined toward the second principal surface 4 and also connects the side walls of the cell separating trench 64 is thereby formed between the cell separating trenches 64 that are adjacent to each other in the vicinity of the IGBT region 8. The anode region 62 has a bottom portion which is inclined with respect to the first principal surface 3, and may therefore be referred to as an inclined anode region 62A.

The flat portion 96 is continuous to a lower end 98 of the inclined portion 95, extends along the first principal surface 3 and integrally covers the bottom walls of the plurality of cell separating trenches 64 from the second principal surface 4 side. A bottom portion 99 of the flat portion 96 may be substantially parallel to the first principal surface 3.

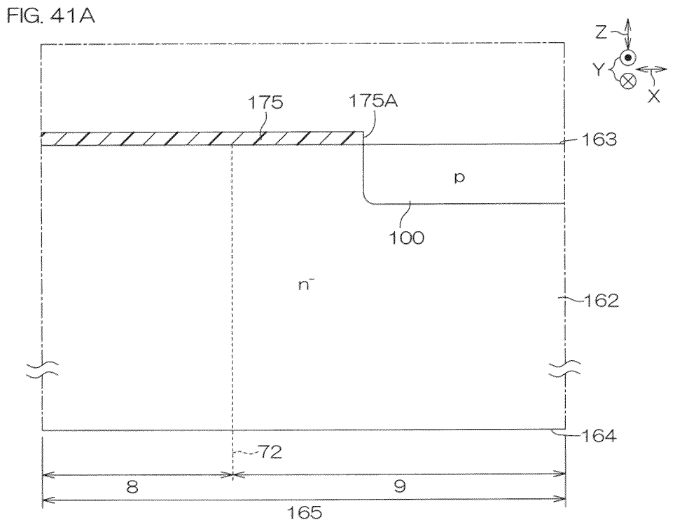

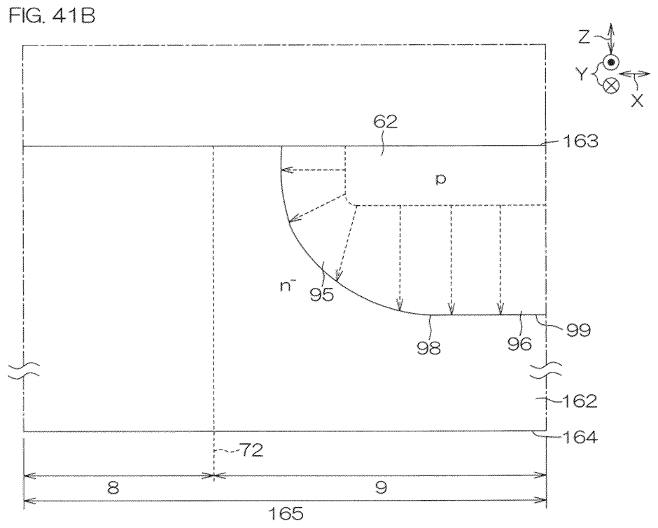

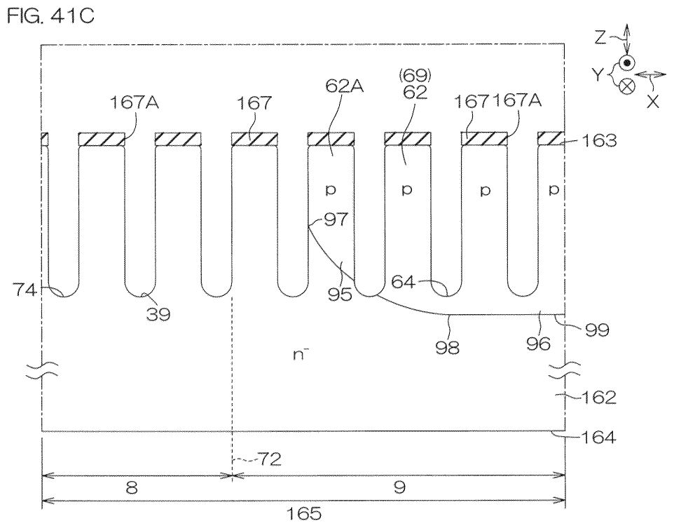

FIG. 41A to FIG. 41C are each a cross-sectional view of a region corresponding to FIG. 40, and a cross-sectional view which shows a step in relation to formation of the structure of FIG. 40. As to the manufacture of the semiconductor device 1 of FIG. 40, for example, the steps of FIG. 10A and FIG. 10B described above may be replaced with the steps of FIG. 41A to FIG. 41C.

First, with reference to FIG. 41A, after the device forming region 165 is set at the semiconductor wafer 162, a p type impurity introducing region 100 is formed in the diode region 9. In this step, first, an ion introducing mask 175 which is the same as FIG. 26A is formed on the first wafer principal surface 163. The ion introducing mask 175 has a plurality of openings 175A which respectively expose regions in which the impurity introducing region 100 is to be formed. Next, a p type impurity is introduced into the semiconductor wafer 162 via the ion introducing mask 175. The impurity introducing region 100 is thereby formed in the diode region 9.

Next, with reference to FIG. 41B, the impurity introducing region 100 is diffused inside the semiconductor wafer 162 by a thermal treatment. Thereby, the impurity introducing region 100 expands in a direction toward the second principal surface 4 (vertical direction) and also expands in a direction along the first principal surface 3 (horizontal direction). The anode region 62 of a predetermined depth having the inclined portion 95 and the flat portion 96 is thereby formed.

Next, with reference to FIG. 41C, the gate trench 39 and the emitter trench 74 are formed in the IGBT region 8, and the cell separating trench 64 is formed in the diode region 9. In this step, first, the hard mask 167 which is the same as FIG. 10B is formed on the first wafer principal surface 163. The opening 167A of the hard mask 167 selectively exposes the anode region 62 having the inclined portion 95. Then, the unnecessary portions of the semiconductor wafer 162 are removed by an etching method via the hard mask 167. Thereby, the gate trench 39 and the emitter trench 74 are formed in the IGBT region 8, and the cell separating trench 64 is formed in the diode region 9.

Thereafter, by executing the same steps as FIG. 10C to FIG. 10R, the semiconductor device 1 shown in FIG. 40 is manufactured.

As described above, Improved Structure 3-1 is also able to widely secure an area of the pn junction portion 68, as with Improved Structure 1-1. As a result, it is possible to recover carriers from the anode region 62 having a wide area at the time of recovery, and it is therefore possible to promote the recovery of the carriers and decrease a recovery loss.

### (1) Improved Structure 3-2

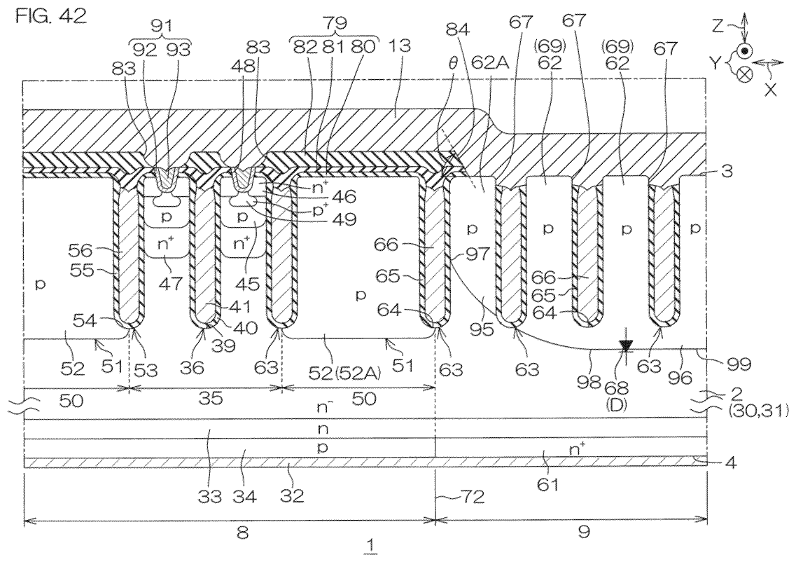

FIG. 42 is a schematic cross-sectional view which shows Improved Structure 3-2 of the semiconductor device 1. It is noted that a structure common to the aforementioned structure shall be given the same reference sign, and a description thereof shall be omitted. FIG. 42 is a cross-sectional view which corresponds to FIG. 29.

FIG. 42 shows the semiconductor device 1 in which the structure of the anode region 62 shown in FIG. 40 described above is applied to the diode region 9 of the semiconductor device 1 of Improved Structure 1-2 of FIG. 29. That is, the anode region 62 shown in FIG. 40 is also applicable to the semiconductor device 1 which has the floating region 52.

As described above, Improved Structure 3-2 is also able to widely secure an area of the pn junction portion 68, as with Improved Structure 3-1. As a result, it is possible to recover carriers from the anode region 62 having a wide area at the time of recovery, and it is therefore possible to promote the recovery of the carriers and decrease a recovery loss.

[Improved Structure 4 of semiconductor device 1]

### (1) Improved Structure 4-1

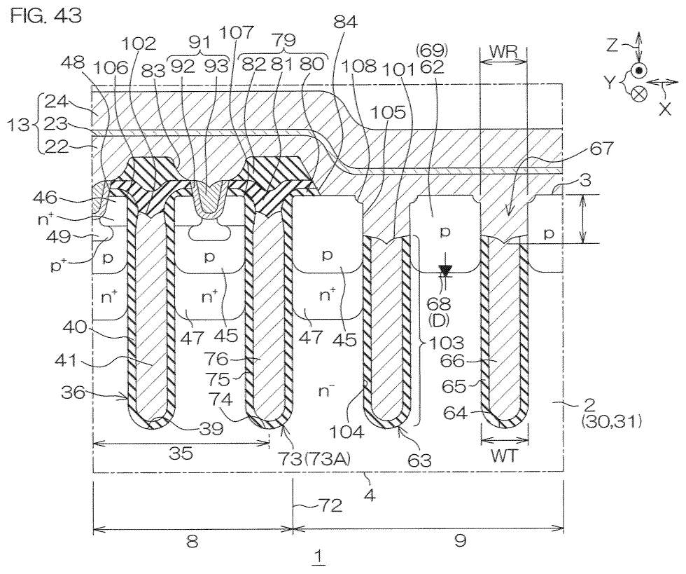

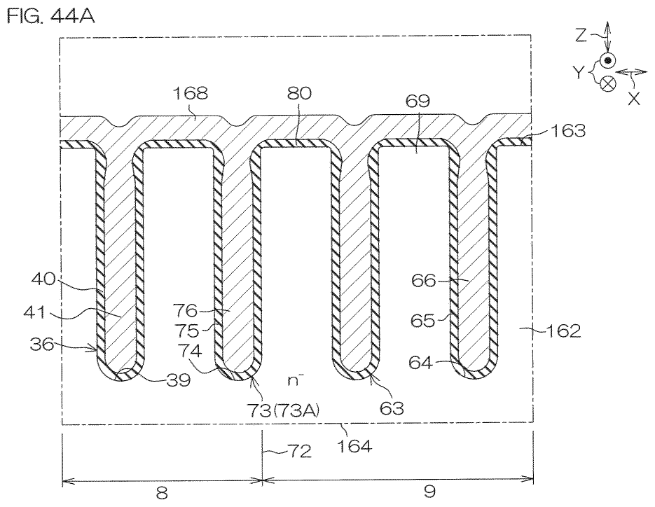

FIG. 43 is a schematic cross-sectional view which shows Improved Structure 4-1 of the semiconductor device 1. It is noted that a structure common to the aforementioned structure shall be given the same reference sign, and a description thereof shall be omitted. FIG. 43 is a cross-sectional view which corresponds to FIG. 8, and a drawing in which a part of FIG. 8 is enlarged. In FIG. 43, for the sake of convenience, the same reference sign as the second principal surface 4 is given to a position at the second principal surface 4 side.

With reference to FIG. 43, in this preferred embodiment, the cell separating electrode layer 66 is dug down with respect to the first principal surface 3, by which an upper end portion 101 (upper surface) of the cell separating electrode layer 66 is positioned further at the second principal surface 4 side than an upper end portion 102 (upper surface) of the gate electrode layer 41 with respect to the first principal surface 3. The recess 67 is thereby formed deeper than the upper end portion 102 of the gate electrode layer 41.

The cell separating trench 64 has the recess 67 and a trench backfilled portion 103 which is formed at the second principal surface 4 side with respect to the recess 67. The trench backfilled portion 103 is a portion which is backfilled by the cell separating electrode layer 66 in the cell separating trench 64. The trench backfilled portion 103 has a flat side wall 104. The recess 67 has a flat side wall 105 which is an extended portion of the side wall 104 of the trench backfilled portion 103. Therefore, the cell separating trench 64 has a flat side wall which continues from the first principal surface 3 to the side wall. The recess 67 and the trench backfilled portion 103 are thereby continuous at a substantially constant width from the first principal surface 3 toward the bottom wall of the cell separating trench 64. That is, a width WR of the recess 67 may be the same as a width WT of the trench backfilled portion 103.

Also, an opening edge portion of the gate trench 39 has a corner portion 106 at which the first principal surface 3 intersects a side wall of the gate trench 39. Similarly, an opening edge portion of the emitter trench 74 has a corner portion 107 at which the first principal surface 3 intersects a side wall of the emitter trench 74.

An opening edge portion of the cell separating trench 64 has a recessed edge portion 108 in a circular arc shape which is recessed toward an interior of the diode cell region 69. That is, the opening edge portion of the cell separating trench 64 is substantially different in shape from the opening edge portion of the gate trench 39 and the opening edge portion of the emitter trench 74. In FIG. 43, for clarification, a front surface of the recessed edge portion 108 is indicated by a smooth curved surface, however, for example, fine unevenness (such as fine surface roughness which develops at the time of etching, etc.) may be formed in the above-described curved surface.

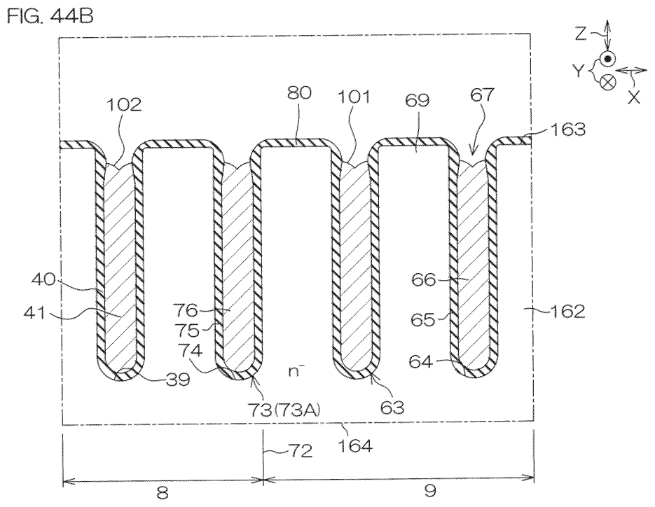

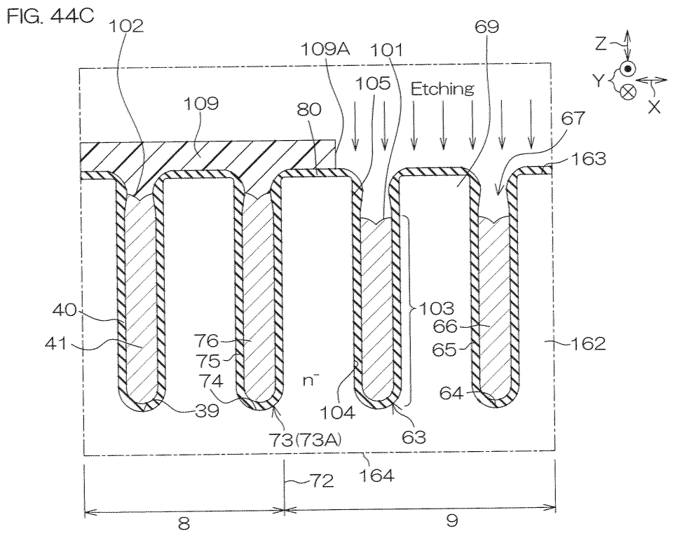

FIG. 44A to FIG. 44C are each a cross-sectional view of a region which corresponds to FIG. 43, and a cross-sectional view which shows a step in relation to formation of the structure of FIG. 43. As to the manufacture of the semiconductor device 1 shown in FIG. 43, for example, the steps of FIG. 10D and FIG. 10E described above may be replaced with the steps of FIG. 44A to FIG. 44C.

First, with reference to FIG. 44A, after the gate insulating layer 40, the emitter insulating layer 75, the cell separating insulating layer 65 and the first insulating layer 80 are formed in the first wafer principal surface 163, the base electrode layer 168 is formed.

Next, with reference to FIG. 44B, the unnecessary portions of the base electrode layer 168 are removed by an etching method. The etching method may be a wet etching method. The base electrode layer 168 is collectively removed from the IGBT region 8 and the diode region 9. Therefore, at this point, the upper end portion 101 (upper surface) of the cell separating electrode layer 66 may be at the same depth position as the upper end portion 102 (upper surface) of the gate electrode layer 41.

Next, with reference to FIG. 44C, in a state where the gate electrode layer 41 is masked, the cell separating electrode layer 66 is selectively dug down. In this step, a resist mask 109 having an opening 109A which selectively exposes the diode region 9 is formed in the first wafer principal surface 163. Next, an upper portion of the cell separating electrode layer 66 is removed by an etching method via the resist mask 109. The etching method may be a dry etching method. Thereby, the recess 67 expands in volume in a depth direction toward the bottom wall of the cell separating trench 64, and a difference in height is developed between the upper end portion 101 (upper surface) of the cell separating electrode layer 66 and the upper end portion 102 (upper surface) of the gate electrode layer 41.

Thereafter, by executing the same steps as FIG. 10F to FIG. 10R, the semiconductor device 1 shown in FIG. 40 is manufactured. It is noted that the recessed edge portion 108 of the cell separating trench 64 may be formed by selectively chipping a corner portion of the opening edge portion of the cell separating trench 64, for example, by etching performed in a step of forming the diode opening 84 (see FIG. 10N). Therefore, there is a case where, under certain etching conditions, recessed edge portion 108 may not be formed when the etching is performed in the step of forming the diode opening 84 (see FIG. 10N). In that case, the opening edge portion of the cell separating trench 64 may have the same corner portion as the corner portion 106 of the gate trench 39.

As described above, according to Improved Structure 4-1, the recess 67 is formed in the opening edge portion of the cell separating trench 64. Also, the upper end portion 101 (upper surface) of the cell separating electrode layer 66 which is exposed to the recess 67 is positioned further at the second principal surface 4 side than the upper end portion 102 (upper surface) of the gate electrode layer 41 with respect to the first principal surface 3. An area of the anode region 62 which is exposed to a side wall of the recess 67 can thereby be widely secured. Therefore, as compared with a case where a contact portion of the emitter terminal electrode 13 with the anode region 62 is restricted to the first principal surface 3 of the semiconductor layer 2, an area of the anode contact of the pn junction diode D can be widely secured. As a result, it is possible to relax the carrier storage effects at the time of recovery, and it is therefore possible to decrease a recovery loss.

### [Improved Structure 5 of Semiconductor Device 1]

### (1) Improved Structure 5-1

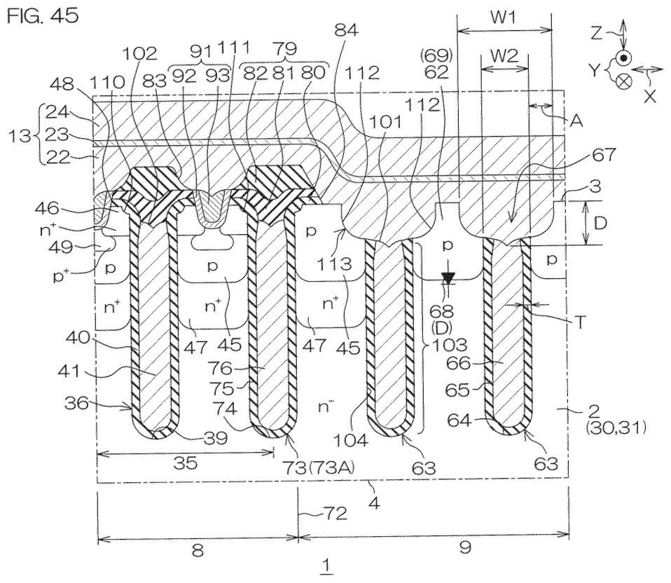

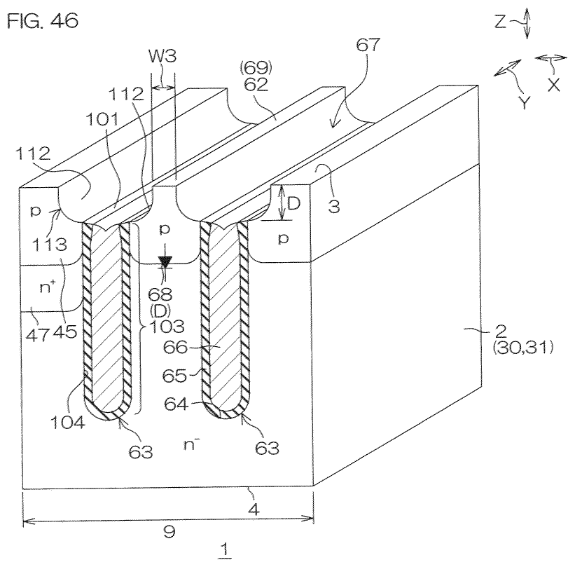

FIG. 45 is a schematic cross-sectional view which shows Improved Structure 5-1 of the semiconductor device 1. FIG. 46 is a schematic perspective view which shows Improved Structure 5-1 of the semiconductor device 1. It is noted that a structure common to the aforementioned structure shall be given the same reference sign, and a description thereof shall be omitted. FIG. 45 is a cross-sectional view which corresponds to FIG. 43. Also, FIG. 46 is a partially enlarged view of FIG. 45. In FIG. 45 and FIG. 46, for the sake of convenience, the same reference sign as the second principal surface 4 is given to a position at the second principal surface 4 side.

With reference to FIG. 45, the opening edge portion of the gate trench 39, the opening edge portion of the emitter trench 74 and the opening edge portion of the cell separating trench 64 all have a recessed edge portion which is recessed toward an interior of the semiconductor layer 2. In FIG. 45, a recessed edge portion 110 is the opening edge portion of the gate trench 39, a recessed edge portion 111 is the opening edge portion of the emitter trench 74, and a recessed edge portion 112 is the opening edge portion of the cell separating trench 64.

The recessed edge portion 112 at the cell separating trench 64 side is formed in a circular arc shape which is recessed to a larger extent than the recessed edge portion 110 at the gate trench 39 side and the recessed edge portion 111 at the emitter trench 74 side. That is, the opening edge portion of the cell separating trench 64 is substantially different in shape from the opening edge portion of the gate trench 39 and the opening edge portion of the emitter trench 74. In FIG. 45, for the sake of clarification, a front surface of the recessed edge portion 112 is indicated by a smooth curved surface, however, for example, fine unevenness (such as fine surface roughness which develops at the time of etching, etc.) may be formed in the above-described curved surface.

The recess 67 includes a cup portion 113. The cup portion 113 has a side wall at the recessed edge portion 112 which is downwardly inclined in a curved line toward the trench backfilled portion 103 from the first principal surface 3 of the diode cell region 69 at both sides neighboring to one side and the other side of the cell separating trench 64 in the first direction X. The cup portion 113 is thereby formed in a cup shape in sectional view.

For example, a recessed amount A of the recessed edge portion 112 toward an interior of the diode cell region 69 in a direction along the first principal surface 3 may be not less than 1.0 times and not more than 10.0 times larger than a thickness T of the cell separating insulating layer 65. Specifically, the thickness T of the cell separating insulating layer 65 may be not less than 80 nm and not more than 150 nm, and the recessed amount A of the recessed edge portion 112 may be not less than 0.05 μm and not more than 1.5 μm. The cup portion 113 may thereby have a width W1 which is not less than 0.62 times and not more than 6.14 times larger than a width W2 of the trench backfilled portion 103. Specifically, the width W2 of the trench backfilled portion 103 may be not less than 0.7 μm and not more than 1.3 μm, and the width W1 of the cup portion 113 may be not less than 0.80 μm and not more than 4.3 μm.

With reference to FIG. 46, the cup portion 113 may be formed in a semi-cylindrical shape along the second direction Y. The cell separating electrode layer 66 of the trench backfilled portion 103 and the upper end portion 101 of the cell separating insulating layer 65 are thereby exposed in a straight line extending along the second direction Y at a lower end of the cup portion 113. Also, the cup portion 113 may have a depth D which is not less than 0.0052 times and not more than 7.5 times larger than a width W3 of the first principal surface 3 of the diode cell region 69. Specifically, the width W3 of the first principal surface 3 of the diode cell region 69 may be not less than 0.2 μm and not more than 9.7 μm, and the depth D of the cup portion 113 may be not less than 0.05 μm and not more than 1.5 μm.

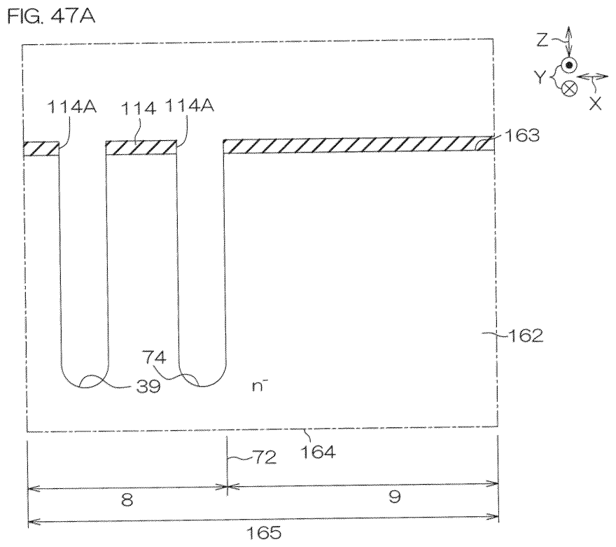

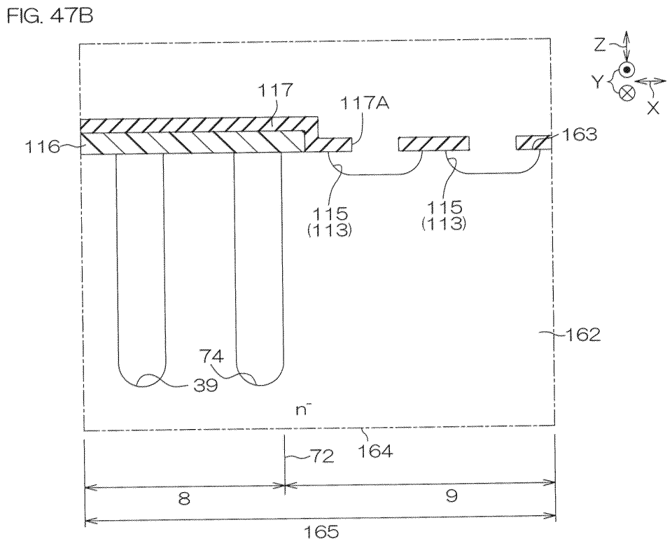

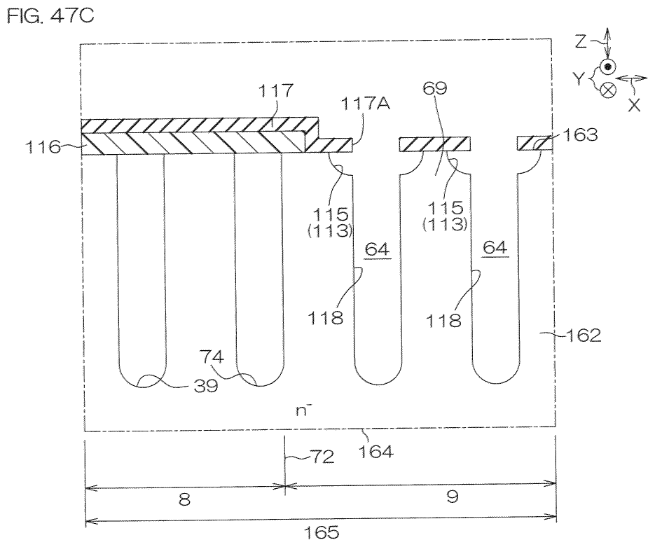

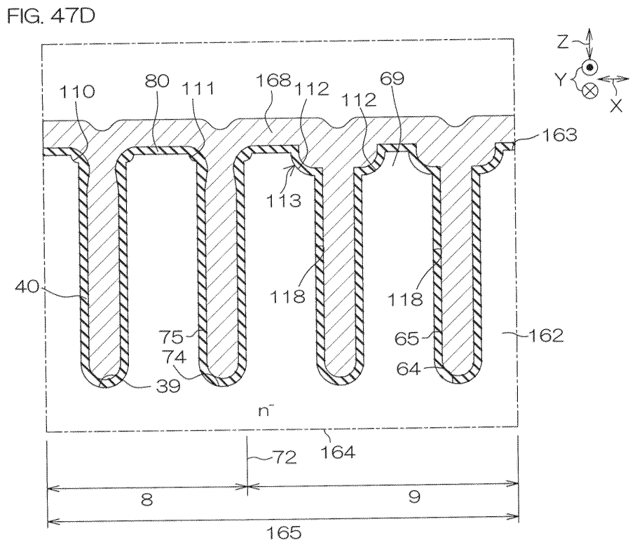

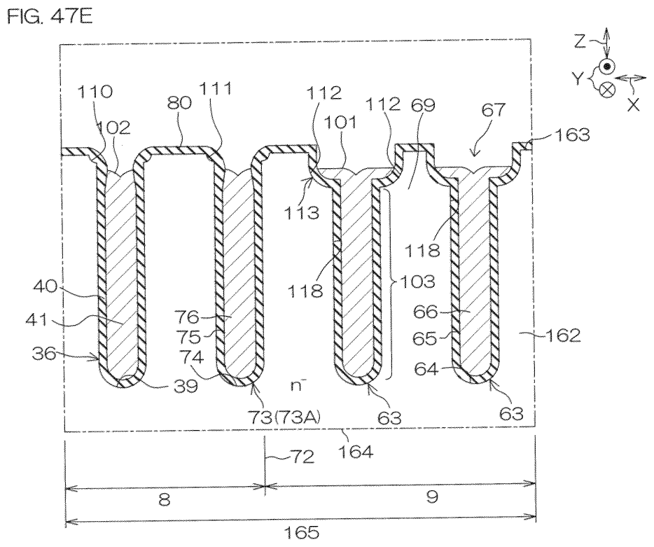

FIG. 47A to FIG. 47E are each a cross-sectional view of a region which corresponds to FIG. 45, and a cross-sectional view which shows a step in relation to formation of the structure of FIG. 45 and FIG. 46. As to the manufacture of the semiconductor device 1 shown in the FIG. 45 and FIG. 46, for example, the steps of FIG. 10A to FIG. 10E described above may be replaced with the steps of FIG. 47A to FIG. 47E.

First, with reference to FIG. 47A, after the plurality of device forming regions 165 are set at the n⁻ type semiconductor wafer 162, the gate trench 39 and the emitter trench 74 are formed in the IGBT region 8. In this step, first, a hard mask 114 having a predetermined pattern is formed on the first wafer principal surface 163. The hard mask 114 has a plurality of openings 114A which respectively expose regions in which the gate trench 39 and the emitter trench 74 are to be formed. The hard mask 114 may be formed by an oxidation treatment method performed on the first wafer principal surface 163. Next, the unnecessary portions of the semiconductor wafer 162 are removed by an etching method via the hard mask 114. The gate trench 39 and the emitter trench 74 are thereby formed in the IGBT region 8. Thereafter, the hard mask 114 is removed.

Next, with reference to FIG. 47B, a recess portion 115 for the cell separating trench 64 is formed in the diode region 9. In this step, first, a resist mask 116 which selectively covers the IGBT region 8 and exposes the diode region 9 is formed on the first wafer principal surface 163. Next, a hard mask 117 having a predetermined pattern is formed on the first wafer principal surface 163. The hard mask 117 has a plurality of openings 117A which respectively expose regions in which the cell separating trenches 64 are to be formed. The hard mask 117 may be formed by an oxidation treatment method performed on the first wafer principal surface 163. Next, a surface layer portion of the semiconductor wafer 162 is selectively removed by a wet etching method via the hard mask 117. At this time, since the etching progresses in an isotropic manner, the recess portion 115 having a wider width than that of the opening 117A is formed in a surface layer portion of the first wafer principal surface 163 of the semiconductor wafer 162. The recess portion 115 serves as a base of the cup portion 113.

Next, with reference to FIG. 47C, the etching performed on the semiconductor wafer 162 is switched from wet etching to dry etching. A trench main body portion 118 having a width narrower than that of the recess portion 115 is thereby formed from a bottom wall of the recess portion 115 by the dry etching (anisotropic etching) via the opening 117A having a width narrower than that of recess portion 115. The cell separating trench 64 in which the recess portion 115 and the trench main body portion 118 are thereby made integral is formed. The trench main body portion 118 is a trench part of the trench backfilled portion 103.

Next, with reference to FIG. 47D, the gate insulating layer 40, the emitter insulating layer 75, the cell separating insulating layer 65 and the first insulating layer 80 are formed in the first wafer principal surface 163. The gate insulating layer 40, the emitter insulating layer 75, the cell separating insulating layer 65 and the first insulating layer 80 may be formed by a CVD (chemical vapor deposition) method or an oxidation treatment method (for example, thermal oxidation treatment method). The recessed edge portion 110 of the gate trench 39 and the recessed edge portion 111 of the emitter trench 74 may be formed by the thermal oxidation treatment method. For example, in the opening edge portions of the gate trench 39 and the emitter trench 74, a thermal oxidation progresses from both sides, that is, from each side wall and the first principal surface 3, by which a corner portion of the opening edge portion is selectively chipped, and the recessed edge portion 110 and the recessed edge portion 111 are formed. Next, a base electrode layer 168 is formed. The base electrode layer 168 serves as a base of each of the gate electrode layer 41, the emitter potential electrode layer 76 and the cell separating electrode layer 66. The base electrode layer 168 contains a conductive polysilicon. The base electrode layer 168 may be formed by a CVD method.

Next, with reference to FIG. 47E, the unnecessary portions of the base electrode layer 168 are removed by an etching method. The etching method may be a wet etching method. The base electrode layer 168 is collectively removed from the IGBT region 8 and the diode region 9. Therefore, at this point, the upper end portion 101 (upper surface) of the cell separating electrode layer 66 may be at the same depth position as the upper end portion 102 (upper surface) of the gate electrode layer 41.

Thereafter, by executing the same steps as FIG. 10F to FIG. 10R, the semiconductor device 1 shown in FIG. 45 and FIG. 46 is manufactured. It is noted that the upper end portion 101 (upper surface) of the cell separating electrode layer 66 may be lowered to a position of an upper end of the trench main body portion 118, for example, by etching performed in the step of forming the diode opening 84 (see FIG. 10N). A difference in height is thereby formed between the upper end portion 101 (upper surface) of the cell separating electrode layer 66 and the upper end portion 102 (upper surface) of the gate electrode layer 41.

As described above, since the recess 67 (cup portion 113) in the opening edge portion of the cell separating trench 64 is formed in Improved Structure 5-1 as well, an area of the anode region 62 which is exposed to a side wall of the recess 67 can be widely secured. Therefore, as compared with a case where a contact portion of the emitter terminal electrode 13 with the anode region 62 is restricted to the first principal surface 3 of the semiconductor layer 2, an area of the anode contact of the pn junction diode D can be widely secured. As a result, it is possible to relax the carrier storage effects at the time of recovery, and it is therefore possible to decrease a recovery loss.

Further, Improved Structure 5-1 is effective in a case where it is found difficult to adopt a plug electrode such as the emitter plug electrode 91 as an anode contact. For example, a method for improving the recovery characteristics of the pn junction diode D is to keep an impurity concentration of the anode region 62 low. This is due to the fact that a carrier injection amount from the anode region 62 can thereby be decreased. On the other hand, when the impurity concentration of the anode region 62 is made low, the anode contact becomes high in contact resistance, resulting in an increase in forward voltage VF of the pn junction diode D. Therefore, the barrier layer necessary for the plug electrode is relatively high in resistance and difficult to use. Thus, a structure in which the emitter terminal electrode 13 is directly connected to the anode region 62, as in the semiconductor device 1, is adopted.

However, aluminum used in the emitter terminal electrode 13 is not high in embedding property, therefore, when the recess 67 having the same width as the trench backfilled portion 103 is adopted, there is a case where it is difficult to properly embed the emitter terminal electrode 13 in the recess 67. In particular, in circumstances where a microfabrication process is increased, this problem becomes more apparent as a pitch between trenches that are formed in the semiconductor layer 2 is made narrower. Thus, by providing the cup portion 113 having the width W2 larger than the width W1 of the trench backfilled portion 103 as an anode contact portion, it is made possible to satisfactorily embed the emitter terminal electrode 13 and make a contact with the anode region 62.

### [Improved Structure 6 of Semiconductor Device 1]

### (1) Improved Structure 6-1

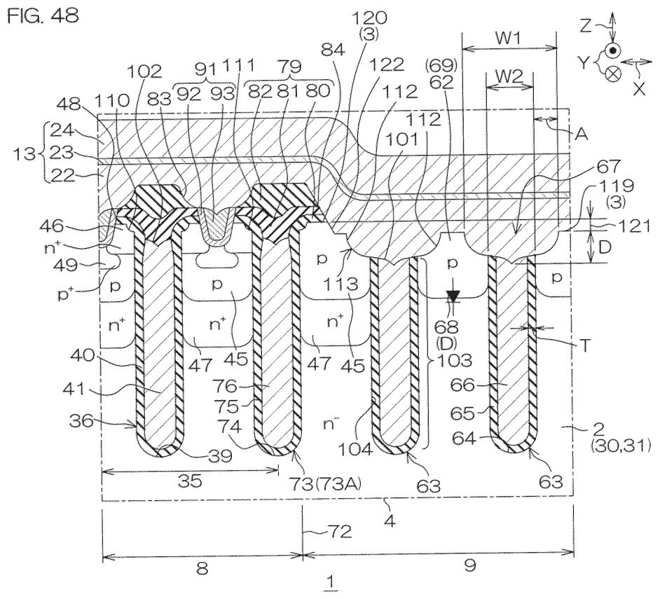

FIG. 48 is a schematic cross-sectional view which shows Improved Structure 6-1 of the semiconductor device 1. It is noted that a structure common to the aforementioned structure shall be given the same reference sign, and a description thereof shall be omitted. FIG. 48 is a cross-sectional view which corresponds to FIG. 45. In FIG. 48, for the sake of convenience, the same reference sign as the second principal surface 4 is given to a position at the second principal surface 4 side.

With reference to FIG. 48, in this preferred embodiment, the first principal surface 3 of the semiconductor layer 2 includes a diode first principal surface 119 which is formed in the diode cell region 69 and an IGBT first principal surface 120 which is formed in the IGBT region 8. A step 121 is formed between the diode first principal surface 119 and the IGBT first principal surface 120. A size of the step 121 may be, for example, not less than 100 nm and not more than 500 nm. The step 121 is formed by a step surface 122 which connects the diode first principal surface 119 and the IGBT first principal surface 120. The diode first principal surface 119 thereby assumes a low position at the second principal surface 4 side with respect to the IGBT first principal surface 120.

The step surface 122 may be a surface extending in a direction which intersects the diode first principal surface 119 and the IGBT first principal surface 120. In this preferred embodiment, it is formed so as to be continuous to an inner wall of the interlayer insulating layer 79 which forms the diode opening 84 at the boundary 72 between the diode region 9 and the IGBT region 8. As shown in FIG. 48, the step surface 122 may be flush with a side wall of the interlayer insulating layer 79. Therefore, the step surface 122 may be an inclined surface which is inclined to both of the diode first principal surface 119 and the IGBT first principal surface 120.

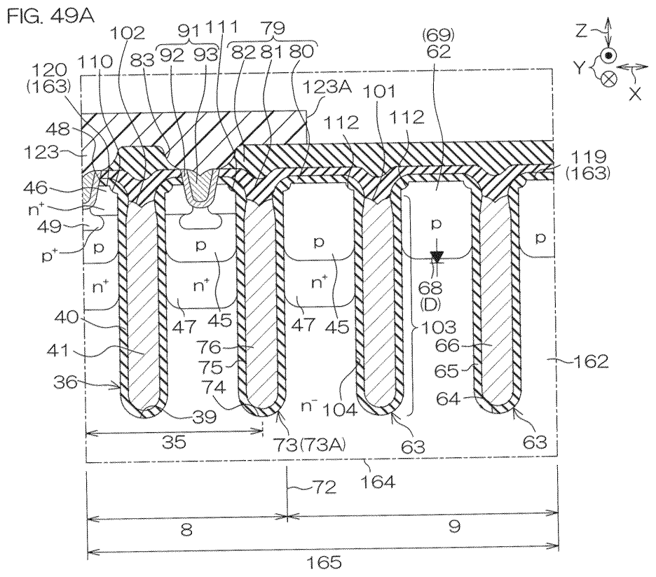

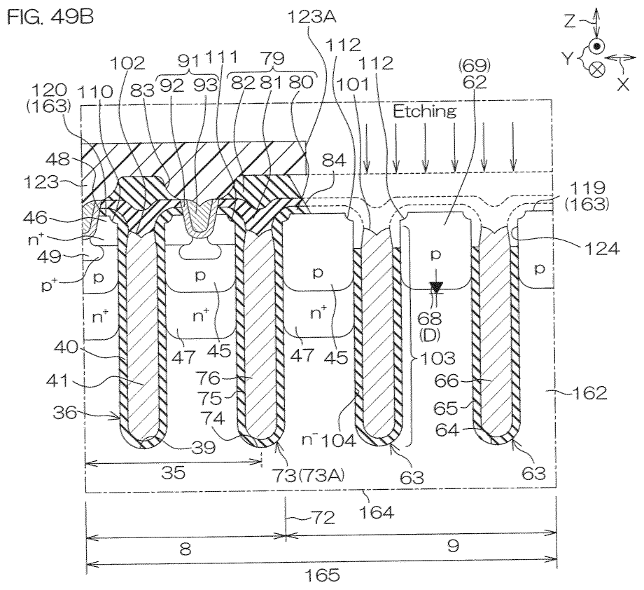

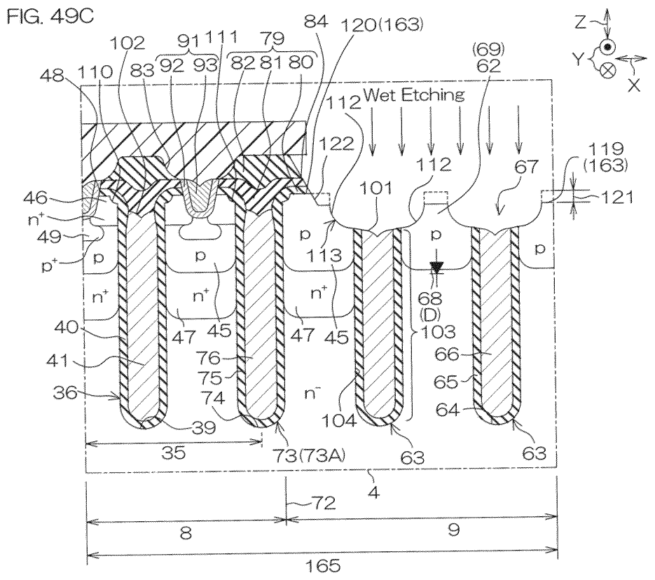

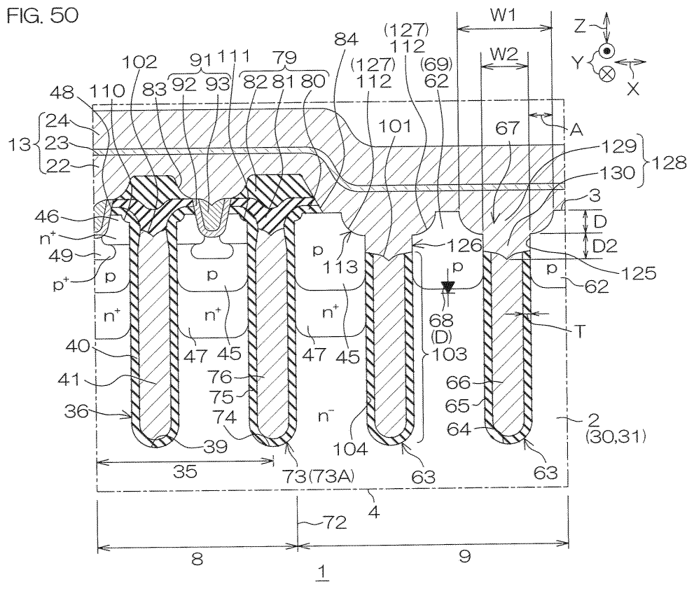

FIG. 49A to FIG. 49C are each a cross-sectional view of a region which corresponds to FIG. 48, and a cross-sectional view which shows a step in relation to formation of the structure of FIG. 48. As to the manufacture of the semiconductor device 1 of FIG. 48, for example, the step of FIG. 10N described above may be replaced with the steps of FIG. 49A to FIG. 49C.

With reference to FIG. 49A, after the emitter plug electrode 91 is formed in the step of FIG. 10M, the diode opening 84 is formed in the diode region 9. In this step, first, a mask 123 having a predetermined pattern is formed on the interlayer insulating layer 79. The mask 123 has an opening 123A which exposes each region in which the diode opening 84 is to be formed.

Next, with reference to FIG. 49B, the unnecessary portions of the interlayer insulating layer 79 are removed by an etching method via the mask 123. The etching method is preferably an anisotropic etching method. The anisotropic etching method may be a dry etching method (specifically, an RIE (reactive ion etching) method).

In this step, the unnecessary portions of the first insulating layer 80, the unnecessary portions of the second insulating layer 81 and the unnecessary portions of the third insulating layer 82 are sequentially removed by the anisotropic etching method. The diode opening 84 is thereby formed. Further, an upper end portion of the cell separating insulating layer 65 is removed subsequent to removal of the first insulating layer 80. A gap 124 which is sandwiched between the cell separating electrode layer 66 and a side wall of the cell separating trench 64 is thereby formed. Thereafter, the mask 123 is removed.

Next, with reference to FIG. 49C, the etching performed on the semiconductor wafer 162 is switched from dry etching (anisotropic etching) to wet etching. An isotropic etching thereby progresses so as to give a shape of the cup portion 113 due to a difference in etching rate between the semiconductor wafer 162 (monocrystalline silicon) and the cell separating electrode layer 66 (polycrystalline silicon). The cup portion 113 of the cell separating trench 64 is thereby formed. At this time, a position of the diode first principal surface 119 which is exposed from the mask 123 is lowered as a whole by the etching, resulting in formation of the step 121 between the IGBT first principal surface 120 and the diode first principal surface 119.

Thereafter, by executing the same steps as FIG. 10O to FIG. 10R, the semiconductor device 1 shown in FIG. 48 is manufactured.

As described above, since the recess 67 (cup portion 113) in the opening edge portion of the cell separating trench 64 is formed in Improved Structure 6-1 as well, an area of the anode region 62 which is exposed to a side wall of the recess 67 can be widely secured. Therefore, as compared with a case where a contact portion of the emitter terminal electrode 13 with the anode region 62 is restricted to the first principal surface 3 of the semiconductor layer 2, an area of the anode contact of the pn junction diode D can be widely secured. As a result, it is possible to relax the carrier storage effects at the time of recovery, and it is therefore possible to decrease a recovery loss.

### [Improved Structure 7 of Semiconductor Device 1]

### (1) Improved Structure 7-1

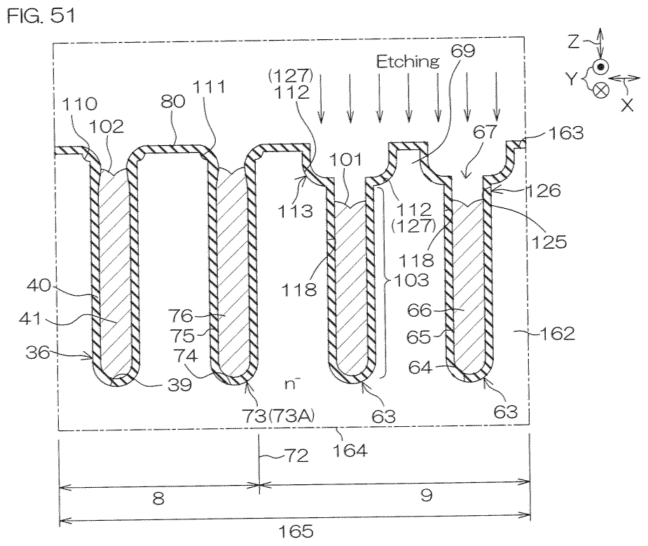

FIG. 50 is a schematic cross-sectional view which shows Improved Structure 7-1 of the semiconductor device 1. It is noted that a structure common to the aforementioned structure shall be given the same reference sign, and a description thereof shall be omitted. FIG. 50 is a cross-sectional view which corresponds to FIG. 45. In FIG. 50, for the sake of convenience, the same reference sign as the second principal surface 4 is given to a position at the second principal surface 4 side.

With reference to FIG. 50, in this preferred embodiment, the recess 67 includes a recess lower portion 126 which has a flat lower side wall 125 that continues from the lower end of the cup portion 113 toward the bottom wall of the cell separating trench 64. The side wall of the recess 67 thereby has a two stage structure which includes the flat lower side wall 125 of the recess lower portion 126 and an upper side wall 127 which is continuous to an upper end of the lower side wall 125 and includes a circular arc-shaped recessed edge portion 112 of the cup portion 113. An embedded portion 128 of the emitter terminal electrode 13 which is embedded in the recess 67 may thereby have a two stage structure which includes a first portion 129 that is embedded in the cup portion 113 and has a relatively broad width and a second portion 130 which is embedded in the recess lower portion 126 so as to project from the first portion 129 toward the second principal surface 4 and has a width narrower than that of the first portion 129.

The recess lower portion 126 has the width W2 which is the same as the width W2 of the trench backfilled portion 103. Also, the recess lower portion 126 has a depth D2 which is not more than ½ of the width W2 of the trench backfilled portion 103. For example, the width W2 of the trench backfilled portion 103 may be not less than 0.7 μm and not more than 1.3 μm, and the depth D2 of the recess lower portion 126 may be not less than 0.1 μm and not more than 0.6 μm.

FIG. 51 is a cross-sectional view of a region which corresponds to FIG. 50, and a cross-sectional view which shows a step in relation to formation of the structure of FIG. 50. As to the manufacture of the semiconductor device of 1 of FIG. 50, for example, the steps of FIG. 10A to FIG. 10E described above may be replaced with the steps of FIG. 47A to FIG. 47E, and also the step of FIG. 51 may be added after the step of FIG. 47E.

With reference to FIG. 51, after the base electrode layer 168 is etched so that the upper end portion 101 (upper surface) of the cell separating electrode layer 66 and the upper end portion 102 (upper surface) of the gate electrode layer 41 are equal in depth position (see FIG. 47E), the cell separating electrode layer 66 is selectively dug down in a state where the IGBT region 8 is selectively masked. In this step, a resist mask (not shown) having an opening which selectively exposes the diode region 9 is formed in the first wafer principal surface 163. Next, an upper portion of the cell separating electrode layer 66 is removed by an etching method via the resist mask. The etching method may be a dry etching method. Thereby, the recess 67 expands in volume in a depth direction toward the bottom wall of the cell separating trench 64, and a difference in height is developed between the upper end portion 101 (upper surface) of the cell separating electrode layer 66 and the upper end portion 102 (upper surface) of the gate electrode layer 41. As a result, the recess lower portion 126 is formed below the cup portion 113.

Thereafter, by executing the same steps as FIG. 10F to FIG. 10R, the semiconductor device 1 shown in FIG. 40 is manufactured.

As described above, since the recess 67 (cup portion 113 and recess lower portion 126) in the opening edge portion of the cell separating trench 64 is formed in Improved Structure 7-1 as well, an area of the anode region 62 which is exposed to a side wall of the recess 67 can be widely secured. Therefore, as compared with a case where a contact portion of the emitter terminal electrode 13 with the anode region 62 is restricted to the first principal surface 3 of the semiconductor layer 2, an area of the anode contact of the pn junction diode D can be widely secured. As a result, it is possible to relax the carrier storage effects at the time of recovery, and it is therefore possible to decrease a recovery loss.

### [Improved Structure 8 of Semiconductor Device 1]

### (1) Improved Structure 8-1

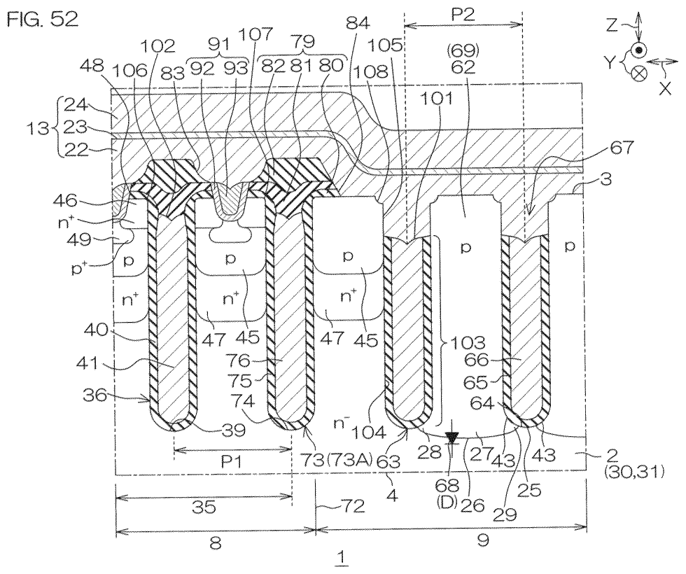

FIG. 52 is a schematic cross-sectional view which shows Improved Structure 8-1 of the semiconductor device 1. It is noted that a structure common to the aforementioned structure shall be given the same reference sign, and a description thereof shall be omitted.

With reference to FIG. 52, Improved Structure 8-1 is a structure in which the structure of the anode region 62 of FIG. 24 is applied as the anode region 62 of Improved Structure 4-1 described above.

### (2) Improved Structure 8-2

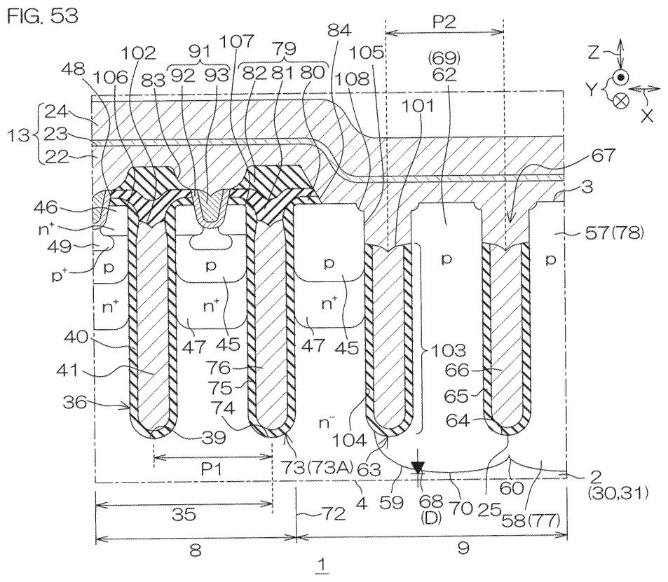

FIG. 53 is a schematic cross-sectional view which shows Improved Structure 8-2 of the semiconductor device 1. It is noted that a structure common to the aforementioned structure shall be given the same reference sign, and a description thereof shall be omitted.

With reference to FIG. 53, Improved Structure 8-2 is a structure in which the structure of the anode region 62 of FIG. 25 is applied as the anode region 62 of Improved Structure 4-1 described above.

### (3) Improved Structure 8-3

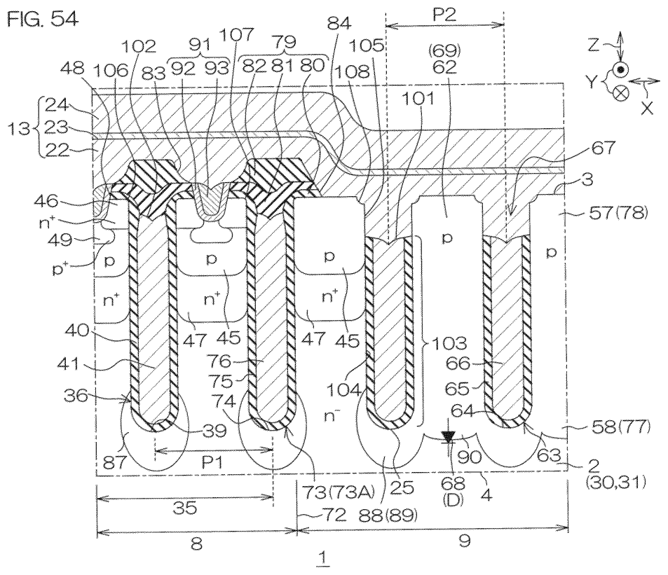

FIG. 54 is a schematic cross-sectional view which shows Improved Structure 8-3 of the semiconductor device 1. It is noted that a structure common to the aforementioned structure shall be given the same reference sign, and a description thereof shall be omitted.

With reference to FIG. 54, Improved Structure 8-3 is a structure in which the structure of the anode region 62 of FIG. 35 is applied as the anode region 62 of Improved Structure 4-1 described above.

### (4) Improved Structure 8-4

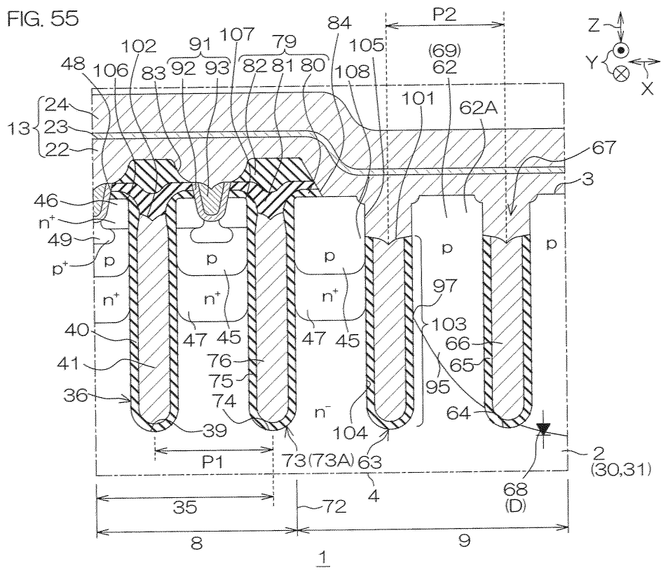

FIG. 55 is a schematic cross-sectional view which shows Improved Structure 8-4 of the semiconductor device 1. It is noted that a structure common to the aforementioned structure shall be given the same reference sign, and a description thereof shall be omitted.

With reference to FIG. 55, Improved Structure 8-4 is a structure in which the structure of the anode region 62 of FIG. 40 is applied as the anode region 62 of Improved Structure 4-1 described above.

As a modified example of Improved Structure 4-1 of the semiconductor device 1, four examples of Improved Structure 8-1 to Improved Structure 8-4 have been shown, however, many other examples can be shown as the modified example of Improved Structure 4-1 described above. For example, a relationship of the second pitch P2>the first pitch P1 may be set in Improved Structure 8-1 to Improved Structure 8-4. Also, the floating region 52 described above (for example, refer to FIG. 28, FIG. 29, FIG. 33, FIG. 34, FIG. 37, FIG. 39, FIG. 42, etc.) may be formed in the IGBT region 8 of each of Improved Structure 8-1 to Improved Structure 8-4.

### [Improved Structure 9 of Semiconductor Device 1]

### (1) Improved Structure 9-1

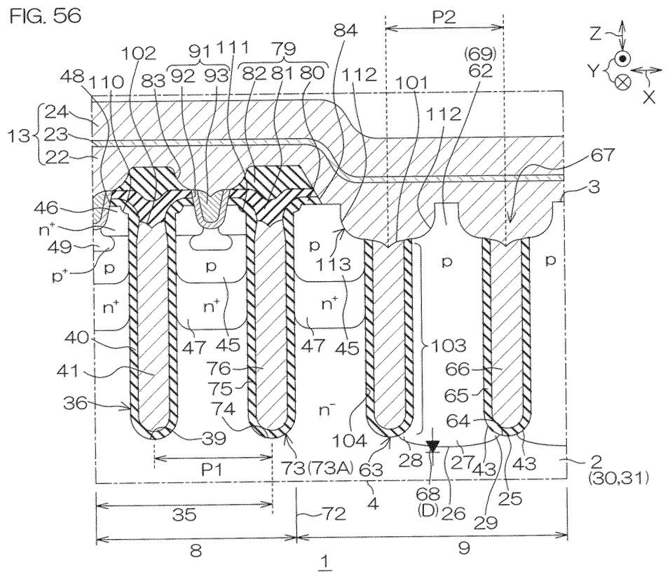

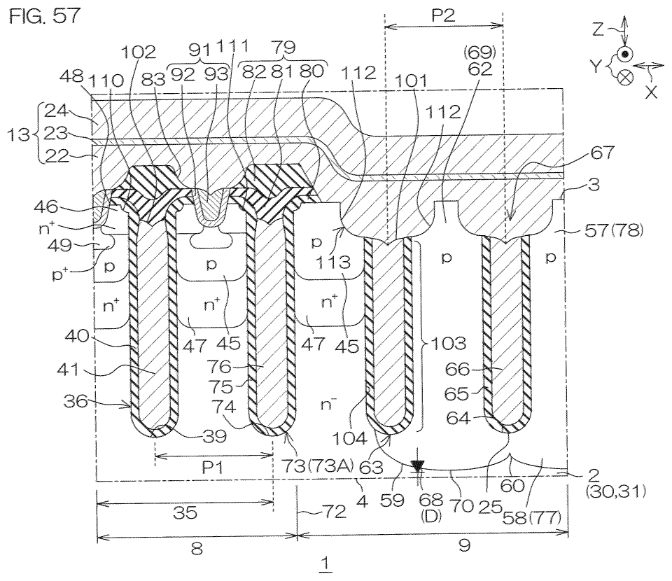

FIG. 56 is a schematic cross-sectional view which shows Improved Structure 9-1 of the semiconductor device 1. It is noted that a structure common to the aforementioned structure shall be given the same reference sign, and a description thereof shall be omitted.

With reference to FIG. 56, Improved Structure 9-1 is a structure in which the structure of the anode region 62 of FIG. 24 is applied as the anode region 62 of Improved Structure 5-1 described above.

### (2) Improved Structure 9-2

FIG. 57 is a schematic cross-sectional view which shows Improved Structure 9-2 of the semiconductor device 1. It is noted that a structure common to the aforementioned structure shall be given the same reference sign, and a description thereof shall be omitted.

With reference to FIG. 57, Improved Structure 9-2 is a structure in which the structure of the anode region 62 of FIG. 25 is applied as the anode region 62 of Improved Structure 5-1 described above.

### (3) Improved Structure 9-3

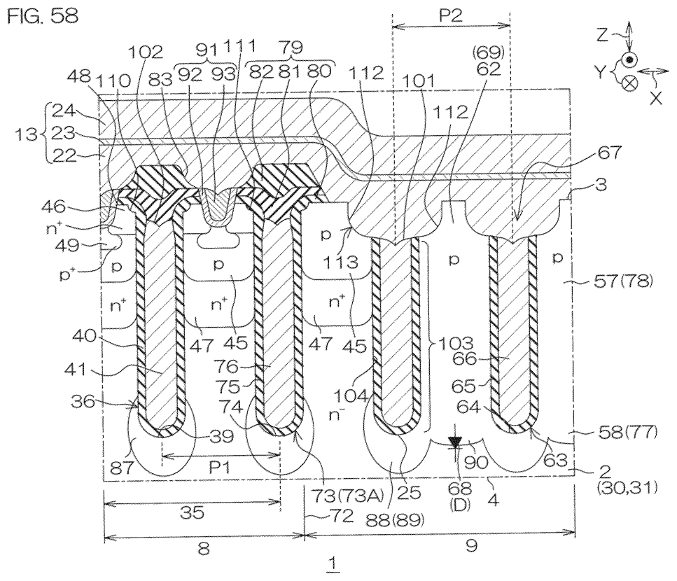

FIG. 58 is a schematic cross-sectional view which shows Improved Structure 9-3 of the semiconductor device 1. It is noted that a structure common to the aforementioned structure shall be given the same reference sign, and a description thereof shall be omitted.

With reference to FIG. 58, Improved Structure 9-3 is a structure in which the structure of the anode region 62 of FIG. 35 is applied as the anode region 62 of Improved Structure 5-1 described above.

### (4) Improved Structure 9-4

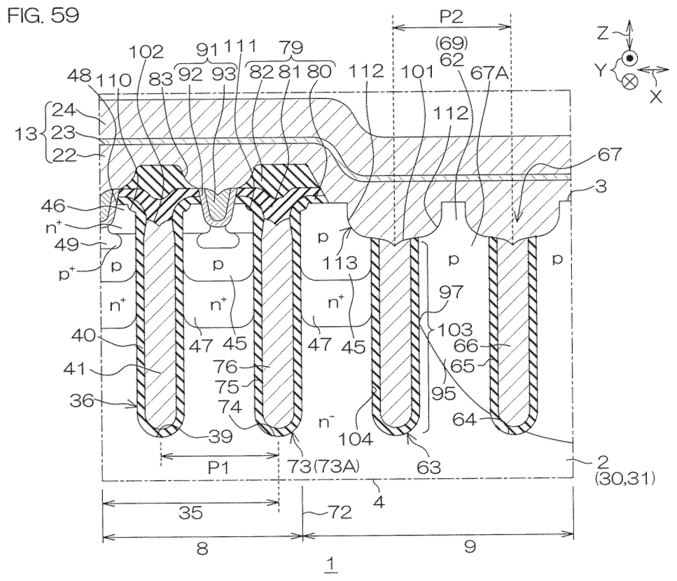

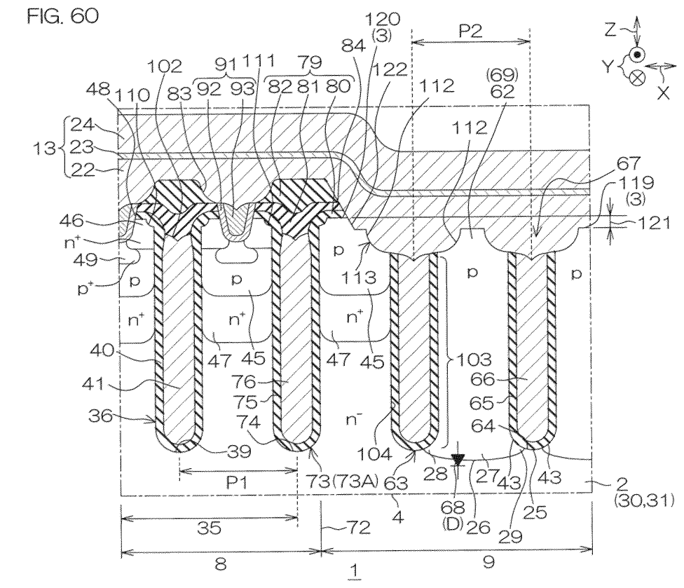

FIG. 59 is a schematic cross-sectional view which shows Improved Structure 9-4 of the semiconductor device 1. It is noted that a structure common to the aforementioned structure shall be given the same reference sign, and a description thereof shall be omitted.

With reference to FIG. 59, Improved Structure 9-4 is a structure in which the structure of the anode region 62 of FIG. 40 is applied as the anode region 62 of Improved Structure 5-1 described above.

As a modified example of Improved Structure 5-1 of the semiconductor device 1, four examples of Improved Structure 9-1 to Improved Structure 9-4 have been shown, however, many other examples can be shown as the modified example of Improved Structure 5-1 described above. For example, a relationship of the second pitch P2>the first pitch P1 may be set in Improved Structure 9-1 to Improved Structure 9-4. Also, the floating region 52 described above (for example, refer to FIG. 28, FIG. 29, FIG. 33, FIG. 34, FIG. 37, FIG. 39, FIG. 42, etc.) may be formed in the IGBT region 8 of each of Improved Structure 9-1 to Improved Structure 9-4.

### [Improved Structure 10 of Semiconductor Device 1]

### (1) Improved Structure 10-1

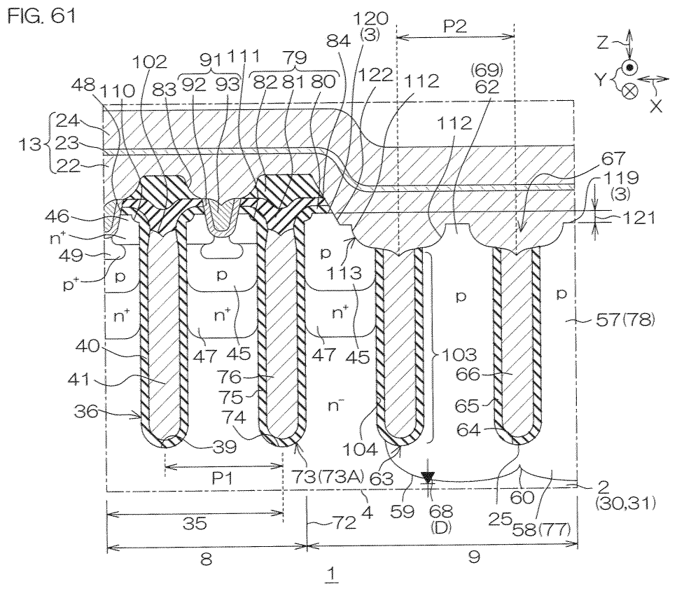

FIG. 60 is a schematic cross-sectional view which shows Improved Structure 10-1 of the semiconductor device 1. It is noted that a structure common to the aforementioned structure shall be given the same reference sign, and a description thereof shall be omitted.

With reference to FIG. 60, Improved Structure 10-1 is a structure in which the structure of the anode region 62 of FIG. 24 is applied as the anode region 62 of Improved Structure 6-1 described above.

### (2) Improved Structure 10-2

FIG. 61 is a schematic cross-sectional view which shows Improved Structure 10-2 of the semiconductor device 1. It is noted that a structure common to the aforementioned structure shall be given the same reference sign, and a description thereof shall be omitted.

With reference to FIG. 61, Improved Structure 10-2 is a structure in which the structure of the anode region 62 of FIG. 25 is applied as the anode region 62 of Improved Structure 6-1 described above.

### (3) Improved Structure 10-3

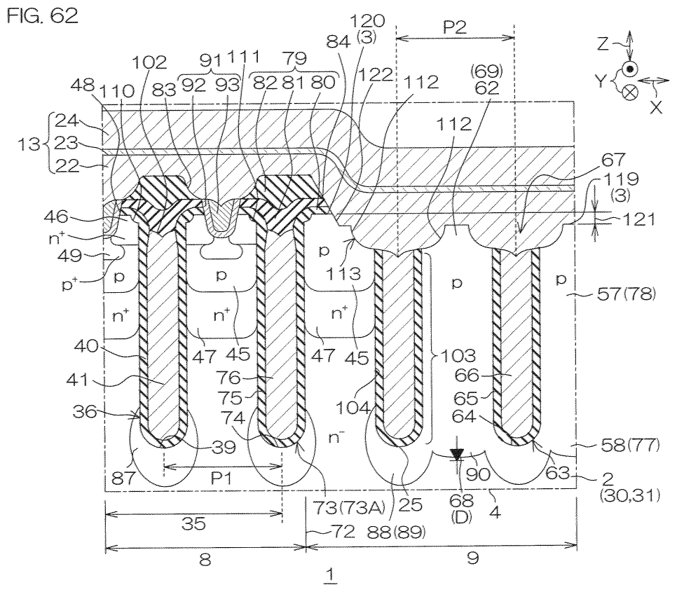

FIG. 62 is a schematic cross-sectional view which shows Improved Structure 10-3 of the semiconductor device 1. It is noted that a structure common to the aforementioned structure shall be given the same reference sign, and a description thereof shall be omitted.

With reference to FIG. 62, Improved Structure 10-3 is a structure in which the structure of the anode region 62 of FIG. 35 is applied as the anode region 62 of Improved Structure 6-1 described above.

### (4) Improved Structure 10-4

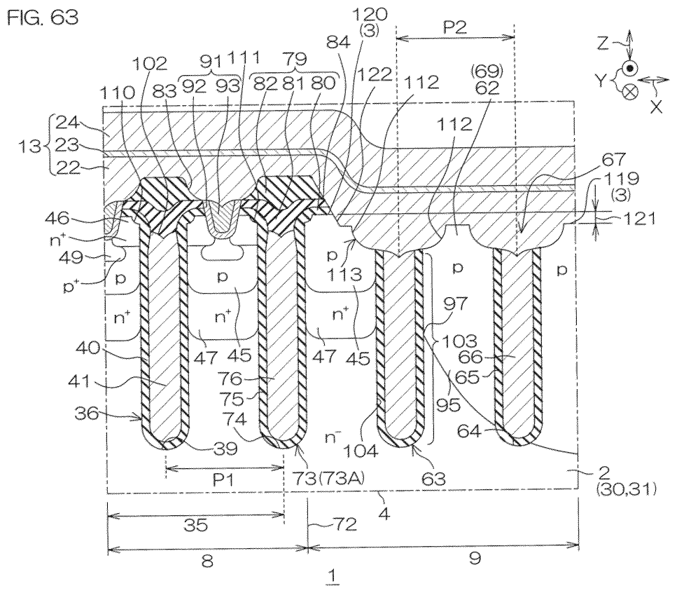

FIG. 63 is a schematic cross-sectional view which shows Improved Structure 10-4 of the semiconductor device 1. It is noted that a structure common to the aforementioned structure shall be given the same reference sign, and a description thereof shall be omitted.

With reference to FIG. 63, Improved Structure 10-4 is a structure in which the structure of the anode region 62 of FIG. 40 is applied as the anode region 62 of Improved Structure 6-1 described above.

As a modified example of Improved Structure 6-1 of the semiconductor device 1, four examples of Improved Structure 10-1 to Improved Structure 10-4 have been shown, however, many other examples can be shown as the modified example of Improved Structure 6-1 described above. For example, a relationship of the second pitch P2>the first pitch P1 may be set in Improved Structure 10-1 to Improved Structure 10-4. Also, the floating region 52 described above (for example, refer to FIG. 28, FIG. 29, FIG. 33, FIG. 34, FIG. 37, FIG. 39, FIG. 42, etc.) may be formed in the IGBT region 8 of each of Improved Structure 10-1 to Improved Structure 10-4.

### [Improved Structure 11 of Semiconductor Device 1]

### (1) Improved Structure 11-1

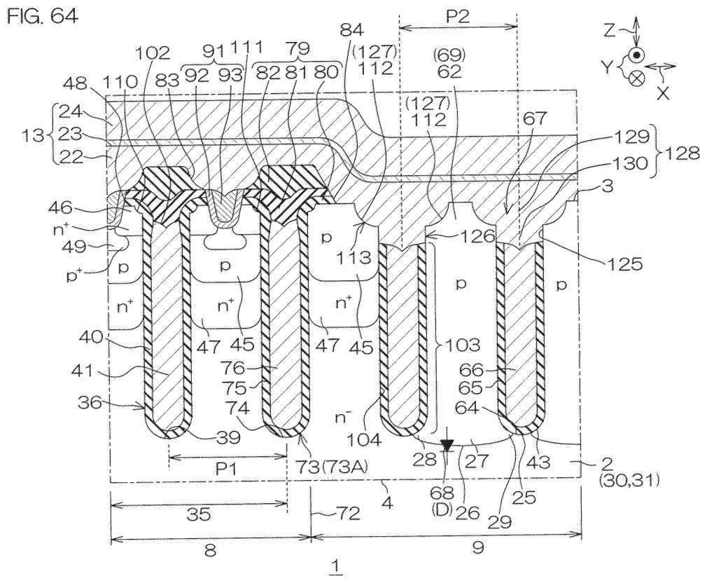

FIG. 64 is a schematic cross-sectional view which shows Improved Structure 11-1 of the semiconductor device 1. It is noted that a structure common to the aforementioned structure shall be given the same reference sign, and a description thereof shall be omitted.

With reference to FIG. 64, Improved Structure 11-1 is a structure in which the structure of the anode region 62 of FIG. 24 is applied as the anode region 62 of Improved Structure 7-1 described above.

### (2) Improved Structure 11-2

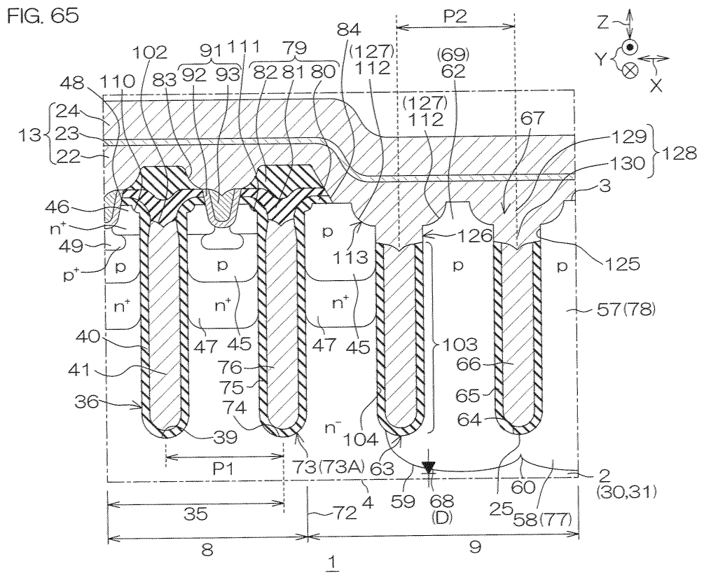

FIG. 65 is a schematic cross-sectional view which shows Improved Structure 11-2 of the semiconductor device 1. It is noted that a structure common to the aforementioned structure shall be given the same reference sign, and a description thereof shall be omitted.

With reference to FIG. 65, Improved Structure 11-2 is a structure in which the structure of the anode region 62 of FIG. 25 is applied as the anode region 62 of Improved Structure 7-1 described above.

### (3) Improved Structure 11-3

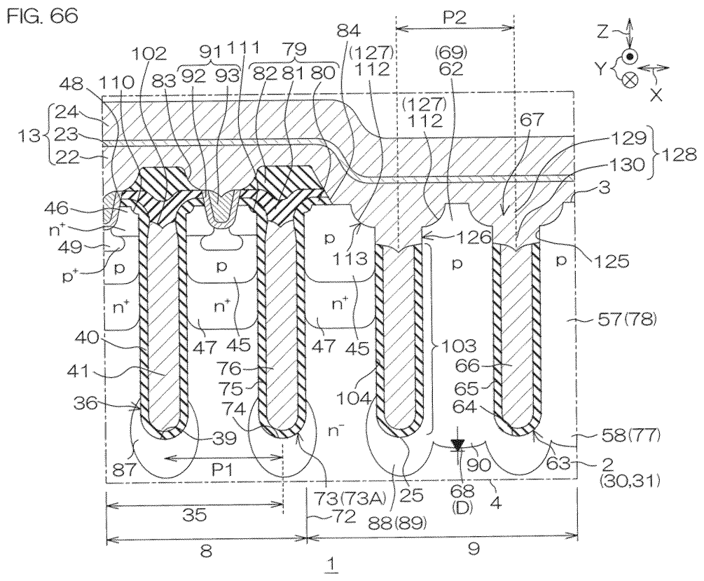

FIG. 66 is a schematic cross-sectional view which shows Improved Structure 11-3 of the semiconductor device 1. It is noted that a structure common to the aforementioned structure shall be given the same reference sign, and a description thereof shall be omitted.

With reference to FIG. 66, Improved Structure 11-3 is a structure in which the structure of the anode region 62 of FIG. 35 is applied as the anode region 62 of Improved Structure 7-1 described above.

### (4) Improved Structure 11-4

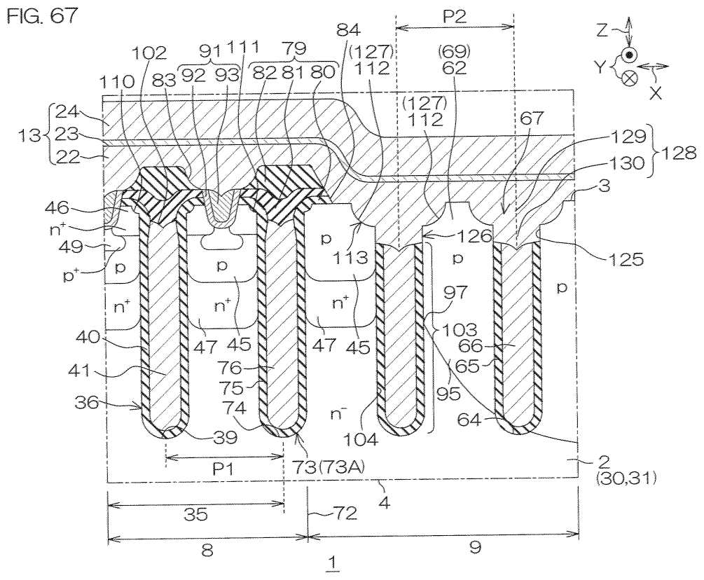

FIG. 67 is a schematic cross-sectional view which shows Improved Structure 11-4 of the semiconductor device 1. It is noted that a structure common to the aforementioned structure shall be given the same reference sign, and a description thereof shall be omitted.

With reference to FIG. 67, Improved Structure 11-4 is a structure in which the structure of the anode region 62 of FIG. 40 is applied as the anode region 62 of Improved Structure 7-1 described above.

As a modified example of Improved Structure 7-1 of the semiconductor device 1, four examples of Improved Structure 11-1 to Improved Structure 11-4 have been shown, however, many other examples can be shown as the modified example of Improved Structure 7-1 described above. For example, a relationship of the second pitch P2>the first pitch P1 may be set in Improved Structure 11-1 to Improved Structure 11-4. Also, the floating region 52 described above (for example, refer to FIG. 28, FIG. 29, FIG. 33, FIG. 34, FIG. 37, FIG. 39, FIG. 42, etc.) may be formed in the IGBT region 8 of each of Improved Structure 11-1 to Improved Structure 11-4.

[Semiconductor Module 201 which has Semiconductor Device 1]

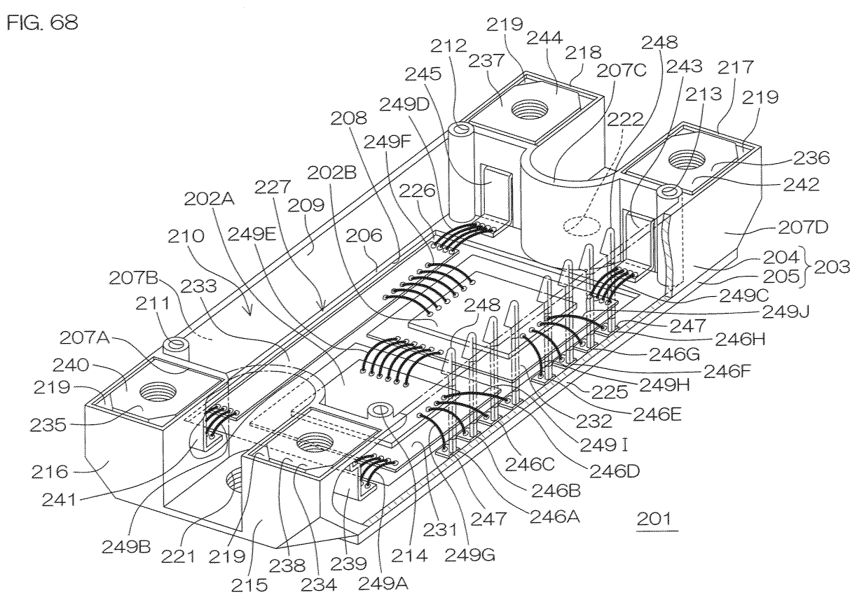

FIG. 68 is a perspective view which shows a configuration example of a semiconductor module 201. One or two or more semiconductor chips 202 are incorporated into the semiconductor module 201.

In this preferred embodiment, the semiconductor module 201 has a structure into which the two semiconductor chips 202 are incorporated. In the following, for the sake of convenience, the two semiconductor chips 202 are respectively referred to as a first semiconductor chip 202A and a second semiconductor chip 202B.

The semiconductor device 1 according to the first preferred embodiment or a semiconductor device 181 according to the second preferred embodiment is applied to the first semiconductor chip 202A. The semiconductor device 1 according to the first preferred embodiment or the semiconductor device 181 according to the second preferred embodiment is applied to the second semiconductor chip 202B.

With reference to FIG. 68, the semiconductor module 201 includes a housing 203 which houses the first semiconductor chip 202A and the second semiconductor chip 202B. The housing 203 includes a resin case 204 and a supporting substrate 205. The supporting substrate 205 is a substrate which supports the first semiconductor chip 202A and the second semiconductor chip 202B.

The resin case 204 includes a bottom wall 206 and side walls 207A, 207B, 207C, 207D. The bottom wall 206 is formed in a quadrilateral shape (rectangular shape in this preferred embodiment) in a plan view as viewed from the normal direction Z thereof.

A through hole 208 is formed in the bottom wall 206. The through hole 208 is formed in a region of the bottom wall 206 at an interval from a peripheral edge thereof to an inner region thereof. In this preferred embodiment, the through hole 208 is formed in a quadrilateral shape (rectangular shape in this preferred embodiment) in a plan view.

The side walls 207A to 207D are erected from the peripheral edge of the bottom wall 206 to the opposite side to the bottom wall 206. The side walls 207A to 207D demarcate an opening 209 at the opposite side to the bottom wall 206. The side walls 207A to 207D demarcate an inner space 210 with the bottom wall 206.

The side wall 207A and the side wall 207C extend along a short direction of the bottom wall 206. The side wall 207A and the side wall 207C oppose each other in a long direction of the bottom wall 206. The side wall 207B and the side wall 207D extend along the long direction of the bottom wall 206. The side wall 207B and the side wall 207D oppose each other in the short direction of the bottom wall 206.

Bolt insertion holes 211, 212, 213, 214 are respectively formed at four corners of the inner space 210. The inner space 210 is closed by a lid member which is not shown. The lid member is fixed to the bolt insertion holes 211, 212, 213, 214 by using bolts.

The resin case 204 includes a plurality of terminal supporting portions 215, 216, 217, 218. In this preferred embodiment, the plurality of terminal supporting portions 215 to 218 include a first terminal supporting portion 215, a second terminal supporting portion 216, a third terminal supporting portion 217 and a fourth terminal supporting portion 218.

The first terminal supporting portion 215 and the second terminal supporting portion 216 are mounted on an outer wall of the side wall 207A. In this preferred embodiment, the first terminal supporting portion 215 and the second terminal supporting portion 216 are formed integral with the outer wall of the side wall 207A.

The first terminal supporting portion 215 and the second terminal supporting portion 216 are formed at an interval from each other in the short direction. The first terminal supporting portion 215 and the second terminal supporting portion 216 are each formed in a block shape. The first terminal supporting portion 215 and the second terminal supporting portion 216 each project outwardly from the outer wall of the side wall 207A toward the long direction.

The third terminal supporting portion 217 and the fourth terminal supporting portion 218 are mounted on the side wall 207C. In this preferred embodiment, the third terminal supporting portion 217 and the fourth terminal supporting portion 218 are formed integral with an outer wall of the side wall 207C.

The third terminal supporting portion 217 and the fourth terminal supporting portion 218 are formed at an interval from each other in the short direction. The third terminal supporting portion 217 and the fourth terminal supporting portion 218 are each formed in a block shape. The third terminal supporting portion 217 and the fourth terminal supporting portion 218 each project outwardly from the side wall 207C toward the long direction.

The first terminal supporting portion 215, the second terminal supporting portion 216, the third terminal supporting portion 217 and the fourth terminal supporting portion 218 each have a supporting wall 219. Each supporting wall 219 is positioned in a region further at the opening 209 side than the bottom wall 206. Each supporting wall 219 is formed in a quadrilateral shape in a plan view.

A first bolt insertion hole 221 is formed in a region between the first terminal supporting portion 215 and the second terminal supporting portion 216. A second bolt insertion hole 222 is formed in a region between the third terminal supporting portion 217 and the fourth terminal supporting portion 218.

The supporting substrate 205 includes a heat dissipation plate 225, an insulating material 226 and a circuit portion 227. The supporting substrate 205 is mounted on an outer surface of the resin case 204 so that the circuit portion 227 is exposed from the through hole 208 of the bottom wall 206. The supporting substrate 205 may be mounted on the outer surface of the resin case 204 by the heat dissipation plate 225 being adhered to the outer surface of the resin case 204.

The heat dissipation plate 225 may be a metal plate. The heat dissipation plate 225 may be an insulating plate which is coated by a metal film. The heat dissipation plate 225 is formed in a quadrilateral shape (rectangular shape in this preferred embodiment) in a plan view as viewed in the normal direction thereof.

The insulating material 226 is formed on the heat dissipation plate 225. The insulating material 226 may be a mounting substrate which contains an insulating material. The insulating material 226 may be an insulating film formed on the heat dissipation plate 225 as a film.

The circuit portion 227 is formed on the heat dissipation plate 225 via the insulating material 226. The circuit portion 227 includes a plurality of wirings 231, 232, 233, the first semiconductor chip 202A and the second semiconductor chip 202B. In this preferred embodiment, the wirings 231 to 233 include a first collector wiring 231, a second collector wiring 232 and an emitter wiring 233.

The first collector wiring 231 is formed as a plate or as a film. The first collector wiring 231 is formed in a quadrilateral shape in a plan view. The first collector wiring 231 is disposed in a region at one side (side wall 207A side) in the long direction and in a region thereof at one side (side wall 207D side) in the short direction of the heat dissipation plate 225.

The second collector wiring 232 is formed as a plate or as a film. The second collector wiring 232 is formed in a quadrilateral shape in a plan view. The second collector wiring 232 is disposed at an interval from the first collector wiring 231 in a region at the other side (side wall 207C side) in the long direction and in a region thereof at one side (side wall 207D side) in the short direction of the heat dissipation plate 225.

The emitter wiring 233 is formed as a plate or as a film. The emitter wiring 233 is formed in a quadrilateral shape in a plan view. In this preferred embodiment, the emitter wiring 233 is formed in a rectangular shape extending along the long direction of the heat dissipation plate 225.

The emitter wiring 233 is disposed at an interval from the first collector wiring 231 and the second collector wiring 232 in a region at the other side (side wall 207B side) in the short direction of the heat dissipation plate 225.

The first semiconductor chip 202A is disposed on the first collector wiring 231 in an orientation in which the collector terminal electrode 32 opposes the heat dissipation plate. The collector terminal electrode 32 of the first semiconductor chip 202A is bonded to the first collector wiring 231 via a conductive bonding material.

The collector terminal electrode 32 of the first semiconductor chip 202A is thereby electrically connected to the first collector wiring 231. The conductive bonding material may contain a solder or a conductive paste.

The second semiconductor chip 202B is disposed on the second collector wiring 232 in an orientation in which the collector terminal electrode 32 opposes the heat dissipation plate. The collector terminal electrode 32 of the second semiconductor chip 202B is bonded to the second collector wiring 232 via a conductive bonding material.

The collector terminal electrode 32 of the second semiconductor chip 202B is thereby electrically connected to the second collector wiring 232. The conductive bonding material may contain a solder or a conductive paste.

The semiconductor module 201 includes a plurality of terminals 234, 235, 236, 237. The plurality of terminals 234 to 237 includes a collector terminal 234, a first emitter terminal 235, a common terminal 236 and a second emitter terminal 237.

The collector terminal 234 is disposed on the first terminal supporting portion 215. The collector terminal 234 is electrically connected to the first collector wiring 231. The collector terminal 234 includes a first region 238 and a second region 239. The first region 238 of the collector terminal 234 is positioned outside the inner space 210. The second region 239 is positioned inside the inner space 210 of the collector terminal 234.

The first region 238 of the collector terminal 234 is supported by the supporting wall 219 of the first terminal supporting portion 215. The second region 239 of the collector terminal 234 penetrates through the side wall 207A from the first region 238 and is led out to the inside of the inner space 210. The second region 239 of the collector terminal 234 is electrically connected to the first collector wiring 231.

The first emitter terminal 235 is disposed on the second terminal supporting portion 216. The first emitter terminal 235 is electrically connected to the emitter wiring 233. The first emitter terminal 235 includes a first region 240 and a second region 241. The first region 240 of the first emitter terminal 235 is positioned outside the inner space 210. The second region 241 of the first emitter terminal 235 is positioned inside the inner space 210.

The first region 240 of the first emitter terminal 235 is supported by the supporting wall 219 of the second terminal supporting portion 216. The second region 241 of the first emitter terminal 235 penetrates through the side wall 207A from the first region 240 and is led out to the inside of the inner space 210. The second region 241 of the first emitter terminal 235 is electrically connected to the emitter wiring 233.

The common terminal 236 is disposed on the third terminal supporting portion 217. The common terminal 236 is electrically connected to the second collector wiring 232. The common terminal 236 includes a first region 242 and a second region 243. The first region 242 of the common terminal 236 is positioned outside the inner space 210. The second region 243 of the common terminal 236 is positioned inside the inner space 210.

The first region 242 of the common terminal 236 is supported by the supporting wall 219 of the second terminal supporting portion 216. The second region 243 of the common terminal 236 penetrates through the side wall 207C from the first region 240 and is led out to the inside of the inner space 210. The second region 243 of the common terminal 236 is electrically connected to the second collector wiring 232.

The second emitter terminal 237 is disposed on the fourth terminal supporting portion 218. The second emitter terminal 237 is electrically connected to the emitter wiring 233. The second emitter terminal 237 includes a first region 244 and a second region 245. The first region 244 of the second emitter terminal 237 is positioned outside the inner space 210. The second region 245 of the second emitter terminal 237 is positioned inside the inner space 210.

The first region 244 of the second emitter terminal 237 is supported by the supporting wall 219 of the fourth terminal supporting portion 218. The second region 245 of the second emitter terminal 237 penetrates through the side wall 207C from the first region 244 and is led out to the inside of the inner space 210. The second region 245 of the second emitter terminal 237 is electrically connected to the emitter wiring 233.

The semiconductor module 201 includes a plurality (six in this preferred embodiment) of side wall terminals 246A to 246H. The plurality of side wall terminals 246A to 246H are disposed at an interval along the side wall 207D in the inner space 210.

The plurality of side wall terminals 246A to 246H each include an inner connection portion 247 and an outer connection portion 248. The inner connection portion 247 is disposed on the bottom wall 206. The outer connection portion 248 extends as a line along the side wall 207D from the inner connection portion 247 and is led out to the outside of the inner space 210.

The plurality of side wall terminals 246A to 246H include four side wall terminals 246A to 246D for the first semiconductor chip 202A and four side wall terminals 246E to 246H for the second semiconductor chip 202B.

The side wall terminals 246A to 246D oppose the first collector wiring 231 along the short direction. The side wall terminal 246A is formed as a gate terminal which is connected to the gate terminal electrode 14 of the first semiconductor chip 202A.

The side wall terminals 246B to 246D are formed respectively as terminals connected to the first sense terminal electrode 15, the second sense terminal electrode 16 and the current detection terminal electrode 17 of the first semiconductor chip 202A. At least one of the side wall terminals 246B to 246D may be an open terminal.

The side wall terminals 246E to 246H oppose the second collector wiring 232 along the short direction. The side wall terminal 246E is formed as a gate terminal which is connected to the gate terminal electrode 14 of the second semiconductor chip 202B.

The side wall terminals 246F to 246H are formed respectively as terminals connected to the first sense terminal electrode 15, the second sense terminal electrode 16 and the current detection terminal electrode 17 of the second semiconductor chip 202B. At least one of the side wall terminals 246F to 246H may be an open terminal.

The semiconductor module 201 includes a plurality of lead wires 249A to 249J. The plurality of lead wires 249A to 249J may each contain at least one type of material among gold, silver, copper and aluminum. The lead wires 249A to 249J may each include a bonding wire. The lead wires 249A to 249J may each contain a conductive plate.

The plurality of lead wires 249A to 249J include a first lead wire 249A, a second lead wire 249B, a third lead wire 249C, a fourth lead wire 249D, a fifth lead wire 249E, a sixth lead wire 249F, a seventh lead wire 249G, an eighth lead wire 249H, a ninth lead wire 249I and a tenth lead wire 249J.

The first lead wire 249A connects the collector terminal 234 and the first collector wiring 231. The second lead wire 249B connects the first emitter terminal 235 and the emitter wiring 233. The third lead wire 249C connects the common terminal 236 and the second collector wiring 232.

The fourth lead wire 249D connects the second emitter terminal 237 and the emitter wiring 233. The fifth lead wire 249E connects the emitter terminal electrode 13 and the second collector wiring 232 of the first semiconductor chip 202A. The sixth lead wire 249F connects the emitter terminal electrode 13 and the emitter wiring 233 of the second semiconductor chip 202B.

The seventh lead wire 249G connects the gate terminal electrode 14 and the side wall terminal 246A of the first semiconductor chip 202A. The eighth lead wire 249H connects the gate terminal electrode 14 and the side wall terminal 246E of the second semiconductor chip 202B.

The ninth lead wire 249I connects the first sense terminal electrode 15, the second sense terminal electrode 16 and the current detection terminal electrode 17 of the first semiconductor chip 202A with the side wall terminals 246B to 246D.

The tenth lead wire 249J connects the first sense terminal electrode 15, the second sense terminal electrode 16 and the current detection terminal electrode 17 of the second semiconductor chip 202B with the side wall terminals 246F to 246H.

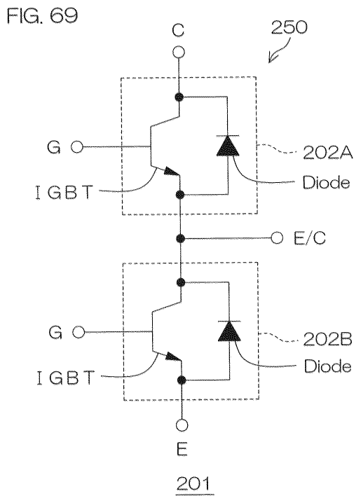

FIG. 69 is a circuit diagram which shows an electrical configuration of the semiconductor module 201 shown in FIG. 68.

With reference to FIG. 69, the semiconductor module 201 includes a half-bridge circuit 250. The half-bridge circuit 250 includes the first semiconductor chip 202A and the second semiconductor chip 202B.

The first semiconductor chip 202A constitutes a high voltage-side arm of the half-bridge circuit 250. The second semiconductor chip 202B constitutes a low voltage-side arm of the half-bridge circuit 250.

The gate terminal (side wall terminal 246A) is connected to the gate terminal electrode 14 of the first semiconductor chip 202A. The collector terminal 234 is connected to the collector terminal electrode 32 of the first semiconductor chip 202A.

The collector terminal electrode 32 of the second semiconductor chip 202B is connected to the emitter terminal electrode 13 of the first semiconductor chip 202A. The common terminal 236 is connected to a connection portion of the emitter terminal electrode 13 of the first semiconductor chip 202A and the collector terminal electrode 32 of the second semiconductor chip 202B.

The gate terminal (side wall terminal 246D) is connected to the gate terminal electrode 14 of the second semiconductor chip 202B. The first emitter terminal 235 (second emitter terminal 237) is connected to the emitter terminal electrode 13 of the second semiconductor chip 202B.

A gate driver IC, etc., may be connected to the gate terminal electrode 14 of the first semiconductor chip 202A via the gate terminal (side wall terminal 246A). A gate driver IC, etc., may be connected to the gate terminal electrode 14 of the second semiconductor chip 202B via the gate terminal (side wall terminal 246D).

The semiconductor module 201 may be an inverter module which drives any one phase among a U-phase, a V-phase and a W-phase in a three phase motor having the U-phase, the V-phase and the W-phase. An inverter device which drives the three phase motor may be arranged by three semiconductor modules 201 corresponding to the U-phase, the V-phase and the W-phase of the three phase motor.

In this case, a DC power supply is connected to the collector terminal 234 and the first emitter terminal 235 (second emitter terminal 237) of each semiconductor module 201. Also, any one phase among the U-phase, the V-phase and the W-phase of the three phase motor is connected as a load to the common terminal 236 of each semiconductor module 201.

With the inverter device, the first semiconductor chip 202A and the second semiconductor chip 202B are driven and controlled according to a predetermined switching pattern. A DC voltage is thereby converted to a three phase AC voltage and the three phase motor is sinusoidally driven.

The preferred embodiments of the present disclosure may be implemented in yet other modes.

With each of the preferred embodiments described above, the semiconductor layer 2 may have a laminated structure which includes a p type semiconductor substrate in place of the n⁻ type semiconductor substrate 31 and an n⁻ type epitaxial layer formed on the semiconductor substrate. In this case, the p type semiconductor substrate corresponds to the collector region 34. Also, the n⁻ type epitaxial layer corresponds to the drift region 30.

The p type semiconductor substrate may be made of silicon. The n⁻ type epitaxial layer may be made of silicon. The n⁻ type epitaxial layer is formed by epitaxially growing silicon from a principal surface of the p type semiconductor substrate.

With each of the preferred embodiments described above, a structure in which the conductivity types of the respective semiconductor portions are inverted may be adopted. That is, a p type portion may be formed to be of an n type and an n type portion may be formed to be of a p type.

The features indicated below can be extracted from this description and the drawings.

### Appendix 1-1

A semiconductor device (1) comprising;
a semiconductor layer (2) which has a first principal surface (3) and a second principal surface (4) at the opposite side thereof;
an IGBT region (8) which is formed in the semiconductor layer (2);
a diode region (9) which is formed in the semiconductor layer (2) and adjacent to the IGBT region (8);
a first impurity region (30, 31) of a first conductivity type which is formed inside the semiconductor layer (2);
a plurality of first trenches (64) which are formed in the first principal surface (3) of the diode region (9);
a diode cell region (69) which is demarcated by being sandwiched between the mutually adjacent first trenches (64);
a second impurity region (62) of a second conductivity type which is formed at a surface layer portion of the first principal surface (3) in the diode region (9), wherein the second impurity region (62) extends in the diode cell region (69) deeper than a bottom wall of the first trench (64) from the first principal surface (3) along a side wall of the first trench (64) and also forms, with the first impurity region, (30, 31) a pn junction portion (68) that covers at least a part of the bottom walls of the mutually adjacent first trenches (64);
a first electrode (32) which is electrically connected to the first impurity region (30, 31);
and a second electrode (13) which is electrically connected to the second impurity region (62).

With the semiconductor device according to the preferred embodiment of the present disclosure, a diode is formed in the diode region by the pn junction portion between the first impurity region and the second impurity region. The second impurity region is formed deeper than the bottom wall of the first trench, by which the pn junction portion covers at least a part of the bottom walls of the mutually adjacent first trenches. As compared with a case where the pn junction portion connects side walls of the mutually adjacent first trenches, it is thereby possible to widely secure an area of the pn junction portion. As a result, carriers are recovered from the second impurity region having a wide area at the time of recovery, it is thus made possible to promote the recovery of the carriers and also to decrease a recovery loss. As a result, it is possible to recover carriers from the second impurity region having a wide area at the time of recovery, and it is therefore possible to promote the recovery of the carriers and decrease a recovery loss.

### Appendix 1-2

The semiconductor device (1) according to Appendix 1-1, wherein the plurality of diode cell regions (69) are adjacent to each other with the first trench (64) therebetween, and
the second impurity region (62) includes a first portion (57) which is formed in each of the diode cell regions (69) and a second portion (58) which extends so as to cross the plurality of first trenches (64) along the first principal surface (3), integrally covers the bottom walls of the plurality of first trenches (64) from the second principal surface (4) side, couples the first portions (57) of the plurality of diode cell regions (69) and forms the pn junction portion (68) with the first impurity region (30, 31).

### Appendix 1-2-2

The semiconductor device (1) according to Appendix 1-2, wherein the first portion (57) of the second impurity region (62) is formed across an entire area from the first principal surface (3) of the diode cell region (69) between the mutually adjacent first trenches (64) up to the bottom wall of the first trench (64).

### Appendix 1-2-3

The semiconductor device (1) according to Appendix 1-1, wherein the plurality of diode cell regions (69) are adjacent to each other with the first trench (64) therebetween, and
the second impurity region (62) integrally includes a base portion (77) which is formed across the plurality of first trenches (64) below the bottom walls of the plurality of first trenches (64) and form the pn junction portion (68) with the first impurity region (30, 31) and a branch portion (78) which is formed from the base portion (77) toward the first principal surface (3) at a position of each diode cell region (69).

### Appendix 1-2-4

The semiconductor device (1) according to Appendix 1-1, wherein the plurality of diode cell regions (69) are adjacent to each other with the first trench (64) therebetween, and
the second impurity region (62) collectively covers the bottom walls of the plurality of first trenches (64) and is formed across the plurality of diode cell regions (69).

### Appendix 1-2-5

The semiconductor device (1) according to Appendix 1-1, including a first embedded conductive layer (66) which is embedded in the first trench (64) via a first insulating layer (65).

### Appendix 1-3

The semiconductor device (1) according to Appendix 1-2, wherein the pn junction portion (68) has a sectional shape which alternately rises and falls at the first principal surface (3) side and at the second principal surface (4) side along the first principal surface (3) of the semiconductor layer (2).

### Appendix 1-3-2

The semiconductor device (1) according to Appendix 1-2, wherein the pn junction portion (68) has a corrugated shape with ups and downs alternately in a thickness direction of the semiconductor layer (2).

### Appendix 1-4

The semiconductor device (1) according to Appendix 1-3, wherein the pn junction portion (68) is raised toward the second principal surface (4) side directly below the diode cell region (69) and raised toward the first principal surface (3) side directly below the first trench (64).

### Appendix 1-4-2

The semiconductor device (1) according to Appendix 1-3-2, wherein the pn junction portion (68) includes a first bulging portion (59) which overlaps with the diode cell region (69) in a thickness direction of the semiconductor layer (2) and bulges toward the second principal surface (4) and a second bulging portion (60) which overlaps with the first trench (64) and protrudes toward the first principal surface (3).

### Appendix 1-5

The semiconductor device (1) according to Appendix 1-1, wherein the plurality of diode cell regions (69) are adjacent to each other with the first trench (64) therebetween, and
the second impurity region (62) is formed physically independent in each of the diode cell regions (69) and forms the pn junction portion (68) with the first impurity region (30, 31) on a lateral side of the bottom wall of the first trench (64).

### Appendix 1-5-2

The semiconductor device (1) according to Appendix 1-5, wherein the bottom wall of the first trench (64) is formed in a curved shape which bulges toward the second principal surface (4) side, and
the second impurity region (62) has a bottom portion (27) which is formed in a curved shape having an apex portion (26) which is positioned further at the second principal surface (4) side than a curved apex portion (25) of the bottom wall of the curved-shaped first trench (64).

### Appendix 1-5-3

The semiconductor device (1) according to Appendix 1-5-2, wherein the bottom wall of the curved-shaped first trench (64) is such that a part thereof (43) is covered by the bottom portion (27) of the second impurity region (62), and the curved apex portion (25) is in contact with the first impurity region (30, 31).

### Appendix 1-6

The semiconductor device (1) according to Appendix 1-5, wherein the pn junction portion (68) has a first end portion (28) in a bottom wall of one of the mutually adjacent first trenches (64) and has a second end portion (29) in a bottom wall of the other of the mutually adjacent first trenches (64).

### Appendix 1-7

The semiconductor device (1) according to Appendix 1-6, wherein the pn junction portion (68) is formed, with the first end portion (28) and the second end portion (29) given as both end portions, in a curved shape which is raised toward the second principal surface (4) side with respect to the both end portions (28, 29).

### Appendix 1-8

The semiconductor device (1) according to any one of Appendix 1-1 to Appendix 1-7, including a plurality of second trenches (39, 54, 74) which are formed in the first principal surface (3) of the IGBT region (8) and arrayed at a first pitch (P1), wherein
the plurality of first trenches (64) are arrayed at a second pitch (P2) which is the same as the first pitch (P1).

### Appendix 1-8-2

The semiconductor device (1) according to Appendix 1-8, wherein the first pitch (P1) and the second pitch (P2) are not less than 1.0 μm and not more than 3.5 μm.

### Appendix 1-9

The semiconductor device (1) according to any one of Appendix 1-1 to Appendix 1-7, including a plurality of second trenches (39, 54, 74) which are formed in the first principal surface (3) of the IGBT region (8) and arrayed at a first pitch (P1), wherein
the plurality of first trenches (64) are arrayed at a second pitch (P2) which is larger than the first pitch (P1).

### Appendix 1-9-2

The semiconductor device (1) according to Appendix 1-8, wherein the second pitch (P2) is not less than 1.0 times and not more than 3.0 times larger than the first pitch (P1).

### Appendix 1-9-3

The semiconductor device (1) according to Appendix 1-9-2, wherein the first pitch (P1) is not less than 1.0 μm and not more than 3.5 μm, and
the second pitch (P2) is not less than 1.0 μm and not more than 10.0 μm.

### Appendix 1-10

The semiconductor device (1) according to Appendix 1-2, including a second trench (39, 54, 74) which is formed in the first principal surface (3) of the IGBT region (8) and
a third impurity region (87) of a second conductivity type which is selectively formed in a bottom wall of the second trench (39, 54, 74), wherein
the second portion (58) of the second impurity region (62) includes a projecting portion (88) which selectively projects at the second principal surface (4) side directly below the first trench (64).

### Appendix 1-10-2

The semiconductor device (1) according to Appendix 1-2-2, further including a mesa region (89) of a second conductivity type which selectively projects in a semi-circular shape or a semi-elliptical shape from a bottom portion of the second impurity region (62) toward the second principal surface (4) side directly below each of the first trenches (64).

### Appendix 1-10-3

The semiconductor device (1) according to Appendix 1-10-2, further including a plurality of second trenches (39, 54, 74) which are formed in the first principal surface (3) of the IGBT region (8) and
a third impurity region (87) of a second conductivity type which selectively projects in a semi-circular shape or a semi-elliptical shape from the bottom wall of the second trench (39, 54, 74) toward the second principal surface (4) side, wherein
the mesa region (89) and the third impurity region (87) have the same impurity concentration.

### Appendix 1-11

The semiconductor device (1) according to Appendix 1-10, wherein the second portion (58) of the second impurity region (62) includes a base portion (77) which extends so as to continuously cross the plurality of first trenches (64) and is connected to the projecting portion (88) directly below each of the first trenches (64), and
the base portion (77) has a curved portion (90) formed in a curved shape that is raised toward the second principal surface (4) side between the mutually adjacent projecting portions (88).

### Appendix 1-12

The semiconductor device (1) according to Appendix 1-11, wherein the projecting portion (88) has a curved shape which is larger in projection amount than the curved shape of the curved portion (90).

### Appendix 1-13

The semiconductor device (1) according to any one of Appendix 1-10 to Appendix 1-12, wherein the projecting portion (88) has a depth which is substantially the same as the third impurity region (87).

### Appendix 1-14

The semiconductor device (1) according to any one of Appendix 1-10 to Appendix 1-13, wherein the plurality of second trenches (39, 54, 74) are arrayed at a first pitch (P1), and
the plurality of first trenches (64) are arrayed at a second pitch (P2) which is the same as the first pitch (P1).

### Appendix 1-14-2

The semiconductor device (1) according to Appendix 1-14, wherein the first pitch (P1) and the second pitch (P2) are not less than 1.0 μm and not more than 3.5 μm.

### Appendix 1-15

The semiconductor device (1) according to any one of Appendix 1-10 to Appendix 1-13, wherein the plurality of second trenches (39, 54, 74) are arrayed at a first pitch (P1), and
the plurality of first trenches (64) are arrayed at a second pitch (P2) which is larger than the first pitch (P1).

### Appendix 1-15-2

The semiconductor device (1) according to Appendix 1-15, wherein the second pitch (P2) is not less than 1.0 times and not more than 3.0 times larger than the first pitch (P1).

### Appendix 1-15-3

The semiconductor device (1) according to Appendix 1-15-2, wherein the first pitch (P1) is not less than 1.0 μm and not more than 3.5 μm, and
the second pitch (P2) is not less than 1.0 μm and not more than 10.0 μm.

### Appendix 1-16

The semiconductor device (1) according to Appendix 1-1, wherein the second impurity region (62) includes an inclined portion (95) which is downwardly inclined to a position deeper than the bottom wall of the first trench (64) from a side wall of at least one of the first trenches (64) toward the second principal surface (4) in a direction away from the IGBT region (8) and a flat portion (96) which is continuous to a lower end (98) of the inclined portion (95), extends along the first principal surface (3) and integrally covers the bottom walls of the plurality of first trenches (64) from the second principal surface (4) side.

### Appendix 1-16-2

The semiconductor device (1) according to Appendix 1-16, wherein the inclined portion (95) includes a curved portion (95) in a circular arc shape that is curved toward the IGBT region (8).

### Appendix 1-17

The semiconductor device (1) according to Appendix 1-16, wherein the inclined portion (95) is downwardly inclined toward the second principal surface (4), with a side wall of the first trench (64) which is closest to the IGBT region (8) among the plurality of first trenches (64) given as a starting point (97).

### Appendix 1-17-2

The semiconductor device (1) according to Appendix 1-17, wherein the inclined portion (95) is divided by the first trench (64) which is adjacent to the first trench (64) that forms the starting point (97) of the inclined portion (95).

### Appendix 1-18

The semiconductor device (1) according to any one of Appendix 1-1 to Appendix 1-17, wherein the second impurity region (62) has the deepest portion at a depth position which is not less than 0.1 μm and not more than 3.0 μm from the bottom wall of the first trench (64).

### Appendix 1-19

The semiconductor device (1) according to any one of Appendix 1-1 to Appendix 1-18, wherein the IGBT region (8) includes a drift region (30) of a first conductivity type which is formed inside the semiconductor layer (2) and an FET structure (35) which includes a body region (45) of a second conductivity type that is formed in a surface layer portion of the drift region (30), an emitter region (46) of a first conductivity type that is formed in a surface layer portion of the body region (45) and a gate conductive layer (41) that opposes the body region (45) and the emitter region (46) via a gate insulating layer (40).

### Appendix 1-19-2

The semiconductor device (1) according to Appendix 1-19, including a second insulating layer (79) which covers the first principal surface (3) in the IGBT region (8) and has a diode opening (84) that exposes the first principal surface (3) in the diode region (9), and
a plug electrode (91) which is embedded in the second insulating layer (79) and electrically connected to the emitter region (46), wherein
the second electrode (13) is electrically connected to the emitter region (46) via the plug electrode (91) on the second insulating layer (79).

### Appendix 1-19-3

The semiconductor device (1) according to Appendix 1-19 or Appendix 1-19-2, wherein the FET structure (35) includes a carrier storage region (47) of a first conductivity type which is formed between the body region (45) and the drift region (30) and has an impurity concentration higher than that of the drift region (30).

### Appendix 1-19-4

The semiconductor device (1) according to Appendix 1-19-3, including a third trench (73A) which is formed in the first principal surface (3) of the IGBT region (8), adjacent to the first trench (64) and forms a boundary (72) between the IGBT region (8) and the diode region (9), and
a second embedded conductive layer (76) which is embedded in the third trench (73A) via an insulating layer (75).

### Appendix 1-19-5

The semiconductor device (1) according to Appendix 1-19-4, wherein the body region (45) and a fourth impurity region (47) having the same impurity concentration as the carrier storage region (47) are sequentially formed from the first principal surface (3) side between the third trench (73A) and the first trench (64) adjacent to the third trench (73A).

### Appendix 1-19-6

The semiconductor device (1) according to any one of Appendix 1-19 to Appendix 1-19-5, wherein the IGBT region (8) includes a floating region (52) of a second conductivity type which is adjacent to the FET structure (35) in a surface layer portion of the first principal surface (3) and formed in an electrically floating state.

### Appendix 1-19-7

The semiconductor device (1) according to the Appendix 1-19-6, wherein the IGBT region (8) includes a region separating structure (53) which demarcates the floating region (52) from the FET structure (35) in the first principal surface (3).

### Appendix 1-20

The semiconductor device (1) according to any one of Appendix 1-1 to Appendix 1-19, further including an RC-IGBT array (12) which includes the plurality of IGBT regions (8) and the plurality of diode regions (9) that are arrayed alternately along the first direction (X).

### Appendix 1-21

The semiconductor device (1) according to any one of Appendix 1-1 to Appendix 1-20, wherein the IGBT region (8) includes a collector region (34) of a second conductivity type which is formed in a surface layer portion of the second principal surface (4), and
the collector region (34) includes a lead-out region (182) which crosses a boundary (72) between the IGBT region (8) and the diode region (9) and is led out to the diode region (9) side.

### Appendix 1-21-2

The semiconductor device (1) according to Appendix 1-21, wherein the lead-out region (182) has a width of not less than 30 μm and not more than 50 μm from the boundary (72) between the IGBT region (8) and the diode region (9).

### Appendix 1-22

A method of manufacturing the semiconductor device (1), comprising:
a step of forming a first impurity introducing region (62) by selectively introducing a second conductivity type impurity into a diode region (9) in a semiconductor layer (162), wherein the semiconductor layer (162) has a first principal surface (163) on which a first impurity region (30, 31) of a first conductivity type and a second principal surface (164) at the opposite side thereof are formed and an IGBT region (8) and the diode region (9) that are adjacent to each other are set in the semiconductor layer (162);
a step of forming, in the diode region (9), a plurality of first trenches (64) so as to sandwich the first impurity introducing region (62) between the plurality of first trenches (64);
a step of forming, by diffusing the second conductivity type impurity of the first impurity introducing region (62) by a thermal treatment, a second impurity region (62) which extends deeper than a bottom wall of the first trench (64) from the first principal surface (163) along a side wall of the first trench (64) in a diode cell region (69) demarcated by being sandwiched between the mutually adjacent first trenches (64) and also forms, with the first impurity region (30, 31), a pn junction portion (68) that covers at least a part of the bottom walls of the mutually adjacent first trenches (64);
a step of forming a first electrode (32) so as to be electrically connected to the first impurity region (30, 31); and
a step of forming a second electrode (13) so as to be electrically connected to the second impurity region (62).

### Appendix 1-23

A method of manufacturing the semiconductor device (1), comprising:
a step of forming a plurality of first trenches (64) in a first principal surface (163) of a diode region (9) of a semiconductor layer (162), wherein the semiconductor layer (162) has the first principal surface (163) on which a first impurity region (30, 31) of a first conductivity type and a second principal surface (164) at the opposite side thereof are formed and an IGBT region (8) and the diode region (9) that are adjacent to each other are set in the semiconductor layer (162);
a step of forming a first impurity introducing region (62) by selectively introducing a second conductivity type impurity into a surface layer portion of the first principal surface (163) of the diode cell region (69) demarcated by being sandwiched between the mutually adjacent first trenches (64);
a step of forming, by diffusing the second conductivity type impurity of the first impurity introducing region (62) by a thermal treatment, a second impurity region (62) which extends in the diode cell region (69) deeper than a bottom wall of the first trench (64) from the first principal surface (163) along a side wall of the first trench (64) and also forms, with the first impurity region (30, 31), a pn junction portion (68) that covers at least a part of the bottom walls of the mutually adjacent first trenches (64);
a step of forming a first electrode (32) so as to be electrically connected to the first impurity region (30, 31); and
a step of forming a second electrode (13) so as to be electrically connected to the second impurity region (62).

### Appendix 1-24

A method of manufacturing the semiconductor device (1), comprising:
a step of forming a first impurity introducing region (100) by selectively introducing a second conductivity type impurity into a diode region (9) in a semiconductor layer (162), the semiconductor layer (162) having a first principal surface (163) on which a first impurity region (30, 31) of a first conductivity type and a second principal surface (164) at the opposite side thereof formed on the semiconductor layer (162) and an IGBT region (8) and the diode region (9) that are adjacent to each other are set in the semiconductor layer (162);
a step of forming, by diffusing the second conductivity type impurity of the first impurity introducing region (100) is diffused at the second principal surface (164) side by a thermal treatment, a second impurity region (62) having a predetermined depth;
a step of forming, by forming a plurality of first trenches (64) shallower than the second impurity region (62) in the second impurity region (62), a pn junction portion (68) that covers at least a part of the bottom walls of the mutually adjacent first trenches (64) by the second impurity region (62) which extends deeper than a bottom wall of the first trench (64) from the first principal surface (163) along a side wall of the first trench (64) in a diode cell region (69) demarcated by being sandwiched between the mutually adjacent first trenches (64) and also forms, with the first impurity region (30, 31);
a step of forming a first electrode (32) so as to be electrically connected to the first impurity region (30, 31); and
a step of forming a second electrode (13) so as to be electrically connected to the second impurity region (62).

### Appendix 1-25

A method of manufacturing the semiconductor device (1), comprising:
a step of forming a first impurity introducing region (62) by selectively introducing a second conductivity type impurity into a diode region (9) in a semiconductor layer (162), wherein the semiconductor layer (162) has a first principal surface (163) on which a first impurity region (30, 31) of a first conductivity type and a second principal surface (164) at the opposite side thereof are formed and an IGBT region (8) and the diode region (9) that are adjacent to each other are set in the semiconductor layer (162);
a step of forming, in the diode region (9), a plurality of first trenches (64) so as to sandwich the first impurity introducing region (62) between the plurality of first trenches (64);
a step of forming a second trench (39, 54, 74) in the first principal surface (163) of the IGBT region (8);
a step of forming, by selectively introducing a second conductivity type impurity into a bottom wall of the second trench (39, 54, 74) and a bottom wall of the first trench (64), a first bottom portion impurity region (87) in the bottom wall of the first trench (64) and forming a second bottom portion impurity region (87) in the bottom wall of the second trench (39, 54, 74);
a step of forming, by selectively introducing the second conductivity type impurity of the first impurity introducing region (62) by a thermal treatment so as to be made integral with the first bottom portion impurity region (87), a second impurity region (62) which extends deeper than the bottom wall of the first trench (64) from the first principal surface (163) along a side wall of the first trench (64) in a diode cell region (69) demarcated by being sandwiched between the mutually adjacent first trenches (64) and also forms, with the first impurity region (30, 31), a pn junction portion (68) that covers at least a part of the bottom walls of the mutually adjacent first trenches (64), a step of forming a first electrode (32) so as to be electrically connected to the first impurity region (30, 31); and
a step of forming a second electrode (13) so as to be electrically connected to the second impurity region (62).

### Appendix 1-26

A method of manufacturing the semiconductor device (1), comprising:
a step of forming a plurality of first trenches (64) in a first principal surface (163) of a diode region (9) of a semiconductor layer (162), wherein the semiconductor layer (162) has the first principal surface (163) on which a first impurity region (30, 31) of a first conductivity type and a second principal surface (164) at the opposite side thereof are formed and an IGBT region (8) and the diode region (9) that are adjacent to each other are set in the semiconductor layer (162);
a step of forming a second trench (39, 54, 74) in the first principal surface (163) of the IGBT region (8);
a step of forming, by selectively introducing a second conductivity type impurity into a bottom wall of the second trench (39, 54, 74) and a bottom wall of the first trench (64), a first bottom portion impurity region (87) in the bottom wall of the first trench (64) and forming a second bottom portion impurity region (87) in the bottom wall of the second trench (39, 54, 74);
a step of forming a first impurity introducing region (62) by selectively introducing a second conductivity type impurity into a surface layer portion of the first principal surface (163) of the diode cell region (69) demarcated by being sandwiched between the mutually adjacent first trenches (64);
a step of forming, by diffusing the second conductivity type impurity of the first impurity introducing region (62) by a thermal treatment so as to be made integral with the first bottom portion impurity region, a second impurity region (62) which extends in the diode cell region (69) deeper than a bottom wall of the first trench (64) from the first principal surface (163) along a side wall of the first trench (64) and also forms, with the first impurity region (30, 31), a pn junction portion (68) that covers at least a part of the bottom walls of the mutually adjacent first trenches (64);
a step of forming a first electrode (32) so as to be electrically connected to the first impurity region (30, 31); and
a step of forming a second electrode (13) so as to be electrically connected to the second impurity region (62).

### Appendix 2-1

A semiconductor device (1), comprising:
a semiconductor layer (2) which has a first principal surface (3) and a second principal surface (4) at the opposite side thereof;
an IGBT region (8) which is formed in the semiconductor layer (2);
a diode region (9) which is formed in the semiconductor layer (2) and adjacent to the IGBT region (8);
a first impurity region (30, 31) of a first conductivity type which is formed inside the semiconductor layer (2);
a gate trench (39) which is formed in the first principal surface (3) of the IGBT region (8);
a gate conductive layer (41) which is embedded in the gate trench (39) via a gate insulating layer (40);
a plurality of first trenches (64) which are formed in the first principal surface (3) of the diode region (9);
a first embedded conductive layer (66) which is embedded in the first trench (64) via the first insulating layer (65);
a diode cell region (69) which is demarcated by being sandwiched between the mutually adjacent first trenches (64);
a second impurity region (62) of a second conductivity type which is formed in a surface layer portion of the first principal surface (3) in the diode cell region (69) and forms a pn junction portion (68) with the first impurity region (30, 31);
a recess (67) which is formed in an opening end portion of the first trench (64), demarcated by side walls (105, 112, 125, 127) of the first trench (64) and an upper end portion (101) of the first embedded conductive layer (66) and to which a part of the second impurity region (62) is exposed;
a first electrode (32) which is electrically connected to the first impurity region (30, 31);
and a second electrode (13) which is formed on the first principal surface (3) of the semiconductor layer (2) and connected to the second impurity region (62) at least in the first principal surface (3) and the side walls (105, 112, 125, 127) of the recess (67); wherein
the upper end portion (101) of the first embedded conductive layer (66) is positioned further at the second principal surface (4) side than an upper end portion (102) of the gate conductive layer (41) with respect to the first principal surface (3).

### Appendix 2-1-2

The semiconductor device (1) according to Appendix 2-1, wherein the first trench (64) includes a trench backfilled portion (103) which is formed at the second principal surface (4) side with respect to the recess (67), provided with the first embedded conductive layer (66) that is embedded and has a flat side wall (104), and
the recess (67) has a flat side wall (105) which is an extended portion of a side wall (104) of the trench backfilled portion (103).

### Appendix 2-1-3

The semiconductor device (1) according to Appendix 2-1-2, wherein the recess (67) and the trench backfilled portion (103) continue at a substantially constant width from the first principal surface (3) toward a bottom wall of the first trench (64).

### Appendix 2-2

The semiconductor device (1) according to Appendix 2-1, wherein an opening edge portion (108, 112) of the first trench (64) which is formed in a side wall (105, 112, 125, 127) of the recess (67) is substantially different in shape from an opening edge portion (106, 110) of the gate trench (39) in sectional view.

### Appendix 2-3

The semiconductor device (1) according to Appendix 2-2, wherein the opening edge portion (106, 110) of the gate trench (39) has a corner portion (106) at which the first principal surface (3) intersects a side wall of the gate trench (39), and
the opening edge portion (108, 112) of the first trench (64) has a recessed edge portion (108, 112) in a circular-arc shape which is recessed toward an interior of the diode cell region (69).

### Appendix 2-4

The semiconductor device (1) according to Appendix 2-2, wherein the opening edge portion (106, 110) of the gate trench (39) has a gate-side recessed edge portion (110) which is recessed toward an interior of the semiconductor layer (2), and
the opening edge portion (108, 112) of the first trench (64) has a recessed edge portion (112) in a circular-arc shape which is recessed toward an interior of the diode cell region (69) at a greater extent than the gate-side recessed edge portion (110).

### Appendix 2-4-2

The semiconductor device (1) according to Appendix 2-3 or Appendix 2-4, wherein a recessed amount (A) of the recessed edge portion (112) to the interior of the diode cell region (69) in a direction along the first principal surface (3) is not less than 1.0 times and not more than 10.0 times larger than a thickness (T) of the first insulating layer (65).

### Appendix 2-4-3

The semiconductor device (1) according to Appendix 2-4-2, wherein the thickness (T) of the first insulating layer (65) is not less than 80 nm and not more than 150 nm, and
the recessed amount (A) of the recessed edge portion is not less than 0.05 μm and not more than 1.5 μm.

### Appendix 2-5

The semiconductor device (1) according to Appendix 2-3 or Appendix 2-4, wherein the first trench (64) includes a trench backfilled portion (103) which is formed at the second principal surface (4) side with respect to the recess (67) and wherein the first embedded conductive layer (66) is embedded, and
the recess (67) includes a cup portion (113) which is in sectional view formed in a cup shape having a side wall in the recessed edge portion (112) which is inclined toward the trench backfilled portion (103) from the first principal surface (3) of the diode cell region (69) at both sides neighboring to one side and the other side of the first trench (64) in a first direction (X).

### Appendix 2-6

The semiconductor device (1) according to Appendix 2-5, wherein the first trench (64) extends in a second direction (Y) which intersects the first direction (X), and
the cup portion (113) is formed in a semi-cylindrical shape along the second direction (Y).

### Appendix 2-7

The semiconductor device (1) according to Appendix 2-5 or Appendix 2-6, wherein the cup portion (113) has a width (W1) which is not less than 0.62 times and not more than 6.14 times larger than a width (W2) of the trench backfilled portion (103).

### Appendix 2-8

The semiconductor device (1) according to Appendix 2-7, wherein the width (W2) of the trench backfilled portion (103) is not less than 0.7 μm and not more than 1.3 μm, and
the width (W1) of the cup portion (113) is not less than 0.80 μm and not more than 4.3 μm.

### Appendix 2-9

The semiconductor device (1) according to any one of Appendix 2-5 to Appendix 2-8, wherein the first embedded conductive layer (66) of the trench backfilled portion (103) and the upper end portion (101) of the first insulating layer (65) are exposed to a lower end of the cup portion (113).

### Appendix 2-10

The semiconductor device (1) according to any one of Appendix 2-5 to Appendix 2-8, wherein the recess (67) includes a recess lower portion (126) which has a flat lower side wall (125) continuing from the lower end of the cup portion (113) toward the bottom wall of the first trench (64).

### Appendix 2-11

The semiconductor device (1) according to Appendix 2-10, wherein a side wall (105, 112, 125, 127) of the recess (67) has a two stage structure including the flat lower side wall (125) of the recess lower portion (126) and an upper side wall (127) which is continuous to an upper end of the lower side wall (125) and includes the recessed edge portion (112) of the cup portion (113) in a circular-arc shape.

### Appendix 2-12

The semiconductor device (1) according to Appendix 2-11 or Appendix 2-10, wherein the recess lower portion (126) has the same width as the trench backfilled portion (103).

### Appendix 2-13

The semiconductor device (1) according to any one of Appendix 2-10 to Appendix 2-12, wherein the recess lower portion (126) has a depth (D2) which is not more than ½ of a width of the trench backfilled portion (103).

### Appendix 2-14

The semiconductor device (1) according to any one of Appendix 2-5 to Appendix 2-13, wherein the cup portion (113) has a depth (D) which is not less than 0.0052 times and not more than 7.5 times larger than a width (W3) of the first principal surface (3) of the diode cell region (69).

### Appendix 2-15

The semiconductor device (1) according to Appendix 2-14, wherein the width (W3) of the first principal surface (3) of the diode cell region (69) is not less than 0.2 μm and not more than 9.7 μm, and
the depth (D) of the cup portion (113) is not less than 0.05 μm and not more than 1.5 μm.

### Appendix 2-16

The semiconductor device (1) according to any one of Appendix 2-3 to Appendix 2-15, wherein the first principal surface (3) includes a diode first principal surface (119) which is formed in the diode cell region (69) and an IGBT first principal surface (120) which is formed in the IGBT region (8), and
the diode first principal surface (119) assumes a low position at the second principal surface (4) side with respect to the IGBT first principal surface (120).

### Appendix 2-17

The semiconductor device (1) according to Appendix 2-16, including a second insulating layer (79) which covers the IGBT first principal surface (120) and has a diode opening (84) that exposes the diode first principal surface (119), and
a step surface (122) which is exposed inside the diode opening (84), connects the IGBT first principal surface (120) and the diode first principal surface (119) and forms a step (121) between the IGBT first principal surface (120) and the diode first principal surface (119).

### Appendix 2-17-2

The semiconductor device (1) according to Appendix 2-17, wherein the step (121) between the IGBT first principal surface (120) and the diode first principal surface (119) is not less than 100 nm and not more than 500 nm.

### Appendix 2-18

The semiconductor device (1) according to any one of Appendix 2-1 to Appendix 2-17, wherein the second electrode (13) is embedded in the recess (67) and directly connected to the second impurity region (62) at least in the first principal surface (3) and the side wall (105, 112, 125, 127) of the recess (67).

### Appendix 2-18-2

The semiconductor device (1) according to Appendix 2-18, wherein the second impurity region (62) has an impurity concentration which is not less than 1.0×10¹⁵ cm⁻³ and not more than 1.0×10¹⁸ cm⁻³.

### Appendix 2-18-3

The semiconductor device (1) according to Appendix 2-18-2, wherein the second electrode (13) includes a part (22) which contains aluminum at a part directly in contact with the second impurity region (62).

### Appendix 2-19

The semiconductor device (1) according to any one of Appendix 2-1 to Appendix 2-18, wherein the second impurity region (62) has an impurity concentration which is not less than 1.0×10¹⁵ cm⁻³ and not more than 1.0×10¹⁸ cm⁻³.

### Appendix 2-20

The semiconductor device (1) according to any one of Appendix 2-1 to Appendix 2-19, wherein the IGBT region (8) includes a first conductivity type drift region (30) which is formed inside the semiconductor layer (2) and an FET structure (35) which includes a body region (45) of a second conductivity type that is formed in a surface layer portion of the drift region (30) and an emitter region (46) of a first conductivity type that is formed in a surface layer portion of the body region (45), and the second electrode (13) is electrically connected to the emitter region (46).

### Appendix 2-20-2

The semiconductor device (1) according to Appendix 2-20, including a second insulating layer (79) which covers the first principal surface (3) in the IGBT region (8) and has a diode opening (84) that exposes the first principal surface (3) in the diode region (9), and
a plug electrode (91) which is embedded in the second insulating layer (79) and electrically connected to the emitter region (46), wherein
the second electrode (13) is electrically connected to the emitter region (46) via the plug electrode (91) on the second insulating layer (79).

### Appendix 2-20-3

The semiconductor device (1) according to Appendix 2-20 or Appendix 2-20-2, wherein the FET structure (35) includes a carrier storage region (47) of a first conductivity type which is formed between the body region (45) and the drift region (30) (30) and has an impurity concentration higher than that of the drift region (30).

### Appendix 2-20-4

The semiconductor device (1) according to Appendix 2-20-3, wherein the FET structure (35) includes the plurality of second trenches (39, 54, 74), and
at least one of the plurality of second trenches (39, 54, 74) is adjacent to the first trench (64) and forms a boundary (72) between the IGBT region (8) and the diode region (9).

### Appendix 2-20-5

The semiconductor device (1) according to Appendix 2-20-4, wherein the body region (45) and a third impurity region (47) having the same impurity concentration as the carrier storage region (47) are sequentially formed from the first principal surface (3) side between the second trench (39, 54, 74) which forms the boundary (72) and the first trench (64) adjacent to the second trench (39, 54, 74).

### Appendix 2-20-6

The semiconductor device (1) according to any one of Appendix 2-20 to Appendix 2-20-5, wherein the IGBT region (8) includes a floating region (52) of a second conductivity type which is adjacent to the FET structure (35) in a surface layer portion of the first principal surface (3) and formed in an electrically floating state.

### Appendix 2-20-7

The semiconductor device (1) according to Appendix 2-20-6, wherein the IGBT region (8) includes a region separating structure (53) which demarcates the floating region (52) from the FET structure (35) in the first principal surface (3).

### Appendix 2-21

The semiconductor device (1) according to any one of Appendix 2-1 to Appendix 2-20, further including an RC-IGBT array (12) which includes the plurality of IGBT regions (8) and the plurality of diode regions (9) that are arrayed alternately along the first direction (X).

### Appendix 2-22

The semiconductor device (1) according to any one of Appendix 2-1 to Appendix 2-21, wherein the IGBT region (8) includes a collector region (34) of a second conductivity type which is formed in a surface layer portion of the second principal surface (4), and
the collector region (34) includes a lead-out region (182) which crosses a boundary (72) between the IGBT region (8) and the diode region (9) and is led out to the diode region (9) side.

### Appendix 2-22-2

The semiconductor device (1) according to Appendix 2-22, wherein the lead-out region (182) has a width of not less than 30 μm and not more than 50 μm from the boundary (72) between the IGBT region (8) and the diode region (9).

### Appendix 2-23

A method of manufacturing the semiconductor device (1), comprising:
a step of forming a gate trench (39) in a first principal surface (163) of the IGBT region (8) of a semiconductor layer (2), wherein the semiconductor layer (2) has the first principal surface (163) on which a first impurity region (30, 31) of a first conductivity type and a second principal surface (164) at the opposite side thereof are formed and the IGBT region (8) and a diode region (9) that are adjacent to each other are set in the semiconductor layer (2);
a step of forming a plurality of first trenches (64) in the first principal surface (163) of the diode region (9);
a step of forming a gate insulating layer (40) inside the gate trench (39);
a step of forming a first insulating layer (65) inside of the first trench (64);
a step of embedding a gate conductive layer (41) via the gate insulating layer (40) in the gate trench (39);
a step of embedding a first embedded conductive layer (66) via the first insulating layer (65) in the first trench (64);
a step of digging down, by selectively etching the first embedded conductive layer (66), the first embedded conductive layer (66) so that an upper end portion (101) of the first embedded conductive layer (66) is made lower than an upper end portion (102) of the gate conductive layer (41) with respect to the first principal surface (163), and demarcating a recess (67) by a side wall (105) of the first trench (64) and the upper end portion (101) of the first embedded conductive layer (66);
a step of forming a second impurity region (62) of a second conductivity type in a diode cell region (69) which is demarcated by being sandwiched between the mutually adjacent first trenches (64);
a step of forming a first electrode (32) so as to be electrically connected to the first impurity region (30, 31); and
a step of forming a second electrode (13) on the first principal surface (163) of the semiconductor layer (2) so as to be connected to the second impurity region (62) at least in the first principal surface (163) and a side wall (105) of the recess (67).

### Appendix 2-24

A method of manufacturing the semiconductor device (1) comprising:
a step of forming a gate trench (39) in a first principal surface (163) of the IGBT region (8) of a semiconductor layer (2), wherein the semiconductor layer (2) has the first principal surface (163) on which a first impurity region (30, 31) of a first conductivity type and a second principal surface (164) at the opposite side thereof are formed and the IGBT region (8) and a diode region (9) that are adjacent to each other are set in the semiconductor layer (2);
a step of forming, by selectively subjecting a surface layer portion of the first principal surface (163) of the diode region (9) to an isotropic etching, a cup-shape recess portion (115) which is recessed to the first principal surface (163) in a circular arc shape;
a step of forming, by selectively subjecting the semiconductor layer (2) to an anisotropic etching from a bottom wall of the recess portion (115) to form a trench main body portion (118) having a width narrower than the recess portion (115), a plurality of first trenches (64) in which the recess portion and the trench main body portion (118) are made integral;
a step of forming a gate insulating layer (40) inside the gate trench (39);
a step of forming a first insulating layer (65) inside of the first trench (64);
a step of embedding a gate conductive layer (41) via the gate insulating layer (40) in the gate trench (39);
a step of embedding a first embedded conductive layer (66) via the first insulating layer (65) in the first trench (64);
a step of removing, by selectively etching the first embedded conductive layer (66), the first embedded conductive layer (66) at least inside the recess portion (115), and making an upper end portion (101) of the first embedded conductive layer (66) lower than an upper end portion (102) of the gate conductive layer (41) with respect to the first principal surface (163);
a step of forming a second impurity region (62) of a second conductivity type in a diode cell region (69) which is demarcated by being sandwiched between the mutually adjacent first trenches (64);
a step of forming a first electrode (32) so as to be electrically connected to the first impurity region (30, 31); and
a step of forming a second electrode (13) on the first principal surface (163) of the semiconductor layer (2) so as to be connected to the second impurity region (62) at least in the first principal surface (163) and a side wall (112) of the recess portion (115) of the first trench (64).

### Appendix 2-25

The method of manufacturing a semiconductor device (1) according to Appendix 2-24, wherein the step of etching the first embedded conductive layer (66) includes a step of removing a part of the first embedded conductive layer (66) inside the trench main body portion (118) subsequent to removal of the first embedded conductive layer (66) inside the recess portion.

### Appendix 2-26

A method of manufacturing the semiconductor device (1), comprising:
a step of forming a gate trench (39) in a first principal surface (163) of the IGBT region (8) of a silicon semiconductor layer (162), wherein the silicon semiconductor layer (162) has the first principal surface (163) on which a first impurity region (30, 31) of a first conductivity type and a second principal surface (164) at the opposite side thereof are formed and the IGBT region (8) and a diode region (9) that are adjacent to each other are set in the silicon semiconductor layer (162);
a step of forming a plurality of first trenches (64) in the first principal surface (163) of the diode region (9);
a step of forming a gate insulating layer (40) inside the gate trench (39);
a step of forming a first insulating layer (65) inside of the first trench (64);
a step of embedding a gate conductive layer (41) that contains a polysilicon via the gate insulating layer (40) in the gate trench (39);
a step of embedding a first embedded conductive layer (66) containing a polysilicon via the first insulating layer (65) in the first trench (64);
a step of forming a second insulating layer (79) which covers the IGBT region (8) and has a diode opening (84) which selectively exposes the diode region (9) in the first principal surface (163);
a step of forming, by subjecting the first embedded conductive layer (66) and a part of the silicon semiconductor layer (162) adjacent to the first embedded conductive layer (66) to an isotropic etching via the diode opening (84), a cup-shaped cup portion (113) which is recessed in a circular arc shape with respect to the first principal surface (163) at an opening end portion of the first trench (64);
a step of forming a second impurity region (62) of a second conductivity type in a diode cell region (69) which is demarcated by being sandwiched between the mutually adjacent first trenches (64);
a step of forming a first electrode (32) so as to be electrically connected to the first impurity region (30, 31); and
a step of forming a second electrode (13) so as to be connected to the second impurity region (62) at least in the first principal surface (163) and a side wall (112) of the cup portion (113) of the first trench (64) on the first principal surface (163) of the semiconductor layer (162).

### Appendix 3-1

A semiconductor device (1), comprising:
a semiconductor layer (2) which has a first principal surface (3) and a second principal surface (4) at the opposite side thereof;
an IGBT region (8) which is formed in the semiconductor layer (2);
a diode region (9) which is formed in the semiconductor layer (2) and adjacent to the IGBT region (8);
a first impurity region (30, 31) of a first conductivity type which is formed inside the semiconductor layer (2);
a gate trench (39) which is formed in the first principal surface (3) of the IGBT region (8);
a gate conductive layer (41) which is embedded in the gate trench (39) via a gate insulating layer (40);
a plurality of first trenches (64) which are formed in the first principal surface (3) of the diode region (9);
a first embedded conductive layer (66) which is embedded in the first trench (64) via the first insulating layer (65);
a diode cell region (69) which is demarcated by being sandwiched between the mutually adjacent first trenches (64);
a second impurity region (62) of a second conductivity type which is formed in a surface layer portion of the first principal surface (3) in the diode region (9), wherein the second impurity region (62) extends in the diode cell region (69) deeper than a bottom wall of the first trench (64) from the first principal surface (3) along a side wall of the first trench (64) and also forms, with the first impurity region (30, 31), a pn junction portion (68) which strides between bottom walls of the mutually adjacent first trenches (64);
a recess (67) which is formed in an opening end portion of the first trench (64), demarcated by side walls (105, 112, 125, 127) of the first trench (64) and an upper end portion (101) of the first embedded conductive layer (66) and to which a part of the second impurity region (62) is exposed;
a first electrode (32) which is electrically connected to the first impurity region (30, 31);
and a second electrode (13) which is formed on the first principal surface (3) of the semiconductor layer (2) and connected to the second impurity region (62) at least in the first principal surface (3) and the side walls (105, 112, 125, 127) of the recess (67); wherein
the upper end portion (101) of the first embedded conductive layer (66) is positioned further at the second principal surface (4) side than an upper end portion (102) of the gate conductive layer (41) with respect to the first principal surface (3).

### Appendix 3-2

The semiconductor device (1) according to Appendix 3-1, wherein the plurality of diode cell regions (69) are adjacent to each other with the first trench (64) therebetween, and
the second impurity region (62) includes a first portion (57) which is formed in each of the diode cell regions (69) and a second portion (58) which extends so as to cross the plurality of first trenches (64) along the first principal surface (3), integrally covers the bottom walls of the plurality of first trenches (64) from the second principal surface (4) side, couples the first portions (57) of the plurality of diode cell regions (69) and forms the pn junction portion (68) with the first impurity region (30, 31).

### Appendix 3-3

The semiconductor device (1) according to Appendix 3-2, wherein the pn junction portion (68) has a sectional shape which alternately rises and falls at the first principal surface (3) side and at the second principal surface (4) side along the first principal surface (3) of the semiconductor layer (2).

### Appendix 3-4

The semiconductor device (1) according to Appendix 3-3, wherein the pn junction portion (68) is raised toward the second principal surface (4) side directly below the diode cell region (69) and raised toward the first principal surface (3) side directly below the first trench (64).

### Appendix 3-5

The semiconductor device (1) according to Appendix 3-1, wherein the plurality of diode cell regions (69) are adjacent to each other with the first trench (64) therebetween, and
the second impurity region (62) is formed physically independent in each of the diode cell regions (69) and forms the pn junction portion (68) with the first impurity region (30, 31) on a lateral side of the bottom wall of the first trench (64).

### Appendix 3-6

The semiconductor device (1) according to Appendix 3-5, wherein the pn junction portion (68) has a first end portion (28) in a bottom wall of one of the mutually adjacent first trenches (64) and has a second end portion (29) in a bottom wall of the other of the mutually adjacent first trenches (64).

### Appendix 3-7

The semiconductor device (1) according to Appendix 3-6, wherein the pn junction portion (68) is formed, with the first end portion (28) and the second end portion (29) given as both end portions, in a curved shape which is raised toward the second principal surface (4) side with respect to the both end portions (28, 29).

### Appendix 3-8

The semiconductor device (1) according to any one of Appendix 3-1 to Appendix 3-7, including a plurality of second trenches (39, 54, 74) which are formed in the first principal surface (3) of the IGBT region (8) and arrayed at a first pitch (P1), wherein
the plurality of first trenches (64) are arrayed at a second pitch (P2) which is the same as the first pitch (P1).

### Appendix 3-9

The semiconductor device (1) according to any one of Appendix 3-1 to Appendix 3-7, including a plurality of second trenches (39, 54, 74) which are formed in the first principal surface (3) of the IGBT region (8) and arrayed at a first pitch (P1), wherein
the plurality of first trenches (64) are arrayed at a second pitch (P2) which is larger than the first pitch (P1).

### Appendix 3-10

The semiconductor device (1) according to Appendix 3-2, including a second trench (39, 54, 74) which is formed in the first principal surface (3) of the IGBT region (8) and
a third impurity region (87) of a second conductivity type which is selectively formed in a bottom wall of the second trench (39, 54, 74), wherein
the second portion (58) of the second impurity region (62) includes a projecting portion (88) which selectively projects at the second principal surface (4) side directly below the first trench (64).

### Appendix 3-11

The semiconductor device (1) according to Appendix 3-10, wherein the second portion (58) of the second impurity region (62) includes a base portion (77) which extends so as to continuously cross the plurality of first trenches (64) and is connected to the projecting portion (88) directly below each of the first trenches (64), and
the base portion (77) has a curved portion (90) formed in a curved shape that is raised toward the second principal surface (4) side between the mutually adjacent projecting portions (88).

### Appendix 3-12

The semiconductor device (1) according to Appendix 3-11, wherein the projecting portion (88) has a curved shape which is larger in projection amount than the curved shape of the curved portion (90).

### Appendix 3-13

The semiconductor device (1) according to any one of Appendix 3-10 to Appendix 3-12, wherein the projecting portion (88) has a depth which is substantially the same as the third impurity region (87).

### Appendix 3-14

The semiconductor device (1) according to any one of Appendix 3-10 to Appendix 3-13, wherein the plurality of second trenches (39, 54, 74) are arrayed at a first pitch (P1), and
the plurality of first trenches (64) are arrayed at a second pitch (P2) which is the same as the first pitch (P1).

### Appendix 3-15

The semiconductor device (1) according to any one of Appendix 3-10 to Appendix 3-13, wherein the plurality of second trenches (39, 54, 74) are arrayed at a first pitch (P1), and
the plurality of first trenches (64) are arrayed at a second pitch (P2) which is larger than the first pitch (P1).

### Appendix 3-16

The semiconductor device (1) according to Appendix 3-1, wherein the second impurity region (62) includes an inclined portion (95) which is downwardly inclined to a position deeper than the bottom wall of the first trench (64) from a side wall of at least one of the first trenches (64) toward the second principal surface (4) in a direction away from the IGBT region (8) and a flat portion (96) which is continuous to a lower end (98) of the inclined portion (95), extends along the first principal surface (3) and integrally covers the bottom walls of the plurality of first trenches (64) from the second principal surface (4) side.

### Appendix 3-17

The semiconductor device (1) according to Appendix 3-16, wherein the inclined portion (95) is downwardly inclined toward the second principal surface (4), with a side wall of the first trench (64) which is closest to the IGBT region (8) among the plurality of first trenches (64) given as a starting point (97).

### Appendix 3-18

The semiconductor device (1) according to any one of Appendix 3-1 to Appendix 3-17, wherein the second impurity region (62) has the deepest portion at a depth position which is not less than 0.1 μm and not more than 3.0 μm from the bottom wall of the first trench (64).

### Appendix 3-19

The semiconductor device (1) according to any one of Appendix 3-1 to Appendix 3-18, wherein the IGBT region (8) includes a drift region (30) of a first conductivity type which is formed inside the semiconductor layer (2) and an FET structure (35) which includes a body region (45) of a second conductivity type that is formed in a surface layer portion of the drift region (30), an emitter region (46) of a first conductivity type that is formed in a surface layer portion of the body region (45) and a gate conductive layer (41) that opposes the body region (45) and the emitter region (46) via a gate insulating layer (40).

### Appendix 3-20

The semiconductor device (1) according to any one of Appendix 3-1 to Appendix 3-19, further including an RC-IGBT array (12) which includes the plurality of IGBT regions (8) and the plurality of diode regions (9) that are arrayed alternately along the first direction (X).

### Appendix 3-21

The semiconductor device (1) according to any one of Appendix 3-1 to Appendix 3-20, wherein an opening edge portion (108, 112) of the first trench (64) which is formed in a side wall (105, 112, 125, 127) of the recess (67) is substantially different in shape from an opening edge portion (106, 110) of the gate trench (39) in sectional view.

### Appendix 3-22

The semiconductor device (1) according to Appendix 3-21, wherein the opening edge portion (106, 110) of the gate trench (39) has a corner portion (106) at which the first principal surface (3) intersects a side wall of the gate trench (39), and
the opening edge portion (108, 112) of the first trench (64) has a recessed edge portion (108, 112) in a circular-arc shape which is recessed toward an interior of the diode cell region (69).

### Appendix 3-23

The semiconductor device (1) according to Appendix 3-21, wherein the opening edge portion (106, 110) of the gate trench (39) has a gate-side recessed edge portion (110) which is recessed toward an interior of the semiconductor layer (2), and
the opening edge portion (108, 112) of the first trench (64) has a recessed edge portion (112) in a circular-arc shape which is recessed toward an interior of the diode cell region (69) at a greater extent than the gate-side recessed edge portion (110).

### Appendix 3-24

The semiconductor device (1) according to Appendix 3-22 or Appendix 3-23, wherein the first trench (64) includes a trench backfilled portion (103) which is formed at the second principal surface (4) side with respect to the recess (67) and wherein the first embedded conductive layer (66) is embedded, and
the recess (67) includes a cup portion (113) which is in sectional view formed in a cup shape having a side wall in the recessed edge portion (112) which is inclined toward the trench backfilled portion (103) from the first principal surface (3) of the diode cell region (69) at both sides neighboring to one side and the other side of the first trench (64) in a first direction (X).

### Appendix 3-25

The semiconductor device (1) according to Appendix 3-24, wherein the first trench (64) extends in a second direction (Y) which intersects the first direction (X), and
the cup portion (113) is formed in a semi-cylindrical shape along the second direction (Y).

### Appendix 3-26

The semiconductor device (1) according to Appendix 3-24 or Appendix 3-25, wherein the cup portion (113) has a width (W1) which is not less than 0.62 times and not more than 6.14 times larger than a width (W2) of the trench backfilled portion (103).

### Appendix 3-27

The semiconductor device (1) according to Appendix 3-26, wherein the width (W2) of the trench backfilled portion (103) is not less than 0.7 μm and not more than 1.3 μm, and
the width (W1) of the cup portion (113) is not less than 0.80 μm and not more than 4.3 μm.

### Appendix 3-28

The semiconductor device (1) according to any one of Appendix 3-24 to Appendix 3-27, wherein the first embedded conductive layer (66) of the trench backfilled portion (103) and the upper end portion (101) of the first insulating layer (65) are exposed to a lower end of the cup portion (113).

### Appendix 3-29

The semiconductor device (1) according to any one of Appendix 3-24 to Appendix 3-27, wherein the recess (67) includes a recess lower portion (126) which has a flat lower side wall (125) continuing from the lower end of the cup portion (113) toward the bottom wall of the first trench (64).

### Appendix 3-30

The semiconductor device (1) according to Appendix 3-29, wherein a side wall (105, 112, 125, 127) of the recess (67) has a two stage structure including the flat lower side wall (125) of the recess lower portion (126) and an upper side wall (127) which is continuous to an upper end of the lower side wall (125) and includes the recessed edge portion (112) of the cup portion (113) in a circular-arc shape.

### Appendix 3-31

The semiconductor device (1) according to Appendix 3-29 or Appendix 3-30, wherein the recess lower portion (126) has the same width as the trench backfilled portion (103).

### Appendix 3-32

The semiconductor device (1) according to any one of Appendix 3-29 to Appendix 3-31, wherein the recess lower portion (126) has a depth which is not more than ½ of a width of the trench backfilled portion (103).

### Appendix 3-33

The semiconductor device (1) according to any one of Appendix 3-24 to Appendix 3-32, wherein the cup portion (113) has a depth (D) which is not less than 0.0052 times and not more than 7.5 times larger than a width (W3) of the first principal surface (3) of the diode cell region (69).

### Appendix 3-34

The semiconductor device (1) according to Appendix 3-33, wherein the width (W3) of the first principal surface (3) of the diode cell region (69) is not less than 0.2 μm and not more than 9.7 μm, and
the depth (D) of the cup portion (113) is not less than 0.05 μm and not more than 1.5 μm.

### Appendix 3-35

The semiconductor device (1) according to any one of Appendix 3-22 to Appendix 3-34, wherein the first principal surface (3) includes a diode first principal surface (119) which is formed in the diode cell region (69) and an IGBT first principal surface (120) which is formed in the IGBT region (8), and
the diode first principal surface (119) assumes a low position at the second principal surface (4) side with respect to the IGBT first principal surface (120).

### Appendix 3-36

The semiconductor device (1) according to Appendix 3-35, including a second insulating layer (79) which covers the IGBT first principal surface (120) and has a diode opening (84) that exposes the diode first principal surface (119), and
a step surface (122) which is exposed inside the diode opening (84), connects the IGBT first principal surface (120) and the diode first principal surface (119) and forms a step (121) between the IGBT first principal surface (120) and the diode first principal surface (119).

### Appendix 3-37

The semiconductor device (1) according to any one of Appendix 3-1 to Appendix 3-36, wherein the second electrode (13) is embedded in the recess (67) and directly connected to the second impurity region (62) at least in the first principal surface (3) and the side wall (105, 112, 125, 127) of the recess (67).

### Appendix 3-38

The semiconductor device (1) according to any one of Appendix 3-1 to Appendix 3-37, wherein the second impurity region (62) has an impurity concentration which is not less than 1.0×10¹⁵ cm⁻³ and not more than 1.0×10¹⁸ cm⁻³.

The present application corresponds to Japanese Patent Application No. 2021-199503 filed on Dec. 8, 2021, in the Japan Patent Office and Japanese Patent Application No. 2021-199504 filed on Dec. 8, 2021, in the Japan Patent Office, and the entire disclosures of these applications are incorporated herein by reference.

1. A semiconductor device, comprising:
a semiconductor layer which has a first principal surface and a second principal surface at the opposite side thereof;
an IGBT region which is formed in the semiconductor layer;
a diode region which is formed in the semiconductor layer and adjacent to the IGBT region;
a first impurity region of a first conductivity type which is formed inside the semiconductor layer;
a plurality of first trenches which are formed in the first principal surface of the diode region;
a diode cell region which is demarcated by being sandwiched between the mutually adjacent first trenches;
a second impurity region of a second conductivity type which is formed in a surface layer portion of the first principal surface in the diode region, wherein the second impurity region extends in the diode cell region deeper than a bottom wall of the first trench from the first principal surface along a side wall of the first trench and also forms, with the first impurity region, a pn junction portion that covers at least a part of the bottom walls of the mutually adjacent first trenches;
a first electrode which is electrically connected to the first impurity region; and
a second electrode which is electrically connected to the second impurity region.

2. The semiconductor device according to claim 1, wherein
the plurality of diode cell regions are adjacent to each other with the first trench therebetween, and
the second impurity region includes a first portion which is formed in each of the diode cell regions and a second portion which extends so as to cross the plurality of first trenches along the first principal surface, integrally covers the bottom walls of the plurality of first trenches from the second principal surface side, couples the first portions of the plurality of diode cell regions and forms the pn junction portion with the first impurity region.

3. The semiconductor device according to claim 2, wherein
the pn junction portion has a sectional shape which alternately rises and falls at the first principal surface side and at the second principal surface side along the first principal surface of the semiconductor layer.

4. The semiconductor device according to claim 3, wherein
the pn junction portion is raised toward the second principal surface side directly below the diode cell region and raised toward the first principal surface side directly below the first trench.

5. The semiconductor device according to claim 1, wherein
the plurality of diode cell regions are adjacent to each other with the first trench therebetween, and
the second impurity region is formed physically independent in each of the diode cell regions and forms the pn junction portion with the first impurity region on a lateral side of the bottom wall of the first trench.

6. The semiconductor device according to claim 5, wherein the pn junction portion has a first end portion in a bottom wall of one of the mutually adjacent first trenches and has a second end portion in a bottom wall of the other of the mutually adjacent first trenches.

7. The semiconductor device according to claim 6, wherein
the pn junction portion is formed, with the first end portion and the second end portion given as both end portions, in a curved shape which is raised toward the second principal surface side with respect to the both end portions.

8. The semiconductor device according to claim 1, including a plurality of second trenches which are formed in the first principal surface of the IGBT region and arrayed at a first pitch, wherein
the plurality of first trenches are arrayed at a second pitch which is the same as the first pitch.

9. The semiconductor device according to claim 1, including a plurality of second trenches which are formed in the first principal surface of the IGBT region and arrayed at a first pitch, wherein
the plurality of first trenches are arrayed at a second pitch which is larger than the first pitch.

10. The semiconductor device according to claim 2, including a second trench which is formed in the first principal surface of the IGBT region and
a third impurity region of a second conductivity type which is selectively formed in a bottom wall of the second trench, wherein
the second portion of the second impurity region includes a projecting portion which selectively projects at the second principal surface side directly below the first trench.

11. The semiconductor device according to claim 10, wherein
the second portion of the second impurity region includes a base portion which extends so as to continuously cross the plurality of first trenches and is connected to the projecting portion directly below each of the first trenches, and
the base portion has a curved portion formed in a curved shape that is raised toward the second principal surface side between the mutually adjacent projecting portions.

12. The semiconductor device according to claim 11, wherein
the projecting portion has a curved shape which is larger in projection amount than the curved shape of the curved portion.

13. The semiconductor device according to claim 10, wherein
the projecting portion has a depth which is substantially the same as the third impurity region.

14. The semiconductor device according to claim 10, wherein
the plurality of second trenches are arrayed at a first pitch, and
the plurality of first trenches are arrayed at a second pitch which is the same as the first pitch.

15. The semiconductor device according to claim 10, wherein
the plurality of second trenches are arrayed at a first pitch, and
the plurality of first trenches are arrayed at a second pitch which is larger than the first pitch.

16. The semiconductor device according to claim 1, wherein
the second impurity region includes an inclined portion which is downwardly inclined to a position deeper than the bottom wall of the first trench from a side wall of at least one of the first trenches toward the second principal surface in a direction away from the IGBT region and a flat portion which is continuous to a lower end of the inclined portion, extends along the first principal surface and integrally covers the bottom walls of the plurality of first trenches from the second principal surface side.

17. The semiconductor device according to claim 16, wherein
the inclined portion is downwardly inclined toward the second principal surface, with a side wall of the first trench which is closest to the IGBT region among the plurality of first trenches given as a starting point.

18. The semiconductor device according to claim 1, wherein
the second impurity region has a deepest portion at a depth position which is not less than 0.1 μm and not more than 3.0 μm from the bottom wall of the first trench.

19. The semiconductor device according to claim 1, wherein
the IGBT region includes a drift region of a first conductivity type which is formed inside the semiconductor layer and an FET structure which includes a body region of a second conductivity type that is formed in a surface layer portion of the drift region, an emitter region of a first conductivity type that is formed in a surface layer portion of the body region and a gate conductive layer that opposes the body region and the emitter region via a gate insulating layer, and
the second electrode is electrically connected to the emitter region.

20. The semiconductor device according to claim 1, further including an RC-IGBT array which includes the plurality of IGBT regions and the plurality of diode regions that are arrayed alternately along the first direction.
